(19) United States
(12) Patent Application Publication
(10) Pub. No.: US 2012/0164577 A1
(43) Pub. Date: Jun. 28, 2012

(54) POSITIVE RESIST COMPOSITION AND PATTERNING PROCESS

(75) Inventors: Ryosuke TANIGUCHI, Jyoetsu (JP); Tomohiro KOBAYASHI, Jyoetsu (JP); Takayuki NAGASAWA, Jyoetsu (JP); Masaki OHASHI, Jyoetsu (JP)

(73) Assignee: SHIN-ETSU CHEMICAL CO., LTD., Tokyo (JP)

(21) Appl. No.: 13/309,083

(22) Filed: Dec. 1, 2011

(30) Foreign Application Priority Data
Dec. 24, 2010 (JP) 2010-287951

(51) Int. Cl. G03F 7/20; G03F 7/004; G03F 7/027

(52) U.S. Cl. 430/283.1; 430/281.1; 430/270.1; 430/285.1; 430/326

(57) ABSTRACT

A positive resist composition includes at least: (A) a polymer containing a repeating unit (a1) and an acid labile repeating unit (a2), wherein the repeating unit (a1) generates an acid of a structure represented by general formula (1) as a result that the repeating unit (a1) is sensed to a high-energy radiation, the polymer being changed in solubility in alkali by the acid; and (B) an onium sulfonate represented by general formula (2). Also, a positive resist composition, which simultaneously establishes a lower acid diffusing characteristic and a higher dissolution contrast, and which suppresses volatilization of components originated from the resist composition such as a generated acid, a quencher, and the like, to suppress a chemical flare, thereby improving a DOF, a circularity, an LWR, and the like of a hole pattern, trench pattern, and the like; and a patterning process using the positive resist composition.

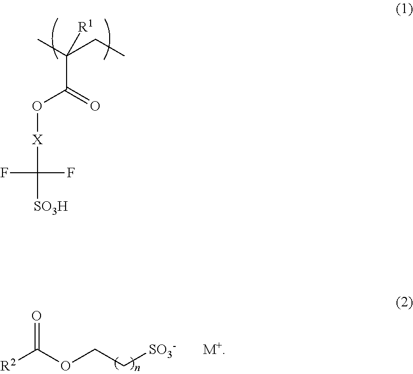

### BACKGROUND OF THE INVENTION

1. Field of the Invention

The present invention relates to a positive resist composition used for microfabrication in a process for manufacturing semiconductor devices and the like, for example, lithography using an ArF excimer laser having a wavelength of 193 nm as a light source, especially, immersion lithography to impregnate water between a projector lens and a wafer, and patterning process using the positive resist composition.

2. Description of the Related Art

In recent years, as LSI progresses toward higher integration and further acceleration in speed, miniaturization of a pattern rule is required. In the light-exposure used as a general technology nowadays, resolution is approaching to its essential limit which is inherent to wavelength of a light source.

Heretofore, light-exposure using a light source of a g-line (436 nm) or an i-line (365 nm) of a mercury lamp as an exposure light was broadly adopted in forming a resist pattern. As a mean for further miniaturization, shifting to a shorter wavelength of an exposing light was assumed to be effective. As a result, in a mass production process after DRAM (Dynamic Random Access Memory) with 64-megabits (0.25 μm or less of a processing dimension), a KrF excimer laser (248 nm), a shorter wavelength than an i-line (365 nm), was used in place of an i-line as an exposure light source.

However, in production of DRAM with an integration of 256 M, 1 G and higher which require further miniaturized process technologies (process dimension of 0.2 μm or less), a light source with a further short wavelength is required, and thus a photo lithography using an ArF excimer laser (193 nm) has been investigated seriously since about a decade ago.

At first, an ArF lithography was planned to be applied to a device-manufacturing starting from a 180-nm node device, but a KrF excimer laser lithography lived, long to a mass production of a 130-nm node device, and thus a full-fledged application of an ArF lithography will start from a 90-nm node. Further, a study of a 65-nm node device by combining with a lens having an increased NA till 0.9 is now underway.

Further shortening of wavelength of an exposure light is progressing towards the next 45-nm node device, and for that an F₂ lithography with a 157-nm wavelength became a candidate. However, there are many problems in an F₂ lithography: an increase in cost of a scanner due to the use of a large quantity of expensive CaF₂ single crystals for a projector lens; extremely poor sustainability of a soft pellicle, which leads to a change of an optical system due to introduction of a hard pellicle; a decrease in an etching resistance of a resist film; and the like. Because of these problems, it was proposed to postpone an F₂ lithography and to introduce an ArF immersion lithography earlier (Proc. SPIE Vol. 4690 xxix).

In an ArF immersion lithography, a proposal is made to impregnate water between a projector lens and a wafer. A refractive index of water at 193 nm is 1.44, and therefore a pattern formation is possible even if a lens with a numerical aperture (NA) of 1.0 or more is used, and moreover, theoretically NA may be increased to near 1.35. A miniaturization to a level of 45 nm or lower becomes possible by combination of a lens having NA of 1.2 or more and a super-resolution technology (Proc. SPIE Vol. 5040 p 724).

However, with decreased circuit line widths, resist compositions have been subjected to more serious affections of contrast deterioration due to acid diffusion. This is because pattern dimensions have been brought closer to lengths of acid diffusion, in a manner to bring about deterioration of mask fidelity and pattern rectangularity, non-uniformity of fine line patterns (line width roughness, LWR), and the like. Thus, so as to sufficiently obtain the benefits of shortened wavelengths of light sources and improved NA's, it is necessary to increase dissolution contrast and to suppress diffusion of acid, in a manner exceeding the conventional compositions.

In turn, various problems have been pointed out in immersion lithography, due to presence of water on a resist film. Namely, the problems include a pattern profile change and contamination of a projection lens of an exposure apparatus, due to leaching of a photoacid generator in the resist composition; an acid generated by photoirradiation; an amine compound added to the resist film as a quencher; and the like, to water which is in contact with the resist film.

To cope with this problem, investigations have been conducted to cause a photoacid generator to be bound. Among them, Japanese Patent Laid-Open (kokai) No. 2008-133448 discloses an anion-bound polymer. It is reported therein that the acid to be generated is immobilized to the polymer chain to thereby exhibit an effect of suppressing leaching of the acid into water contacted with the resist film, and further that acid diffusion is suppressed to thereby attain an improved maximum resolution and a mask fidelity. However, this technique is also accompanied by such a problem that generation of sulfonic acid on the polymer chain by exposure increases a solubility of the resist film into an alkaline developer even by a slight amount of exposure, thereby bringing about a considerable top loss upon formation of a fine pattern.

Japanese Patent Laid-Open (kokai) No. 2010-155824 has reported that a sulfonium salt, configured to generate a sulfonic acid without fluorine substitution by ArF excimer laser light, exhibits an excellent pattern profile and an LWR. Further, Japanese Patent No. 3912767 has reported that a pattern density dependency of lines and spaces is decreased, by combiningly using: a sulfonium salt configured to generate, by an ArF excimer laser light, alkane sulfonic acid substituted with a fluorine atom at an α-position of the sulfonic acid; and an onium salt of alkane sulfonic acid which is not substituted with a fluorine atom at an α-position of the sulfonic acid. This effect is considered, as follows. Namely, the fluorine-substituted sulfonic acid generated by exposure causes a salt exchange with the onium salt of the fluorine-unsubstituted alkane sulfonic acid, to thereby generate a fluorine-substituted sulfonic acid onium salt and a fluorine-unsubstituted sulfonic acid. The fluorine-unsubstituted sulfonic acid generated by this salt exchange is low in acid strength as compared to the fluorine-substituted sulfonic acid, and is low in affection to an elimination reaction of a resin caused by an acid. This means that the generated strong acid is turned into a weak acid, such that the onium salt of the fluorine-unsubstituted alkane sulfonic acid is considered to act as a quencher (acid deactivator) against the fluorine-substituted sulfonic acid generated by the exposure. Also, Japanese Patent Laid-Open (kokai) No. 2009-244859 describes a similar proposal. Further, Japanese Patent Laid-Open (kokai) No. 2009-244859 proposes a fluorine-unsubstituted alkane sulfonic acid onium salt having a specific structure, which is reported to lead to an improved pattern profile and the like. Such a weak acid onium salt quencher is typically involatile, and is thus capable of preventing a concentration change of quencher in a surface layer of resist film, during baking processes upon formation of the resist film and upon patterning thereof, for example, thereby allowing to expect an effect to attain an excellent rectangularity of the pattern.

However, the weak acid onium salt quencher has a tendency to be insufficient, as compared to a nitrogen-containing compound such as amine or the like, in ability for quenching a strong acid, in a manner to frequently fail to sufficiently control acid diffusion, thereby leading to a concern of insufficient mask fidelity at a maximum resolution dimension.

Meanwhile, another problem has been brought about by volatilization and re-attachment (chemical flare) of an generated acid and a quencher from and to a resist surface layer, and the like, during baking processes upon formation of a resist film and upon patterning thereof, so that a difference between a bright pattern profile and a dark pattern profile is made considerable, thereby particularly and problematically leading to an insufficient depth of focus (hereinafter also called “DOF”) due to occlusion of a hole pattern, trench pattern, or the like.

### SUMMARY OF THE INVENTION

The present invention has been carried out in view of the above circumstances, i.e., in view of the problem of an insufficient resolution of a hole pattern, trench pattern, and the like, an insufficient depth of focus due to occlusion caused by a chemical flare, and the like. It is therefore an object of the present invention to provide: a positive resist composition, which simultaneously establishes a lower acid diffusing characteristic and a higher dissolution contrast, and which suppresses volatilization of components originated from the resist composition such as a generated acid, a quencher, and the like, so that a chemical flare is suppressed, and thereby improving a DOF, a circularity, an LWR, and the like of a hole pattern, trench pattern, and the like; and a patterning process using the positive resist composition.

To achieve the above object, the present invention provides a positive resist composition comprising at least:

(A) a polymer containing a repeating unit (a1) and an acid labile repeating unit (a2), wherein the repeating unit (a1) generates an acid of a structure represented by the following general formula (1) as a result that the repeating unit (a1) is sensed to a high-energy radiation,

the polymer being changed in solubility in alkali by the acid; and

(B) an onium sulfonate represented by the following general formula (2),

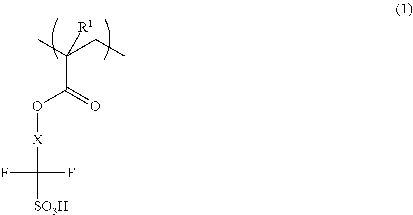

wherein

R¹ represents a hydrogen atom or a methyl group; and

X represents a straight, branched, or cyclic alkylene group having 1 to 10 carbon atoms which may contain an ether group or ester group, and one or more hydrogen atoms of the alkylene group may each be substituted by a fluorine atom,

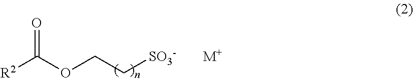

wherein

R² represents a monovalent hydrocarbon group which may contain a heteroatom;

n represents an integer of 1 to 3; and

M⁺ represents a counter cation having a substituent, and represents a sulfonium cation, iodonium cation, or ammonium cation.

In this way, the positive resist composition of the present invention is characterized in that the same comprising both of: (A) a polymer containing a repeating unit (a1) and an acid labile repeating unit (a2), wherein the repeating unit (a1) generates an acid of a specific structure by irradiation of a high-energy radiation, such as ultraviolet rays, deep ultraviolet rays, electron beam, X-rays, excimer laser, γ-rays, synchrotron radiation, or the like, and the polymer being changed (increased) in solubility in alkali, by the acid; and (B) an onium sulfonate of a specific structure having an acid-generating ability. Such a positive resist composition is capable of ensuring a higher latent image contrast even under a condition of lower optical contrast, by virtue of: a lower diffusing characteristic of an acid generated in the polymer (A) after exposure; and an improved dissolution contrast by the function of the onium sulfonate (B). Further, the generated acid from the polymer (A) is immobilized to the polymer, and additionally the onium sulfonate (B) is involatile, so that no components are volatilized in baking processes to thereby suppress chemical flare, and thereby exhibiting en excellent resist performance having a wider baking process margin. This is an effect, which can be never exhibited by only one of the components (A) and (B).

In this case, it is preferable that the acid generated as the result that the repeating unit (a1) in the polymer (A) is sensed to the high-energy radiation, is an acid of a structure represented by the following general formula (3),

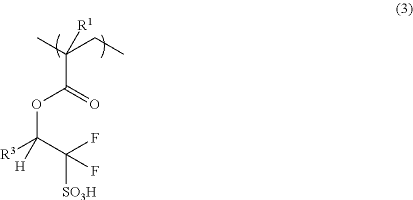

wherein

R¹ represents the same meaning as before; and

R³ represents a hydrogen atom or a trifluoromethyl group.

In this way, the acid generated as the result that the repeating unit (a1) in the polymer (A) is sensed to the high-energy radiation, is preferably the acid of the structure represented by the above general formula (3), among those acids of structures each represented by the above general formula (1). The polymer containing the repeating unit (a1) configured to generate the acid represented by the above general formula (3) is preferable, since the polymer can be synthesized readily and inexpensively.

In this case, it is possible that the repeating unit (a1) in the polymer (A) is a repeating unit represented by the following general formula (4) or (5),

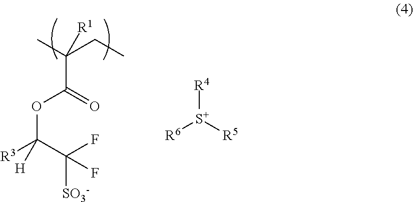

wherein

R¹ represents the same meaning as before;

R³ represents a hydrogen atom or a trifluoromethyl group; and each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;

wherein any two or more of R⁴, R⁵, and R⁶ may bond to each other to form a ring together with a sulfur atom in the formula,

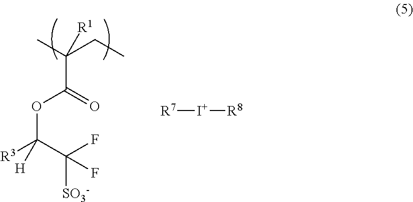

wherein

R¹ represents the same meaning as before;

R³ represents a hydrogen atom or a trifluoromethyl group; and

each R⁷ and R⁸ independently represent a substituted or unsubstituted aryl group having 6 to 18 carbon atoms.

In this way, examples of the repeating unit (a1) in the polymer (A) include those repeating units represented by the general formulae (4) and (5), respectively.

In this case, it is possible that the onium sulfonate (B) is a sulfonium sulfonate represented by the following general formula (6),

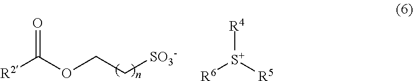

wherein

R²′ represents a straight, branched, or cyclic alkyl group having 1 to 50 carbon atoms which may contain a heteroatom;

n represents the same meaning as before; and

each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;

wherein any two or more of R⁴, R⁵, and R⁶ may bond to each other to form a ring together with a sulfur atom in the formula.

In this way, examples of the onium sulfonate (B) include such a sulfonium sulfonate that the in the above general formula (2) is a sulfonium cation.

In this case, it is also possible that the onium sulfonate (B) is a iodonium sulfonate represented by the following general formula (7),

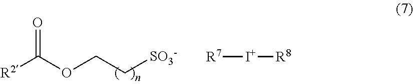

wherein

R²′ represents a straight, branched, or cyclic alkyl group having 1 to 50 carbon atoms which may contain a heteroatom;

n represents the same meaning as before; and

each R⁷ and R⁸ independently represent a substituted or unsubstituted aryl group having 6 to 18 carbon atoms.

In this way, examples of the onium sulfonate (B) include such a iodonium sulfonate that the M⁺ in the above general formula (2) is an iodonium cation.

In this case, it is also possible that the onium sulfonate (B) is a ammonium sulfonate represented by the following general formula (8),

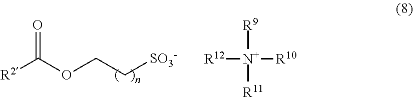

wherein

R²′ represents a straight, branched, or cyclic alkyl group having 1 to 50 carbon atoms which may contain a heteroatom;

n represents the same meaning as before; and

each R⁹, R¹⁰, R¹¹, and R¹² independently represent: a substituted or unsubstituted straight, branched, or cyclic alkyl group, alkenyl group, or oxoalkyl group having 1 to 18 carbon atoms, which group may contain a heteroatom; or a substituted or unsubstituted aryl group, aralkyl group, or aryloxoalkyl group having 6 to 18 carbon atoms;

wherein any two or more of R⁹, R¹⁰, R¹¹, and R¹² may bond to each other to form a ring together with a nitrogen atom in the formula.

In this way, examples of the onium sulfonate (B) include such a ammonium sulfonate that the M⁺ in the above general formula (2) is an ammonium cation.

Further, it is preferable that the polymer (A) further includes a repeating unit (a3) of a structure containing a lactone ring.

In this way, the polymer (A) contains the lactone ring which is an adhesive group, thereby enabling to more effectively improve the LWR.

It is further preferable that the repeating unit (a1) in the polymer (A) has a content ratio of 1 to 10% in molar ratio; and

that the onium sulfonate (B) has a content of 1 to 15 mass parts, relative to 100 mass parts of a content of the polymer (A).

In this way, when the repeating unit (a1) in the polymer (A) has a content ratio of 1 to 10% in molar ratio, and the onium sulfonate (B) has a content of 1 to 15 mass parts, relative to 100 mass parts of a content of the polymer (A), it is allowed to simultaneously establish a lower acid diffusing characteristic and a higher dissolution contrast more certainly, and to improve a DOF, a circularity, an LWR, and the like of a hole pattern, trench pattern, and the like.

It is preferable that the positive resist composition of the present invention further contains at least one or more of an organic solvent, a basic compound, a dissolution control agent, and a surfactant.

In this way, further inclusion of the organic solvent enables to exemplarily improve a coatability of the positive resist composition onto a substrate or the like, further inclusion of the basic compound enables to more improve the resolution, further inclusion of the dissolution control agent enables to more increase the difference of dissolution rate between an exposed portion and an unexposed portion and to more improve the resolution, and addition of the surfactant enables to more improve or control the coatability of the resist composition.

Further, the present invention provides a patterning process comprising the steps of:

applying the aforementioned resist composition to a substrate, and heat-treating the resist composition, to obtain a resist film;

exposing the resist film to a high-energy radiation; and

developing the resist film by a developer.

In this way, according to the patterning process of the present invention, it is enabled to simultaneously establish a lower acid diffusing characteristic and a higher dissolution contrast, and to suppress volatilization of components originated from the resist composition such as a generated acid, a quencher, and the like, so that a chemical flare is suppressed, thereby improving a DOF, a circularity, an LWR, and the like of a hole pattern, trench pattern, and the like.

Further, in this case, it is preferable that the high-energy radiation is within a wavelength range of 180 to 250 nm.

In this way, the patterning process of the present invention is optimum for a fine patterning by deep ultraviolet rays or excimer laser of 180 to 250 nm, X-rays, electron beam, and the like, among high-energy radiations such as ultraviolet rays, deep ultraviolet rays, electron beam, X-rays, excimer laser, γ-rays, synchrotron radiation, and the like.

Further, in this case, it is preferable that the step of exposing the resist film to the high-energy radiation is conducted by immersion exposure configured to expose the resist film through a liquid. In this case, it is possible that the resist film is provided with a top coat thereon, in the immersion exposure. Moreover, it is possible that water is used as the liquid.

In this way, it is possible to use, as the exposing step by the high-energy radiation, the immersion method configured to provide a liquid between a mask and a resist film, and to conduct the exposure through the liquid (particularly, water). In that case, it is possible to form and use a top coat insoluble in water, on the resist film. The top coat is capable of blocking a leaching component(s) from the resist film, thereby enabling to improve a water slidablity of the film surface.

The present invention realizes an improved pattern density dependency and an improved line width roughness (LWR), and suppresses volatilization of components originated from a resist composition such as a generated acid, thereby enabling to suppress chemical flare. Namely, it is enabled to restrict, occlusion of trenches in case of a line and space pattern, and occlusion of a hole in case of a hole pattern. Further, it is enabled to provide: a positive resist composition which is less in pattern profile change due to baking upon film formation and upon patterning; and a patterning process adopting it.

### DETAILED DESCRIPTION OF THE PREFERRED EMBODIMENTS

Although the present invention will be explained hereinafter with reference to a best mode for implementing it, the present invention is not limited thereto.

The present inventors have earnestly and repetitively conducted investigations so as to achieve the above object, and have resultingly found out that, a positive resist composition containing both of: (A) a polymer containing a repeating unit (a1) and an acid labile repeating unit (a2), wherein the repeating unit (a1) generates an acid of a specific structure by irradiation of a high-energy radiation, such as ultraviolet rays, deep ultraviolet rays, electron beam, X-rays, excimer laser, γ-rays, synchrotron radiation, or the like, and the polymer being changed (increased) in solubility in alkali, by the acid; and (B) an onium sulfonate of a specific structure; exhibits an extremely high resolution in a fine pattern, particularly a trench pattern, hole pattern, or the like, and improves a pattern profile, DOF, roughness, and baking process margin.

Namely, it is enabled to ensure a higher latent image contrast even under a condition of lower optical contrast, by virtue of: a lower diffusing characteristic of an acid generated in the polymer (A) after exposure; and an improved dissolution contrast by the function of the onium sulfonate (B). Further, it is considered that the generated acid in the polymer (A) is immobilized to the polymer and the onium sulfonate (B) is additionally involatile, so that no components are volatilized in baking processes, thereby suppressing chemical flare and exhibiting an excellent resist performance having a wider baking process margin. This is an effect, which can be never exhibited by only one of the components (A) and (B).

Namely, the present invention is to propose the positive resist composition containing both of: a polymer (A) containing a repeating unit (a1) and an acid labile repeating unit (a2), wherein the repeating unit (a1) generates an acid of a structure represented by the following general formula (1) as a result that the repeating unit (a1) is sensed to a high-energy radiation, and the polymer being changed in solubility in alkali by the acid; and the onium sulfonate (B) of a specific structure. The positive resist composition of the present invention will be described hereinafter in more detail.

The acid to be generated as a result that the repeating unit (a1) in the polymer (A) is sensed to a high-energy radiation, is represented by the following general formula (1),

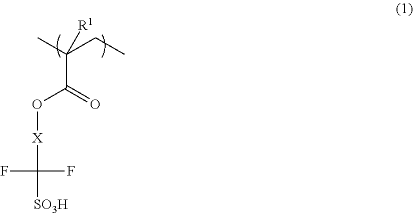

wherein

R¹ represents a hydrogen atom or a methyl group; and

X represents a straight, branched, or cyclic alkylene group having 1 to 10 carbon atoms which may contain an ether group or ester group, and one or more hydrogen atoms of the alkylene group may each be substituted by a fluorine atom.

Specific examples of the compound represented by the above general formula (1) exemplarily include those compounds having structures shown below, respectively, without limited thereto.

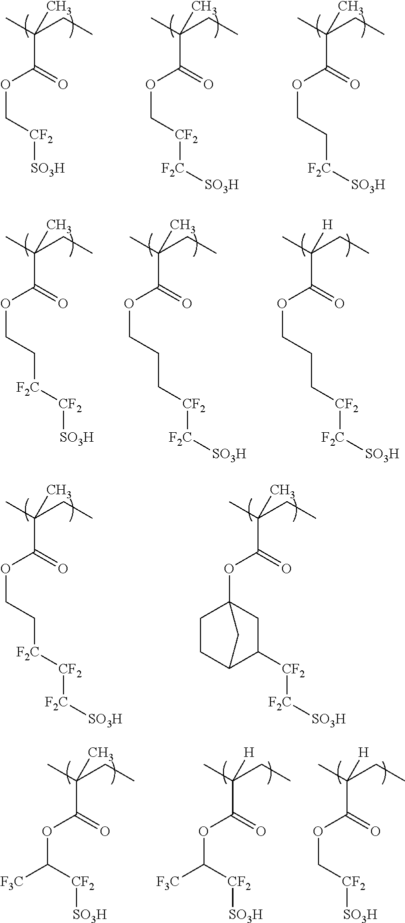

The acid to be generated as a result that the repeating unit (a1) in the polymer (A) is sensed to a high-energy radiation, is more preferably an acid represented by the following general formula (3),

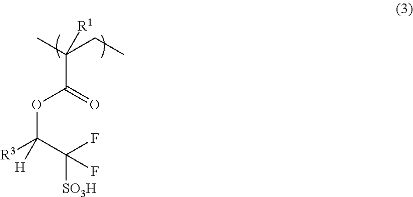

wherein

R¹ represents the same meaning as before; and

R³ represents a hydrogen atom or a trifluoromethyl group.

The repeating unit (a1), which is contained in the polymer (A) and generates the acid represented by the above general formula (1), particularly the acid represented by the above general formula (3), is preferably a repeating unit represented by either of the following general formula (4) or the following general formula (5),

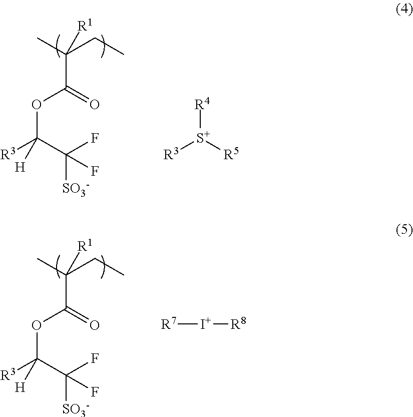

wherein

R¹ represents a hydrogen atom or a methyl group; and

R³ represents a hydrogen atom or a trifluoromethyl group;

each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms, wherein any two or more of R⁴, R⁵, and R⁶ may bond to each other to form a ring together with a sulfur atom in the formula; and

each R⁷ and R⁸ independently represent a substituted or unsubstituted aryl group having 6 to 18 carbon atoms.

Examples of the alkyl group and alkenyl group specifically include a methyl group, ethyl group, n-propyl group, isopropyl group, n-butyl group, tert-butyl group, cyclopropyl group, cyclopentyl group, cyclohexyl group, cyclopropylmethyl group, 4-methylcyclohexyl group, cyclohexylmethyl group, norbornyl group, adamantyl group, vinyl group, allyl group, propenyl group, butenyl group, hexenyl group, cyclohexenyl group, and the like. Further, these groups may each be substituted, at part of hydrogen atoms, by a fluorine atom(s), hydroxyl group(s), or the like, respectively.

Specific examples of the oxoalkyl group include a 2-oxocyclopentyl group, 2-oxocyclohexyl group, 2-oxopropyl group, 2-oxoethyl group, 2-cyclopentyl-2-oxoethyl group, 2-cyclohexyl-2-oxoethyl group, 2-(4-methylcyclohexyl)-2-oxoethyl group, and the like. Further, these groups may each be substituted, at part of hydrogen atoms, by a fluorine atom(s), hydroxyl group(s), or the like, respectively.

Specific examples of the aryl group include: a phenyl group, naphthyl group, and thienyl group; a 4-hydroxylphenyl; alkoxyphenyl groups such as a 4-methoxyphenyl group, 3-methoxyphenyl group, 2-methoxyphenyl group, 4-ethoxyphenyl group, 4-tert-butoxyphenyl group, and 3-tert-butoxyphenyl group; alkylphenyl groups such as a 2-methylphenyl group, 3-methylphenyl group, 4-methylphenyl group, 4-ethylphenyl group, 4-tert-butylphenyl group, 4-n-butylphenyl group, and 2,4-dimethylphenyl group; alkylnaphthyl groups such as a methylnaphthyl group, and ethylnaphthyl group; alkoxynaphthyl groups such as a methoxynaphthyl group, and ethoxynaphthyl group; dialkylnaphthyl groups such as a dimethylnaphthyl group, and diethylnaphthyl group; and dialkoxynaphthyl groups such as a dimethoxynaphthyl group, and diethoxynaphthyl group; and these groups may each be substituted, at part of hydrogen atoms, by a fluorine atom(s), hydroxyl group(s), or the like, respectively.

Examples of the aralkyl group include a benzyl group, 1-phenylethyl group, and 2-phenylethyl group. Further, these groups may each be substituted, at part of hydrogen atoms, by a fluorine atom(s), hydroxyl group(s), or the like, respectively.

Examples of the aryloxoalkyl group include: 2-aryl-2-oxoethyl groups such as a 2-phenyl-2-oxoethyl group, 2-(1-naphthyl)-2-oxoethyl group, and 2-(2-naphthyl)-2-oxoethyl group. Further, these groups may each be substituted, at part of hydrogen atoms, by a fluorine atom(s), hydroxyl group(s), or the like, respectively.

In case that any two or more of R⁴, R⁵, and R⁶ are bonded to each other to form a ring structure together with a sulfur atom in the formula, examples of the ring structure include those groups represented by the following formulae, respectively,

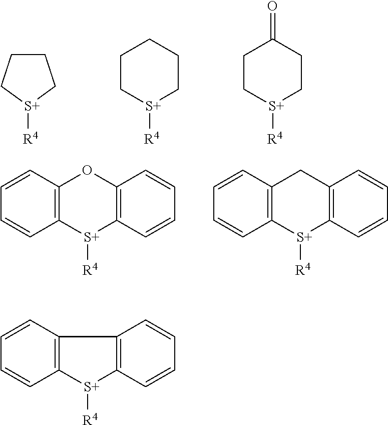

wherein R⁴ represents the same meaning as before.

Specific examples of the repeating unit represented by the above general formula (4) include those compounds having structures shown below, respectively, without limited thereto.

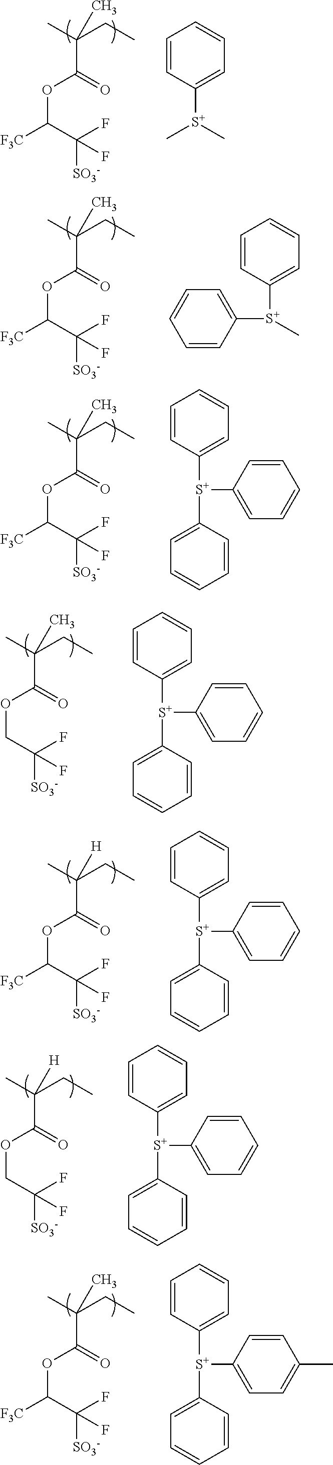

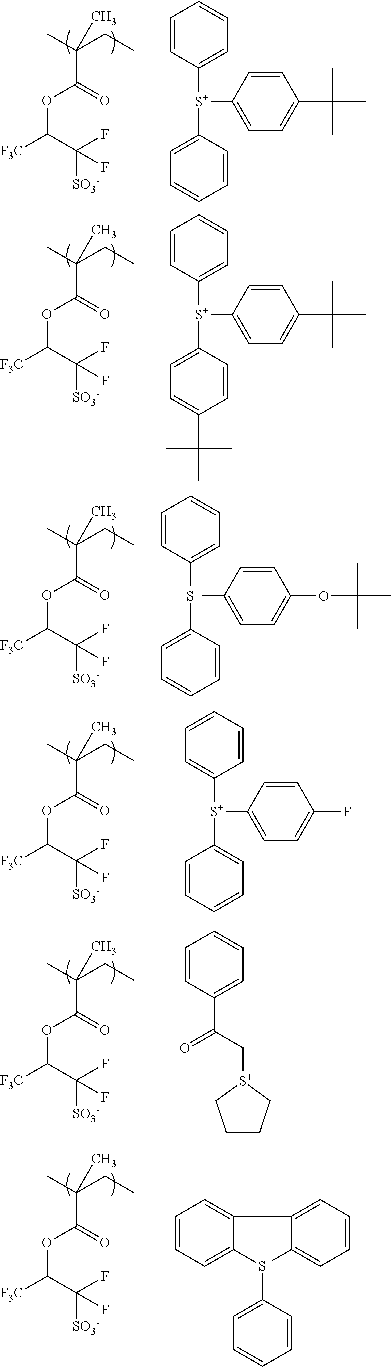

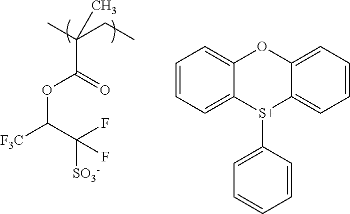

Further, specific examples of the repeating unit represented by the above general formula (5) include those compounds having structures shown below, respectively, without limited thereto.

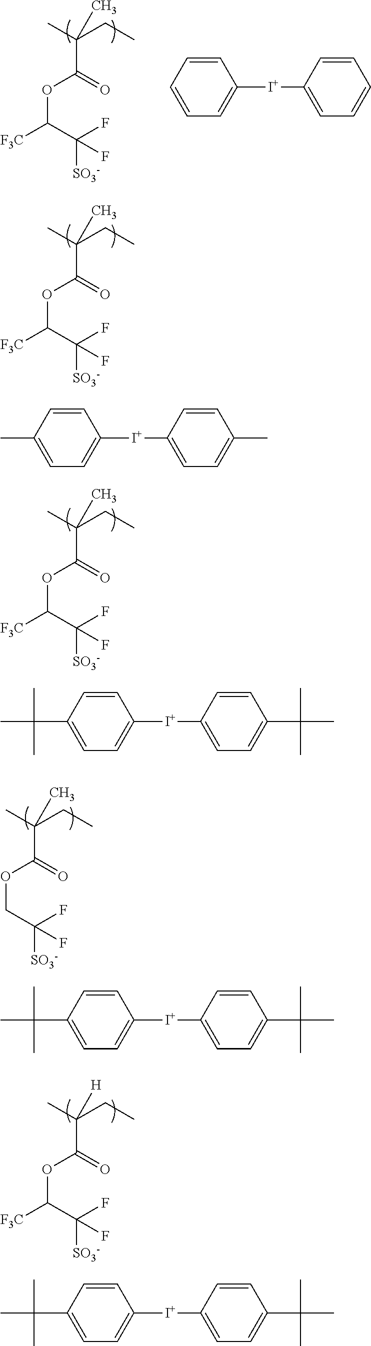

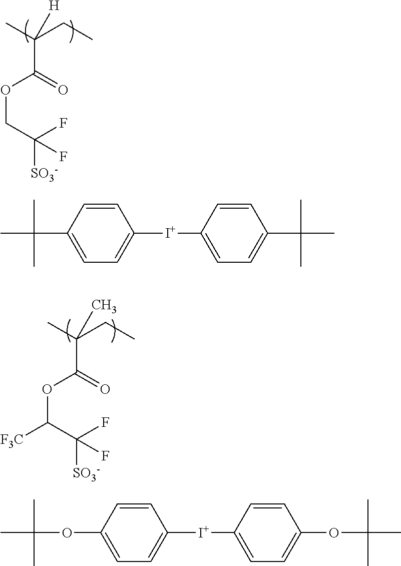

The polymer (A) in the positive resist composition of the present invention is characterized in that the polymer (A) contains one or more acid labile repeating units (a2), together with the repeating unit (a1) which generates the above-described acid having the specific structure. The acid labile repeating unit is a repeating unit having such a structure that an acidic group such as a carboxylic acid, phenol, fluoroalcohol, or the like is protected by an acid labile group, and the repeating unit is deprotected by an acid, thereby enabling to change, i.e., improve a solubility of the polymer in an alkaline developer.

Usable as the acid labile group are various ones, and examples thereof specifically include an alkoxymethyl group represented by the following general formula (L1), tertiary alkyl groups represented by the following general formulae (L2) to (L8), respectively, and an alkoxycarbonyl group or alkoxycarbonylalkyl group represented by the following general formula (L9), without limited thereto:

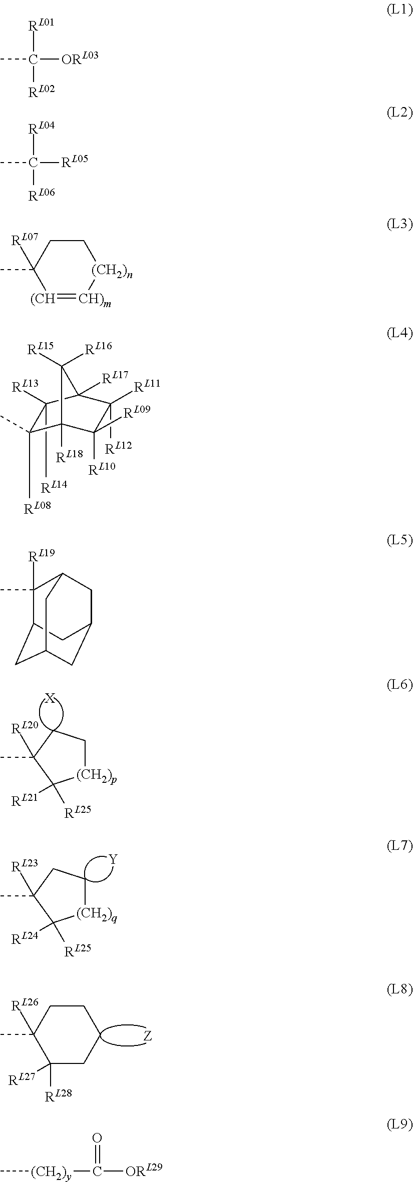

In the above formulae, broken lines each indicate a bonding hand. Further, R^{L01} and R^{L02} each represent a hydrogen atom, or a straight, branched, or cyclic alkyl group having 1 to 18 carbon atoms, preferably 1 to 10 carbon atoms, and examples thereof specifically include a methyl group, ethyl group, propyl group, isopropyl group, n-butyl group, sec-butyl group, tert-butyl group, cyclopentyl group, cyclohexyl group, 2-ethylhexyl group, n-octyl group, and adamantyl group. R^{L03} represents a monovalent hydrocarbon group, which may contain a heteroatom, having 1 to 18 carbon atoms, preferably 1 to 10 carbon atoms, and examples thereof include a straight, branched, or cyclic alkyl group, and such an alkyl group obtained by substituting the above alkyl group, at part of hydrogen atoms, by a hydroxyl group(s), alkoxy group(s), oxo group(s), amino group(s), alkylamino group(s), or the like, such that examples of the straight, branched, or cyclic alkyl group are the same as those for the R^{L01} and R^{L02}, while examples of the substituted alkyl group include the following groups:

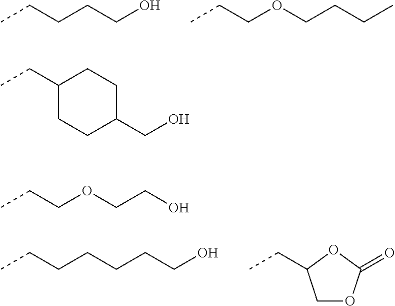

R^{L01} and R^{L02}, R^{L01} and R^{L03}, or R^{L02} and R^{L03} may bond to each other to form a ring together with a carbon atom or oxygen atom to which R^{L01}, R^{L02} and R^{L03} is bonded, and in case of forming a ring, R^{L01}, R^{L02}, and R^{L03} each represent a straight or branched alkylene group having 1 to 18 carbon atoms, preferably 1 to 10 carbon atoms.

R^{L04}, R^{L05}, and R^{L06} each independently represent a straight, branched, or cyclic alkyl group having 1 to 15 carbon atoms. Examples thereof specifically include a methyl group, ethyl group, propyl group, isopropyl group, n-butyl group, sec-butyl group, tert-butyl group, cyclopentyl group, cyclohexyl group, 2-ethylhexyl group, n-octyl group, 1-adamantyl group, 2-adamantyl group, and the like.

R^{L07} represents a straight, branched, or cyclic alkyl group having 1 to 10 carbon atoms which may be substituted, or an aryl group having 6 to 20 carbon atoms which may be substituted. Examples of the alkyl group which may be substituted, specifically include: a straight, branched, or cyclic alkyl group such as a methyl group, ethyl group, propyl group, isopropyl group, n-butyl group, sec-butyl group, tert-butyl group, tert-amyl group, n-pentyl group, n-hexyl group, cyclopentyl group, cyclohexyl group, bicyclo[2.2.1]heptyl group, and the like; such a group obtained by substituting the above alkyl group, at part of hydrogen atoms, by a hydroxyl group(s), alkoxy group(s), carboxyl group(s), alkoxycarbonyl group(s), oxo group(s), amino group(s), alkylamino group(s), cyano group(s), mercapto group(s), alkylthio group(s), sulfo group(s), or the like; or such a group obtained by substituting the above mentioned alkyl group, at part of the methylene group, by an oxygen atom or sulfur atom. Examples of the aryl group which may be substituted, specifically include a phenyl group, methylphenyl group, naphthyl group, anthryl group, phenanthryl group, pyrenyl group, or the like. In the formula (L3), m is 0 or 1, n is 0, 1, 2, or 3, which are numbers satisfying that 2 m+n=2 or 3.

R^{L08} represents a straight, branched, or cyclic alkyl group having 1 to 10 carbon atoms which may be substituted, or an aryl group having 6 to 20 carbon atoms which may be substituted, and examples thereof specifically include the same groups as those for R^{L07}, and the like. R^{L09} to R^{L18} each independently represent a hydrogen atom, or a monovalent hydrocarbon group having 1 to 15 carbon atoms, and examples thereof specifically include: a straight, branched, or cyclic alkyl group such as a methyl group, ethyl group, propyl group, isopropyl group, n-butyl group, sec-butyl group, tert-butyl group, tert-amyl group, n-pentyl group, n-hexyl group, n-octyl group, n-nonyl group, n-decyl group, cyclopentyl group, cyclohexyl group, cyclopentylmethyl group, cyclopentylethyl group, cyclopentylbutyl group, cyclohexylmethyl group, cyclohexylethyl group, cyclohexylbutyl group, and the like; such an alkyl group obtained by substituting the above alkyl group, at part of hydrogen atoms, by a hydroxyl group(s), alkoxy group(s), carboxyl group(s), alkoxycarbonyl group(s), oxo group(s), amino group(s), alkylamino group(s), cyano group(s), mercapto group(s), alkylthio group(s), sulfo group(s), or the like. R^{L09} to R^{L18} may bond to each other to form a ring (for example, R^{L09} and R^{L10}, R^{L09} and R^{L11}, R^{L10} and R^{L12}, R^{L11} and R^{L12}, R^{L13} and R^{L14}, R^{L15} and R^{L16}, or the like), and in such a case, they each represent a divalent hydrocarbon group having 1 to 15 carbon atoms, where examples thereof specifically include those each obtained by eliminating one hydrogen atom from each of those examples mentioned for the monovalent hydrocarbon group, and the like. Further, those two of R^{L09} to R^{L18}, which are bonded to adjacent carbons, respectively, may bond to each other without through any atom therebetween, to form a double bond (for example, R^{L09} and R^{L11}, R^{L11} and R^{L17}, R^{L15} and R^{L17}, or the like).

R^{L19} represents a straight, branched, or cyclic alkyl group having 1 to 10 carbon atoms which may be substituted, or an aryl group having 6 to 20 carbon atoms which may be substituted, and examples thereof specifically include the same groups as those for R^{L07}, and the like.

R^{L20} represents a straight, branched, or cyclic alkyl group having 1 to 10 carbon atoms which may be substituted, or an aryl group having 6 to 20 carbon atoms which may be substituted, and examples thereof specifically include the same groups as those for R^{L07}, and the like. X represents a divalent group that forms, together with a carbon atom to which it bonds, a substituted or unsubstituted cyclopentane ring, cyclohexane ring, or norbornane ring. R^{L21} and R^{L22} each independently represent a hydrogen atom, or a straight, branched, or cyclic monovalent hydrocarbon group having 1 to 10 carbon atoms; or R^{L21} and R^{L22} represent divalent groups, respectively, bonded to each other to form, together with a carbon atom to which the groups are bonded, a substituted or unsubstituted cyclopentane ring or cyclohexane ring. p represents 1 or 2.

R^{L23} represents a straight, branched, or cyclic alkyl group having 1 to 10 carbon atoms which may be substituted, or an aryl group having 6 to 20 carbon atoms which may be substituted, and examples thereof specifically include the same groups as those for R^{L07}, and the like. Y represents a divalent group that forms, together with a carbon atom to which it bonds, a substituted or unsubstituted cyclopentane ring, cyclohexane ring, or norbornane ring. R^{L24} and R^{L25} each independently represent a hydrogen atom, or a straight, branched, or cyclic monovalent hydrocarbon group having 1 to 10 carbon atoms; or R^{L24} and R^{L25} represent divalent groups, respectively, bonded to each other to form, together with a carbon atom to which the groups are bonded, a substituted or unsubstituted cyclopentane ring or cyclohexane ring. q represents 1 or 2.

R^{L26} represents a straight, branched, or cyclic alkyl group having 1 to 10 carbon atoms which may be substituted, or an aryl group having 6 to 20 carbon atoms which may be substituted, and examples thereof specifically include the same groups as those for R^{L07}, and the like. Z represents a divalent group that forms, together with a carbon atom to which it bonds, a substituted or unsubstituted cyclopentane ring, cyclohexane ring, or norbornane ring. R^{L27} and R^{L28} each independently represent a hydrogen atom, or a straight, branched, or cyclic monovalent hydrocarbon group having 1 to 10 carbon atoms; or R^{L27} and R^{L28} represent divalent groups, respectively, bonded to each other to form, together with a carbon atom to which the groups are bonded, a substituted or unsubstituted cyclopentane ring or cyclohexane ring.

R^{L29} represents: a tertiary alkyl group having 4 to 20 carbon atoms, preferably 4 to 15 carbon atoms; a trialkylsilyl group, whose alkyl group has 1 to 6 carbon atoms; an oxoalkyl group having 4 to 20 carbon atoms; or the group represented by the general formula (L1). Examples of the tertiary alkyl group specifically include a tert-butyl group, tent-amyl group, 1,1-diethylpropyl group, 2-cyclopentylpropan-2-yl group, 2-cyclohexylpropan-2-yl group, 2-(bicyclo[2.2.1]heptan-2-yl)propan-2-yl group, 2-(adamantan-1-yl)propan-2-yl group, 1-ethylcyclopentyl group, 1-butylcyclopentyl group, 1-ethylcyclohexyl group, 1-butylcyclohexyl group, 1-ethyl-2-cyclopentenyl group, 1-ethyl-2-cyclohexenyl group, 2-methyl-2-adamantyl group, 2-ethyl-2-adamantyl group, and the like. Examples of the trialkylsilyl group specifically include a trimethylsilyl group, triethylsilyl group, dimethyl-tert-butylsilyl group, and the like. Examples of the oxoalkyl group specifically include a 3-oxocyclohexyl group, 4-methyl-2-oxooxan-4-yl group, 5-methyl-2-oxooxolan-5-yl group, and the like. y is an integer of 0 to 3.

Examples of the acid labile group represented by the formula (L1) specifically include the following groups:

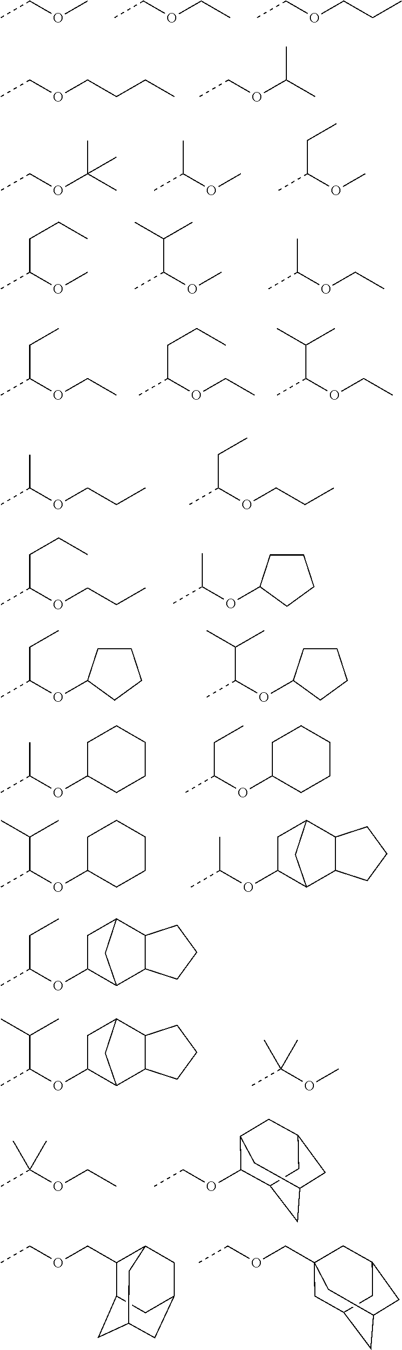

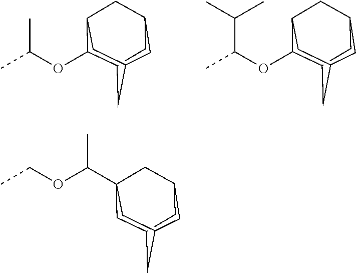

Examples of cyclic ones of the acid labile groups represented by the formula (L1) specifically include a tetrahydrofuran-2-yl group, 2-methyltetrahydrofuran-2-yl group, tetrahydropyran-2-yl group, 2-methyltetrahydropyran-2-yl group, and the like.

Examples of the acid labile group of the formula (L2) specifically include a tert-butyl group, tert-amyl group, and the following groups:

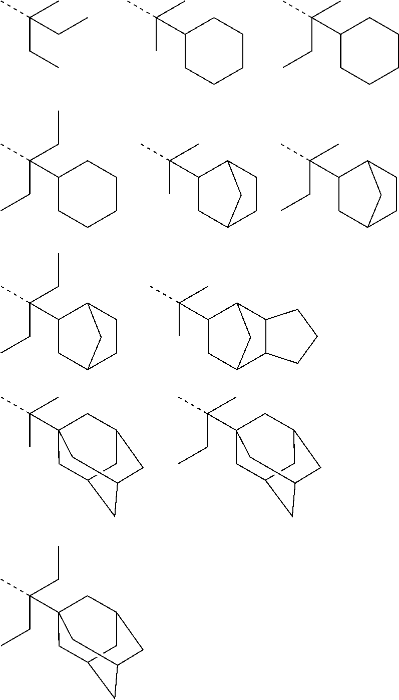

Examples of the acid labile group of the formula (L3) specifically include a 1-methylcyclopentyl group, 1-ethylcyclopentyl group, 1-n-propylcyclopentyl group, 1-isopropylcyclopentyl group, 1-n-butylcyclopentyl group, 1-sec-butylcyclopentyl group, 1-cyclohexylcyclopentyl group, 1-(4-methoxy-n-butyl)cyclopentyl group, 1-(bicyclo[2.2.1]heptan-2-yl)cyclopentyl group, 1-(7-oxabicyclo[2.2.1]heptan-2-yl)cyclopentyl group, 1-methylcyclohexyl group, 1-ethylcyclohexyl group, 3-methyl-1-cyclopenten-3-yl group, 3-ethyl-1-cyclopenten-3-yl group, 3-methyl-1-cyclohexen-3-yl group, 3-ethyl-1-cyclohexen-3-yl group, and the like.

Particularly preferable as the acid labile groups of the formula (L4) are groups represented by the following formulae (L4-1) to (L4-4):

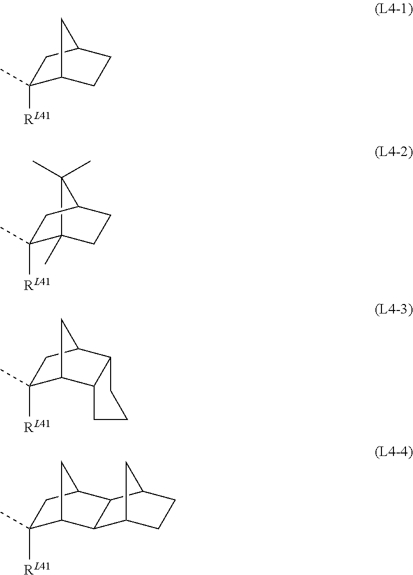

In the general formulae (L4-1) to (L4-4), broken lines each indicate a bonding position and a bonding direction. R^{L41}'s each independently represent a monovalent hydrocarbon group such as a straight, branched, or cyclic alkyl group and the like having 1 to 10 carbon atoms, and examples thereof specifically include a methyl group, ethyl group, propyl group, isopropyl group, n-butyl group, sec-butyl group, tert-butyl group, tert-amyl group, n-pentyl group, n-hexyl group, cyclopentyl group, cyclohexyl group, and the like.

Although examples of the groups of the general formulae (L4-1) to (L4-4) include an enantiomer, diastereomer, and the like, these general formulae (L4-1) to (L4-4) embracingly represent all of these stereoisomers. These stereoisomers may each be used solely, or may be used as a mixture.

For example, the general formula (L4-3) is to embracingly represent one kind or a mixture of two kinds selected from groups represented by the following general formulae (L4-3-1) and (L4-3-2):

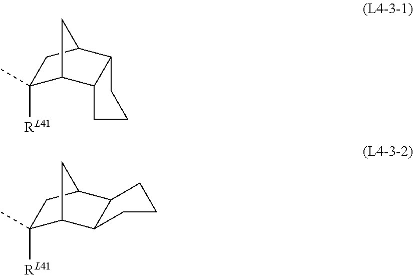

wherein R^{L41} represents the same meaning as before.

Further, the general formula (L4-4) is to embracingly represent one kind or a mixture of two or more kinds selected from groups represented by the following general formulae (L4-4-1) to (L4-4-4):

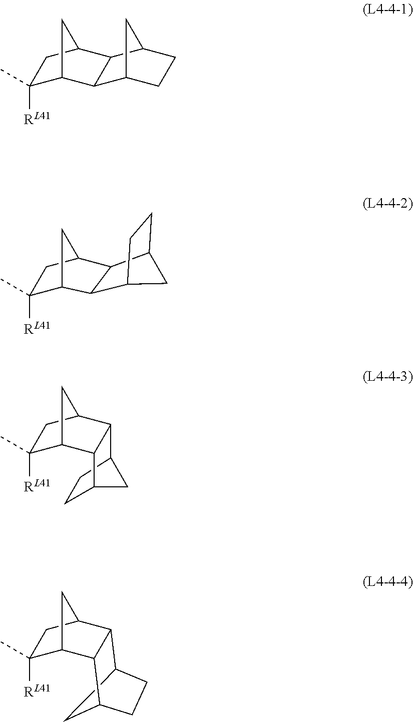

wherein R^{L41} represents the same meaning as before.

The general formulae (L4-1) to (L4-4), (L4-3-1) and (L4-3-2), and formulae (L4-4-1) to (L4-4-4) are to embracingly represent even enantiomers and enantiomer mixtures of the groups represented by these formulae.

It is noted that the bonding direction of each of the groups of the general formulae (L4-1) to (L4-4), (L4-3-1) and (L4-3-2), and formulae (L4-4-1) to (L4-4-4) is placed at an exo side relative to the bicyclo[2.2.1]heptane ring, thereby realizing a higher reactivity in an acid catalyzed elimination reaction (Japanese Patent Application Laid-Open Publication No. 2000-336121). In production of monomers each having a tertiary exo-alkyl group having a bicyclo[2.2.1]heptane structure as a substituent group, the monomers occasionally contain monomers each substituted with an endo-alkyl group represented by the following general formulae (L4-1-endo) to (L4-4-endo); where the exo ratio is preferably 50% or more, and the exo ratio is more preferably 80% or more, for realization of an excellent reactivity:

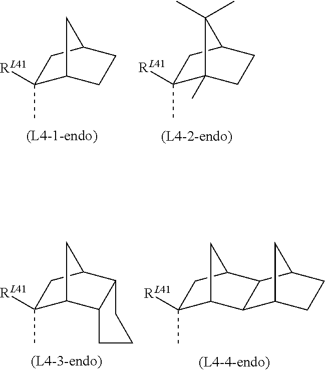

wherein R^{L41} represents the same meaning as before.

Examples of the acid labile group of the formula (L4) specifically include the following groups:

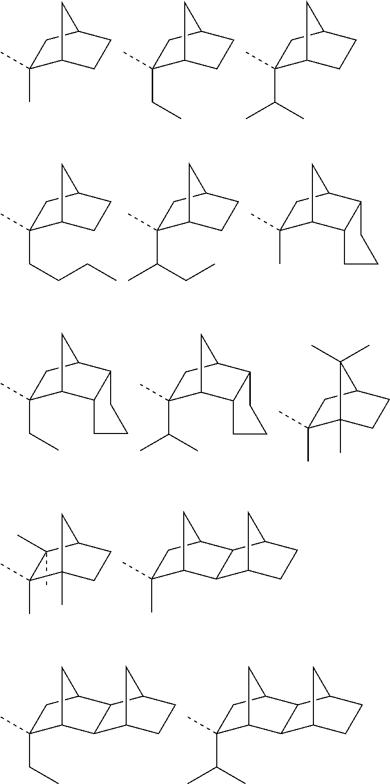

Examples of the acid labile group of the formula (L5) specifically include the following groups:

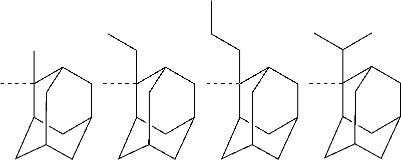

Examples of the acid labile group of the formula (L6) specifically include the following groups:

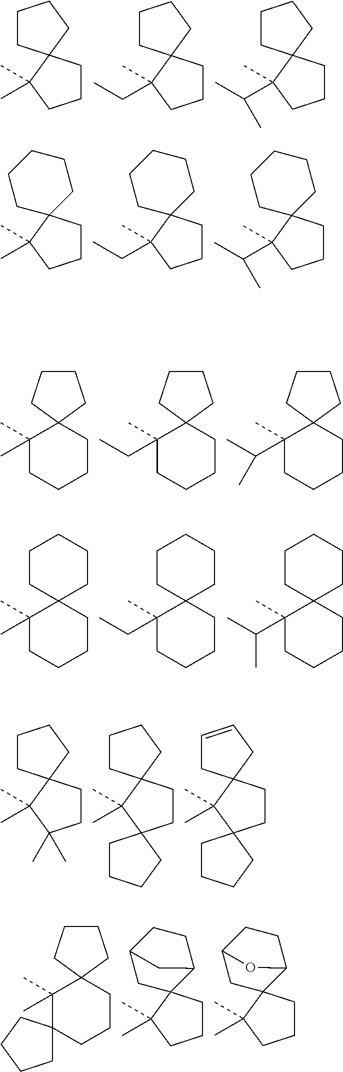

Examples of the acid labile group of the formula (L7) specifically include the following groups:

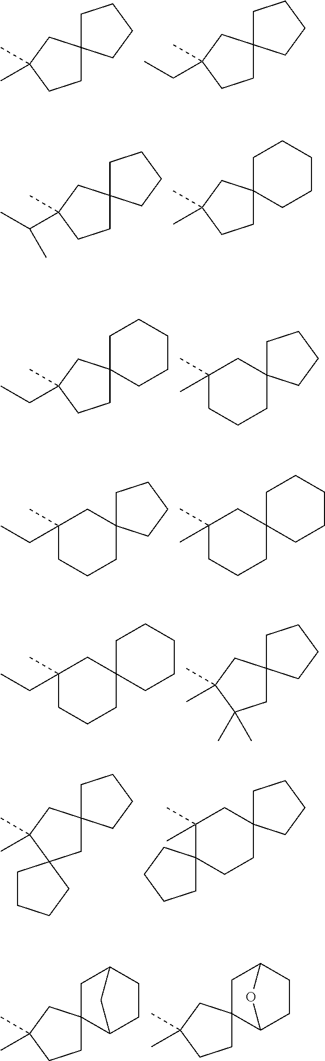

Examples of the acid labile group of the formula (L8) specifically include the following groups:

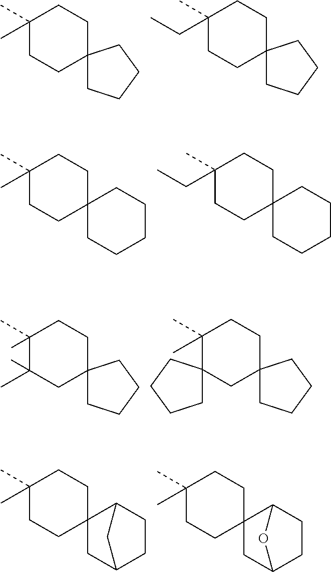

Examples of the acid labile group of the formula (L9) specifically include the following groups:

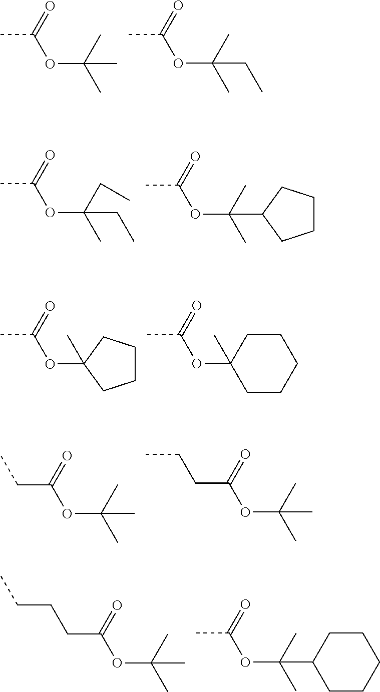

Shown below are specific examples of the acid labile repeating unit (a2) having the above exemplified acid labile group, without limited thereto:

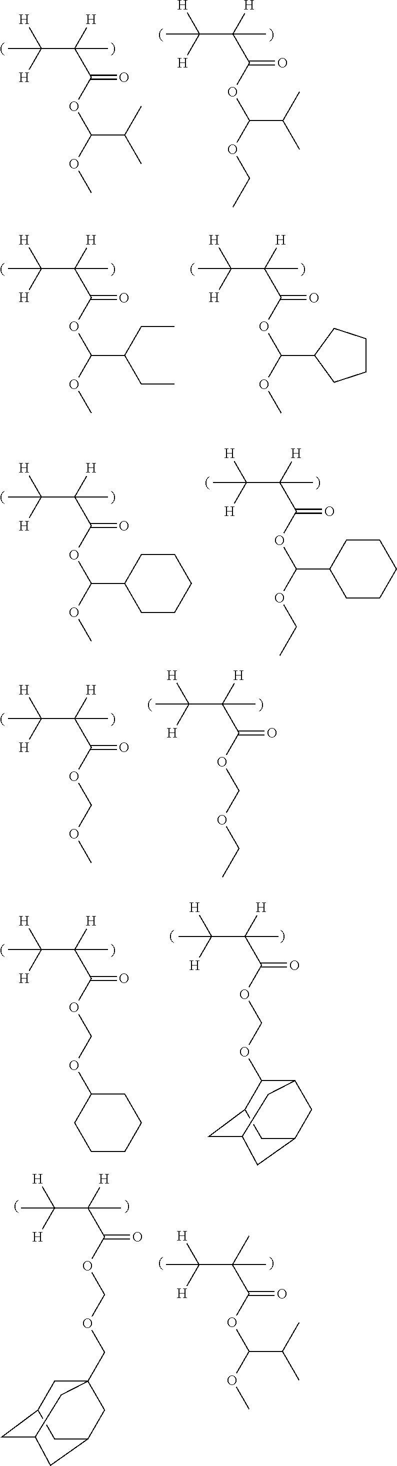

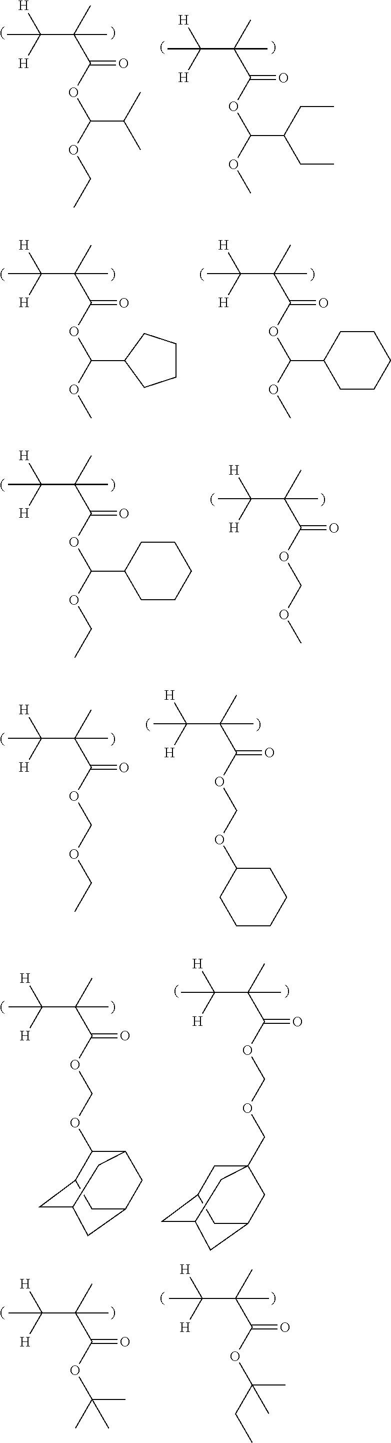

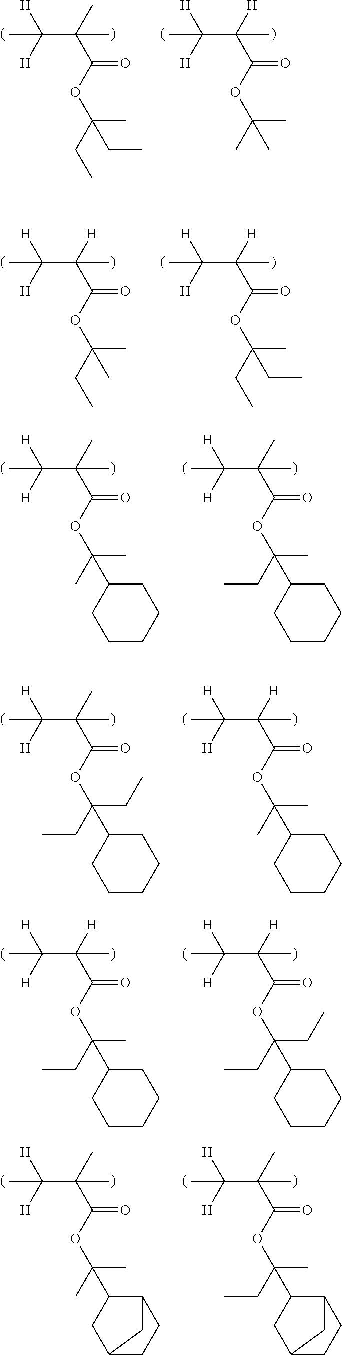

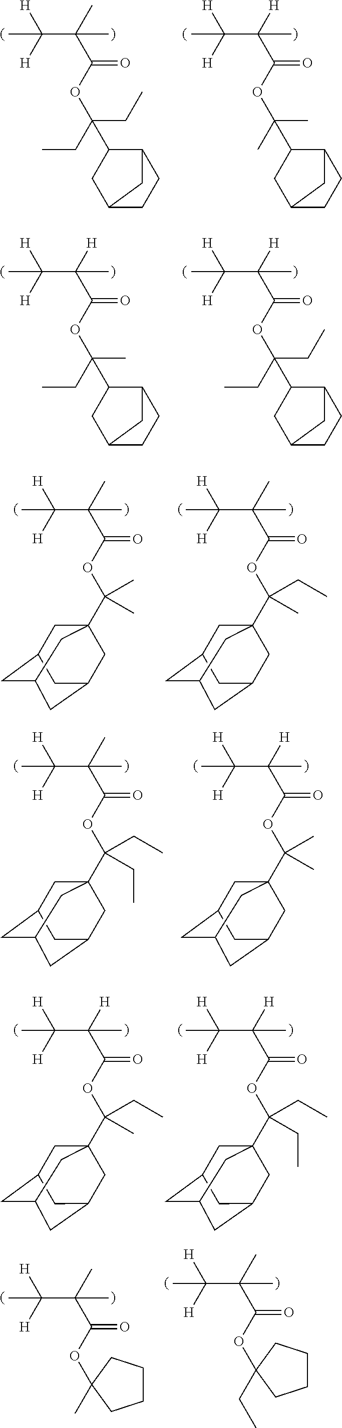

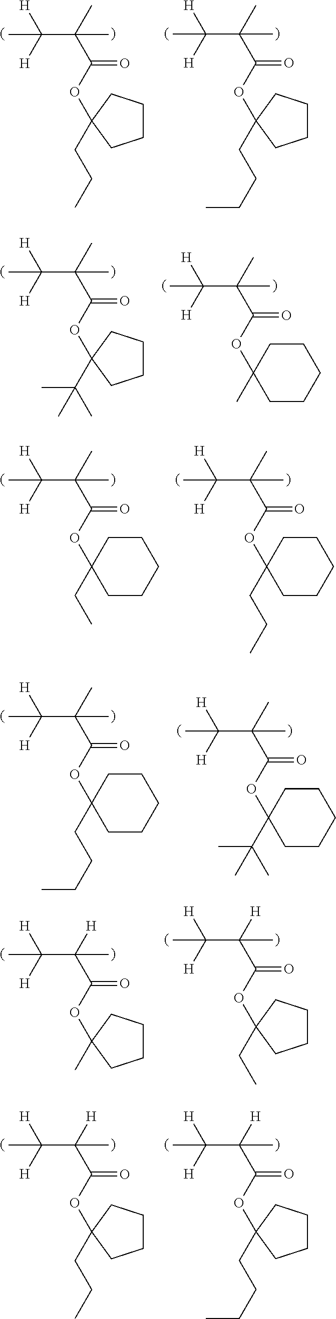

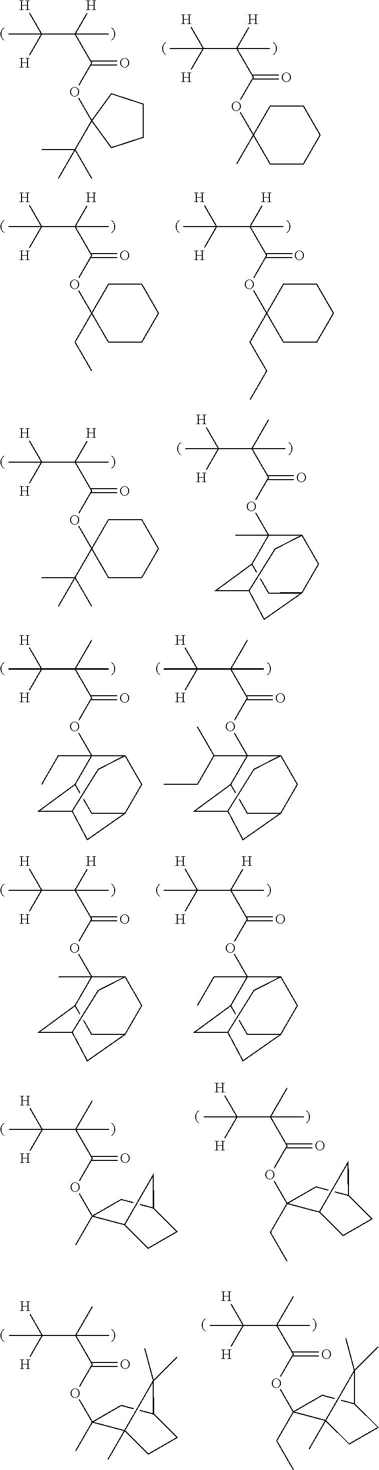

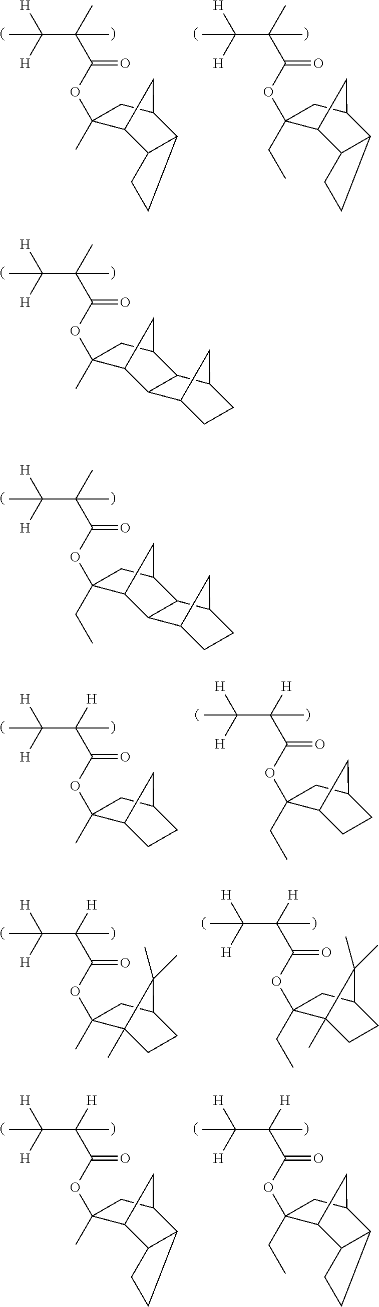

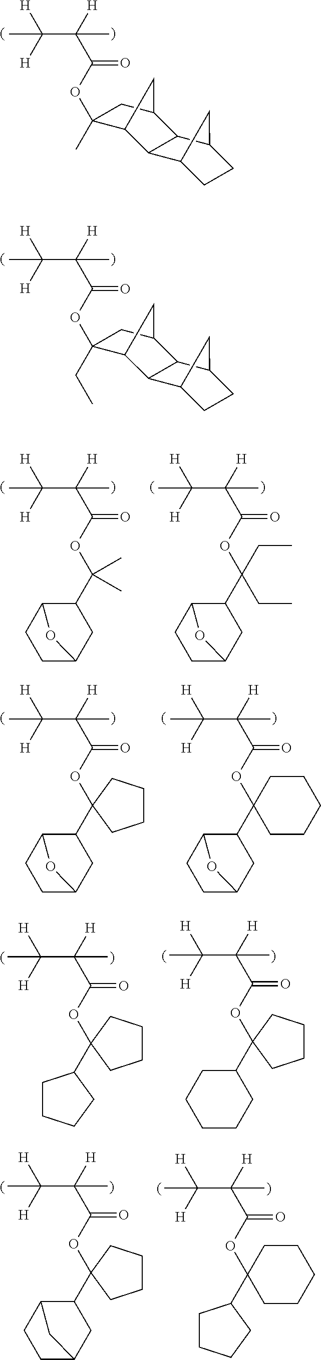

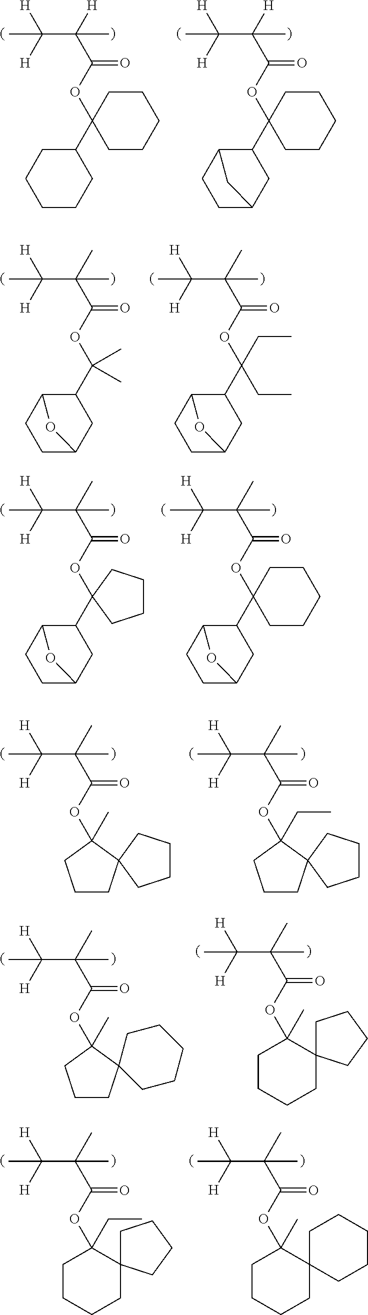

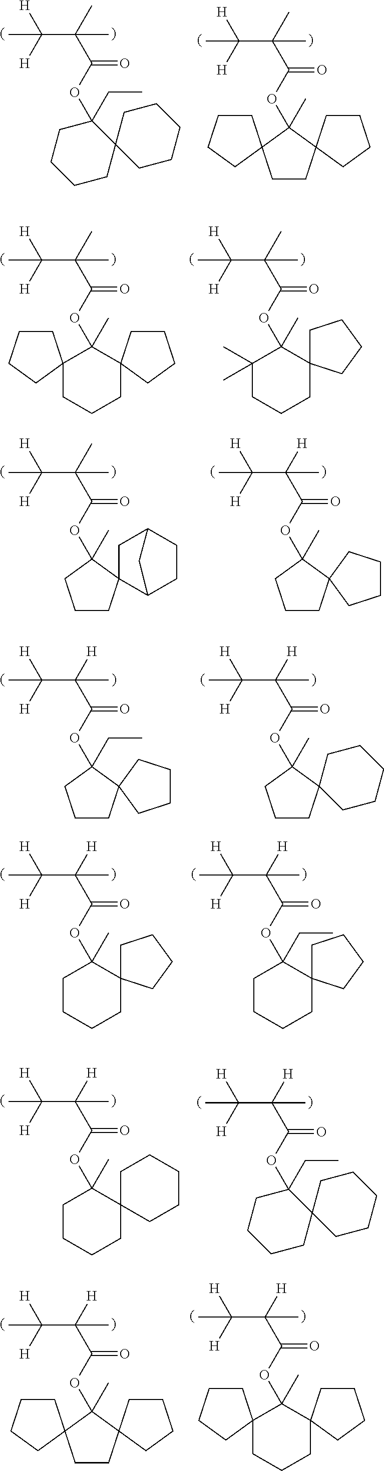

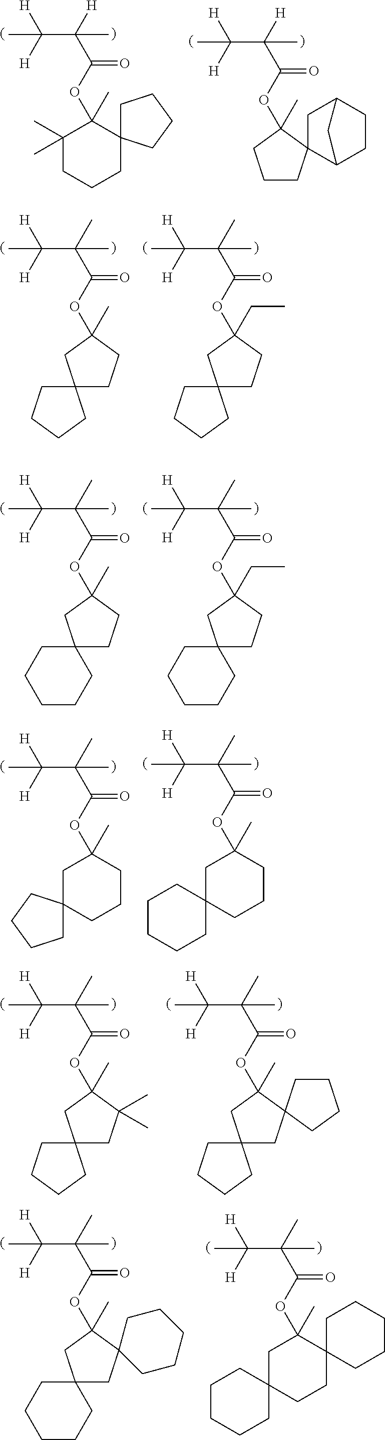

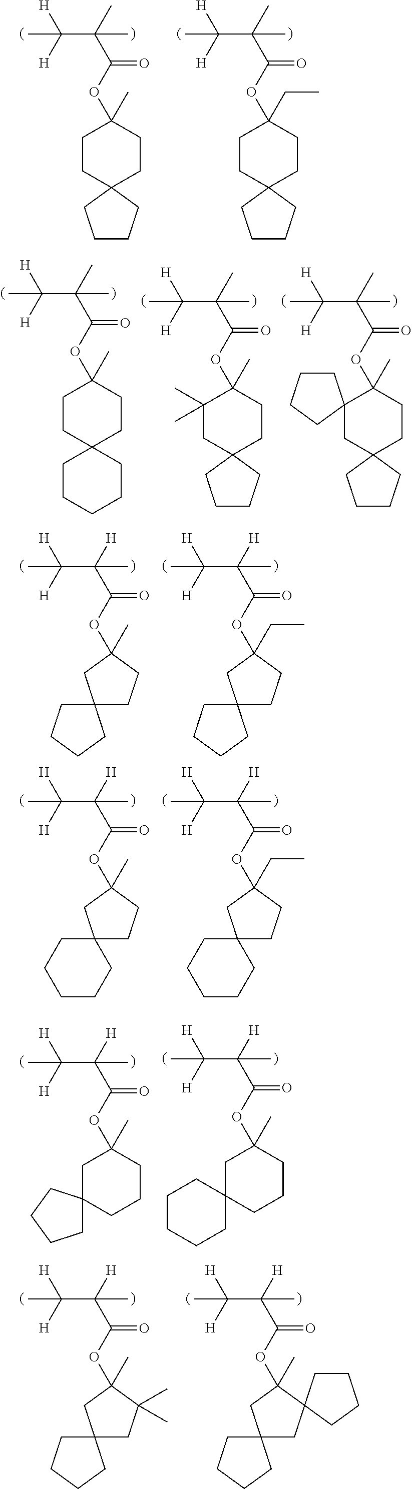

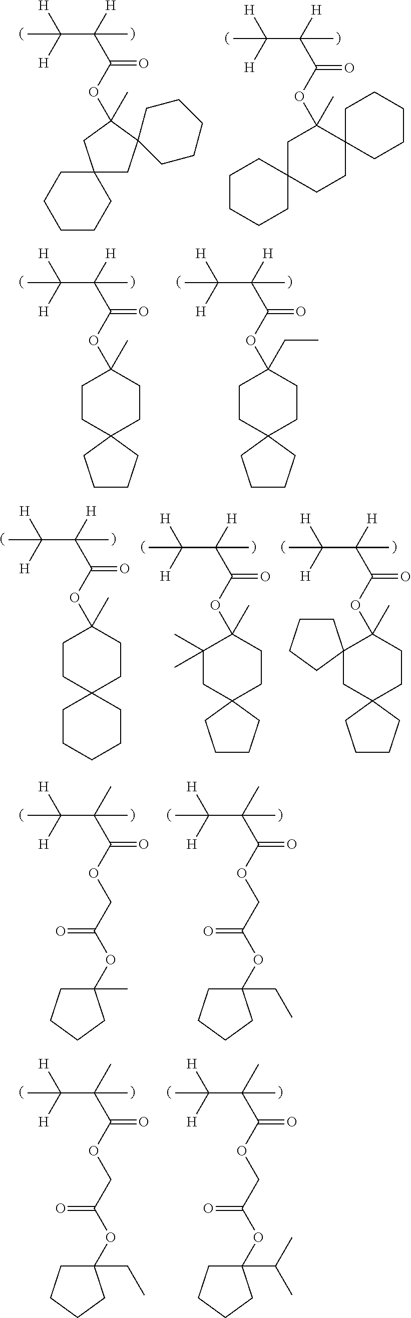

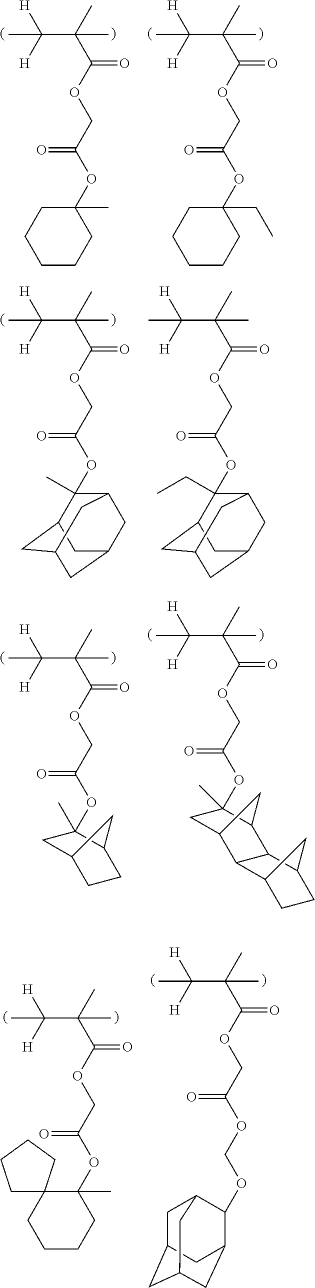

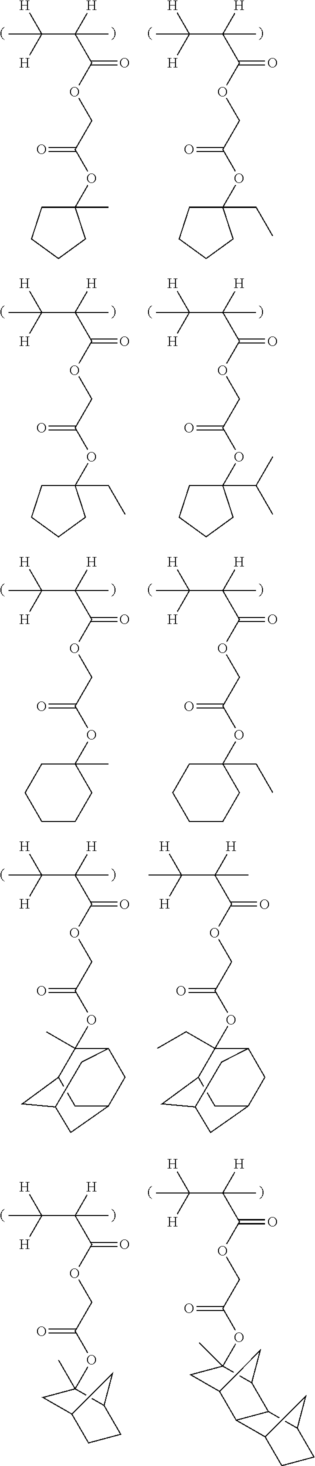

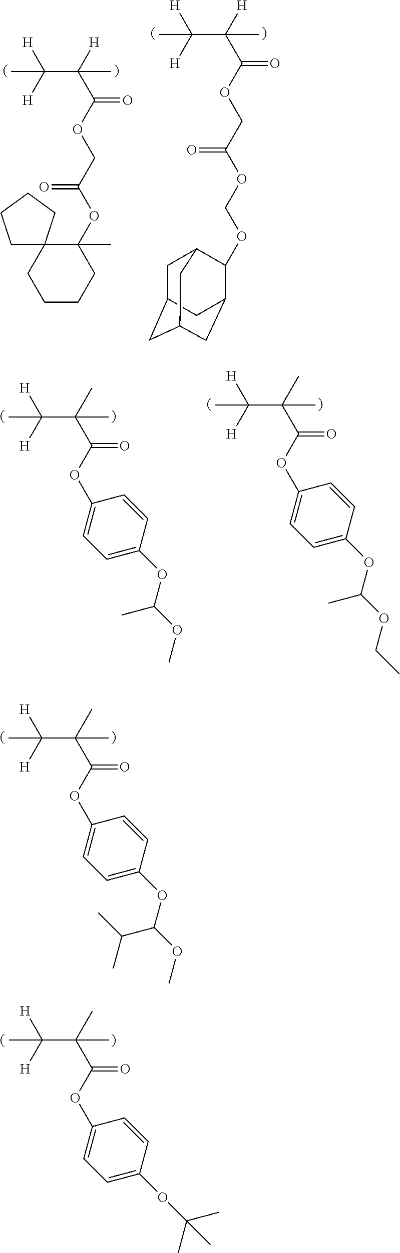

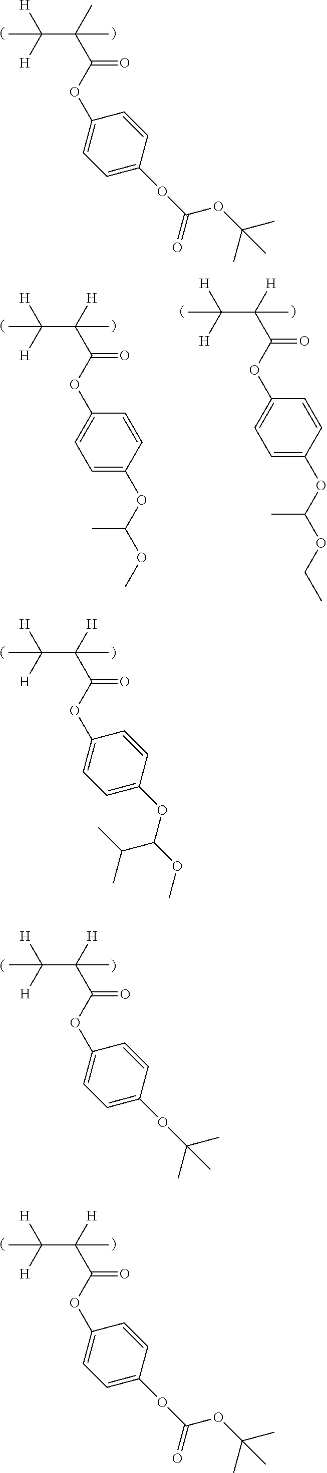

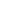

Further, it is desirable that the polymer (A) contained in the positive resist composition of the present invention contains one or more repeating units (a3) each of a structure containing a lactone ring, in addition to the repeating unit (a1) generating an acid of a specific structure as a result that the repeating unit (a1) is sensed to a high-energy radiation, and the acid labile repeating unit (a2). Examples of the repeating unit (a3) specifically include those units shown below, without limited thereto.

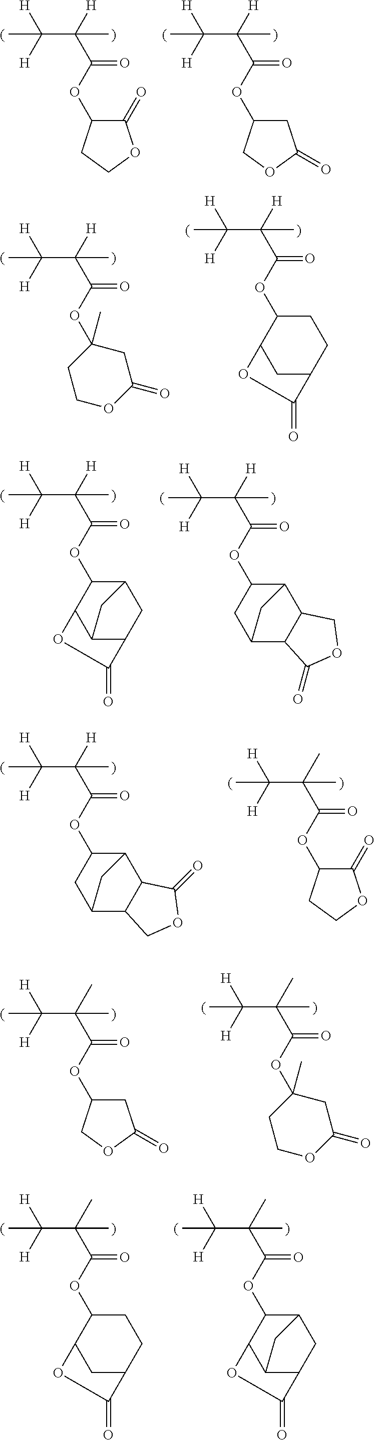

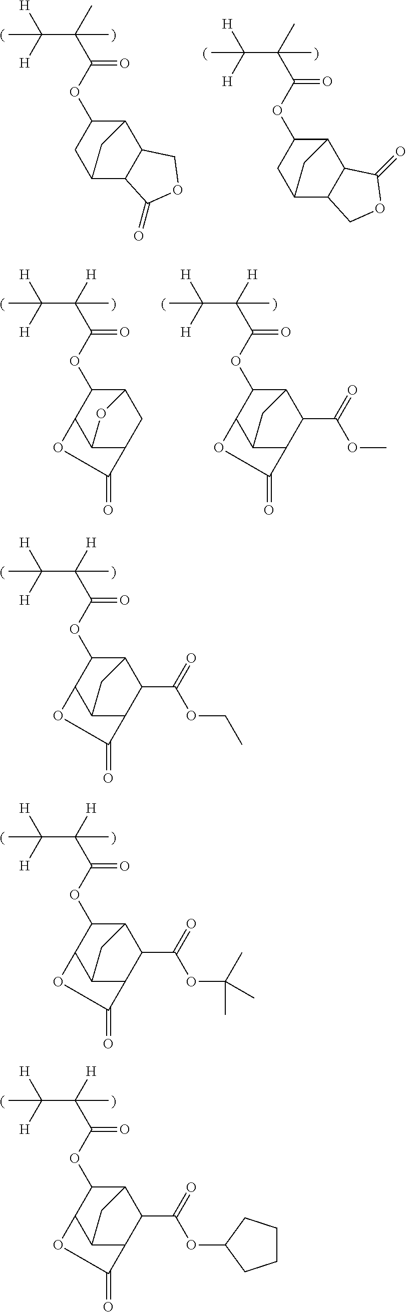

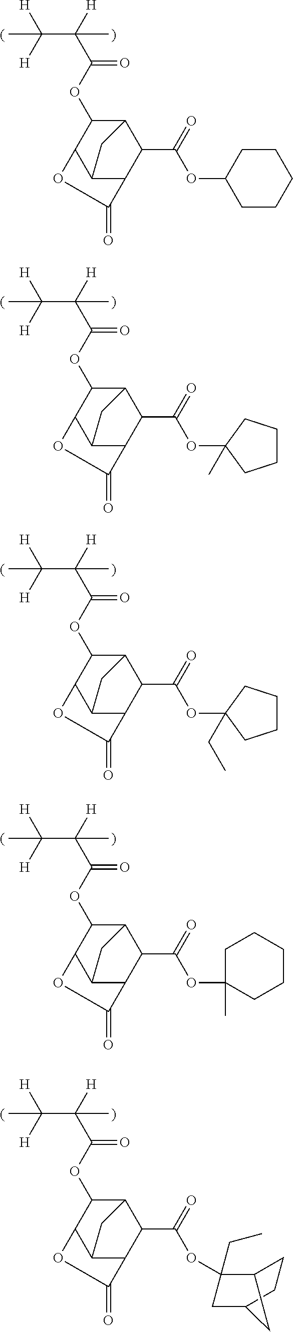

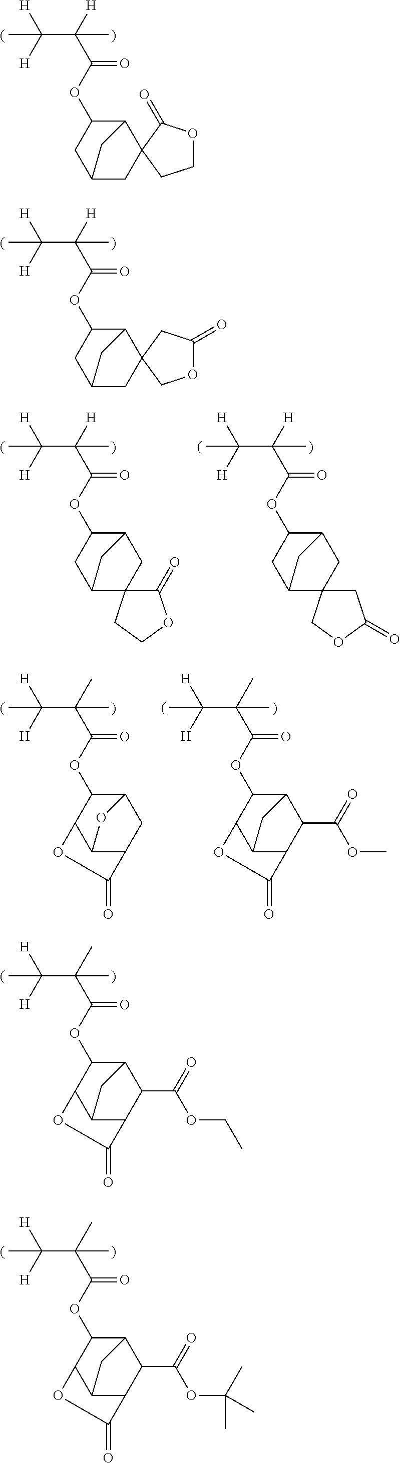

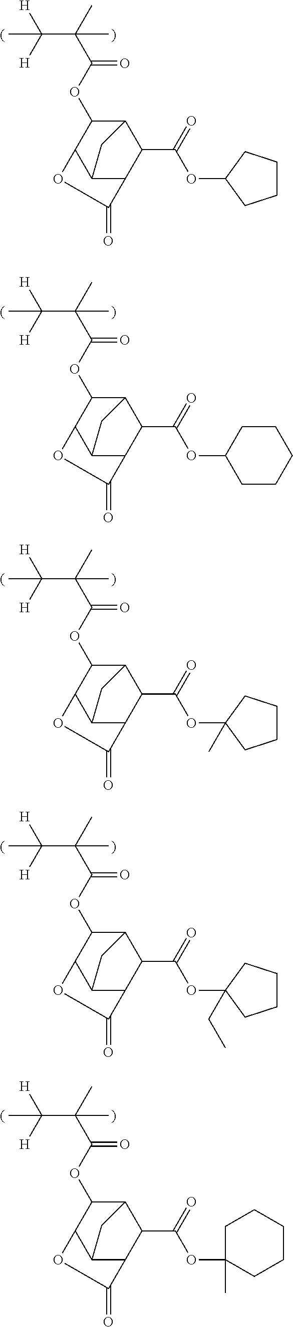

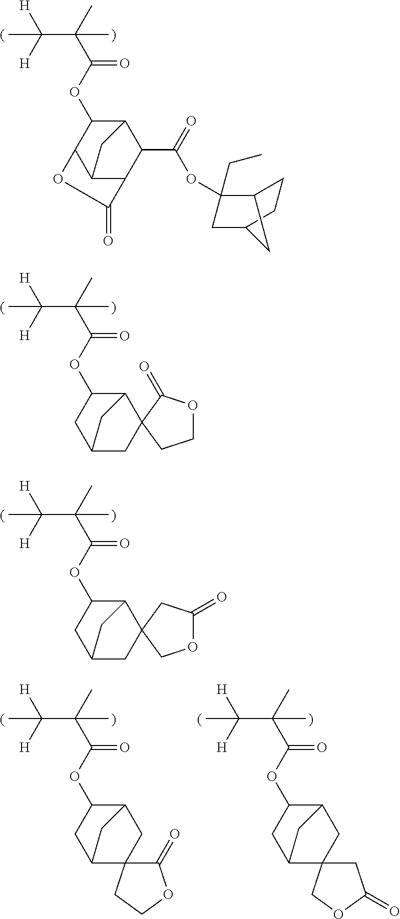

Further, the polymer (A) may contain one or more other repeating units, such as units each containing a hydroxyl group, carboxyl group, fluoroalkyl group, or α-trifluoromethyl alcohol group, as required. Examples of the repeating unit specifically include the following units, without limited thereto:

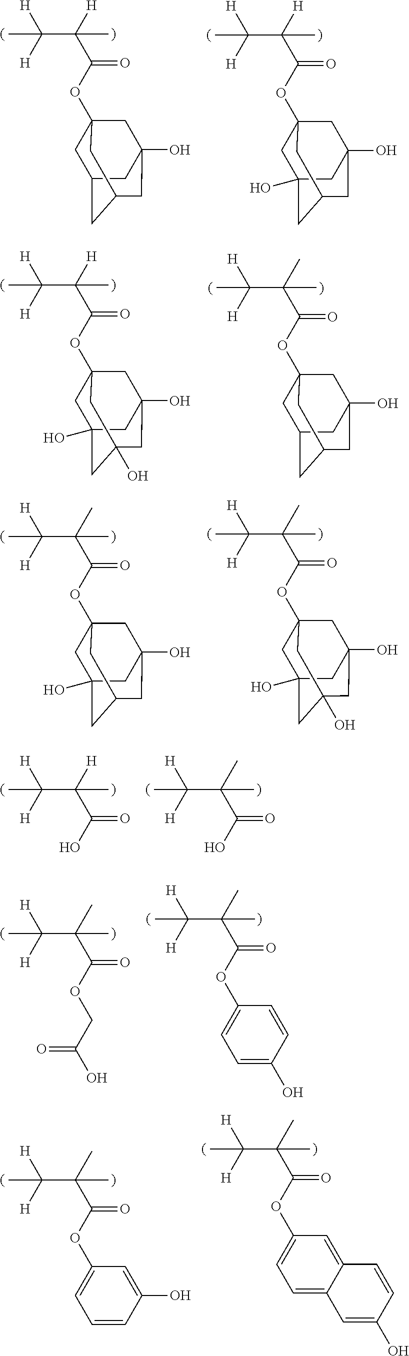

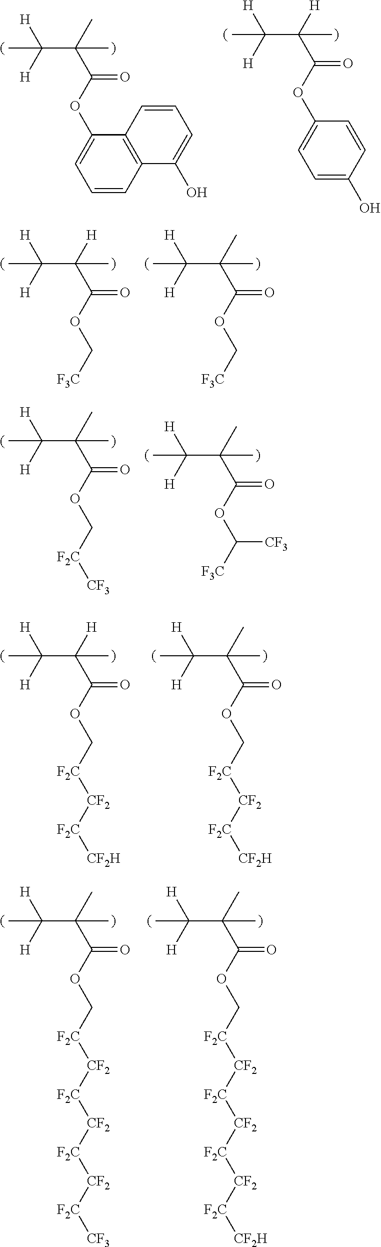

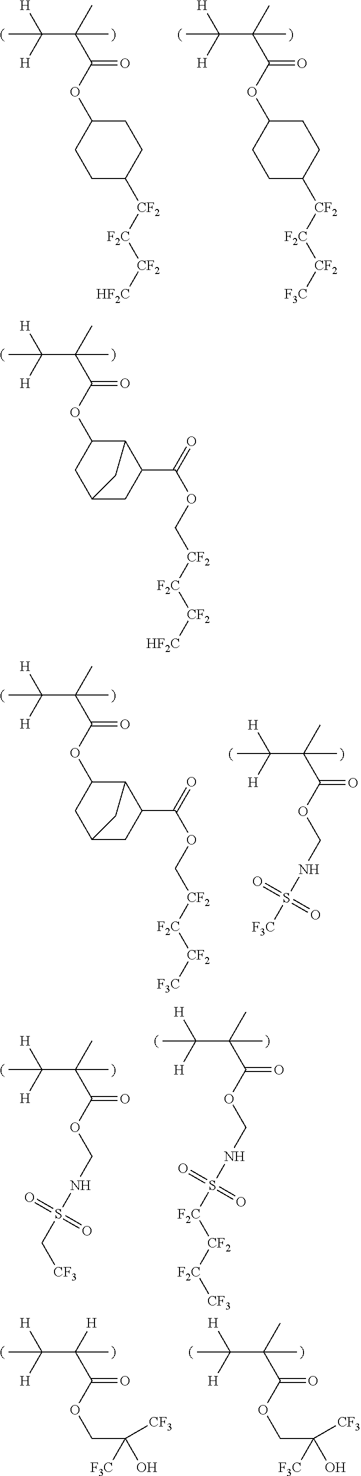

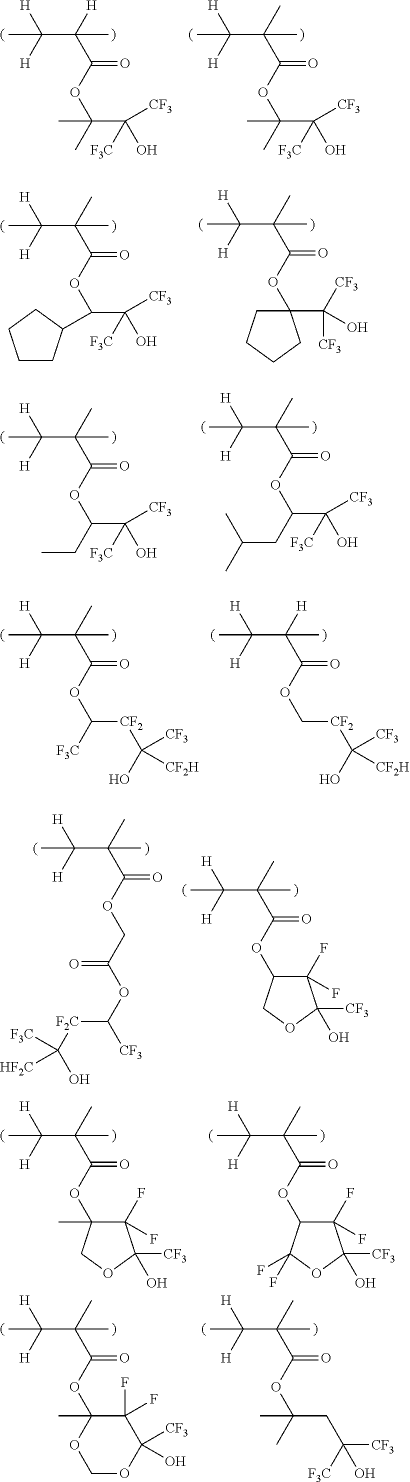

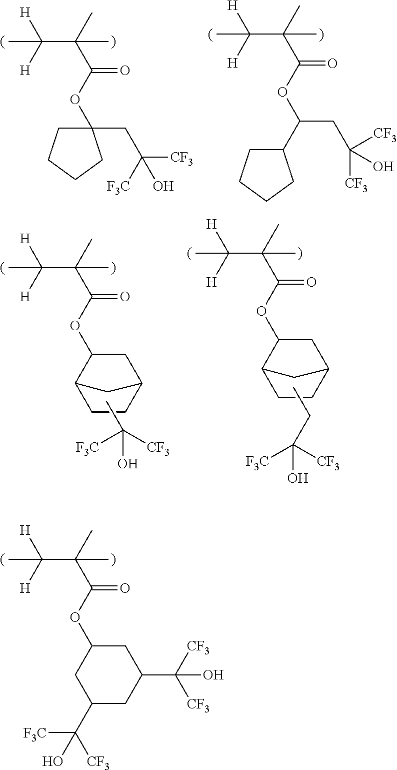

Concerning the composition ratio among the respective repeating units constituting the polymer (A) contained in the positive resist composition of the present invention, preferable is a composition ratio satisfying the following conditions, assuming that: “a” mol % represents a total content ratio of the repeating unit (a1) configured to generate an acid of a structure represented by the above general formula (1) as a result that the repeating unit (a1) is sensed to a high-energy radiation; “b” mol % represents a total content ratio of the acid labile repeating unit (a2); “c” mol % represents a total content ratio of the repeating unit (a3) containing a lactone ring; and “d” mol % represents a total content ratio of other units;

a+b+c+d=100,
1≦a≦10,
0<b≦70,
0≦c≦70, and
0≦d≦30,
particularly,

a+b+c+d=100,
1≦a≦10,
20≦b≦70,
20≦c≦60, and
0≦d≦20.

Concerning the molecular weight of the polymer (A), excessively smaller weight-average molecular weights (Mw) lead to susceptibility of dissolution of the polymer in water, while excessively larger weight-average molecular weights cause deterioration of solubility of the polymer in alkali, coating defects upon spin coating thereof, and the like, with a great possibility.

From that standpoint, it is preferable that the polymer has a weight-average molecular weight of 1,000 to 500,000, preferably 2,000 to 30,000 as determined relative to polystyrene standards in gel permeation chromatography (GPC).

The positive resist composition of the present invention is characterized in that the same contains the onium sulfonate (B) represented by the following general formula (2), in addition to the polymer (A):

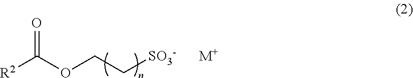

wherein

R² represents a monovalent hydrocarbon group, which may contain a heteroatom;

n represents an integer of 1 to 3; and

M⁺ represents a counter cation having a substituent, and represents a sulfonium cation, iodonium cation, or ammonium cation.

Examples of the monovalent hydrocarbon group in the formula (2), which is represented by R² and which may contain a heteroatom, specifically include: a methyl group, ethyl group, propyl group, isopropyl group, n-butyl group, sec-butyl group, tert-butyl group, tert-amyl group, n-pentyl group, n-hexyl group, cyclopentyl group, cyclohexyl group, ethylcyclopentyl group, butylcyclopentyl group, ethylcyclohexyl group, butylcyclohexyl group, adamantyl group, ethyladamantyl group, butyladamantyl group, aryl group, aralkyl group, alkenyl group; those groups each obtained by inserting, between an arbitrary carbon-carbon bond of one of the above mentioned groups, a heteroatom group such as —O—, —S—, —SO—, —SO₂—, —NH—, —C(═O)—, —C(═O)O—, —C(═O)NH—, or the like; and those groups each obtained by substituting an arbitrary hydrogen atom(s) of one of the above mentioned groups, with a functional group such as —OH, —NH₂, —CHO, —CO₂H, or the like. M⁺ represents a counter cation having a substituent, and represents a sulfonium cation, iodonium cation, or ammonium cation, i.e., represents a counter cation which has a substituent and the central atom of which is sulfur, iodine, or nitrogen.

Particularly preferable as such an onium sulfonate (B) are a sulfonium sulfonate, iodonium sulfonate, and ammonium sulfonate, represented by the following general formulae (6), (7), and (8), respectively:

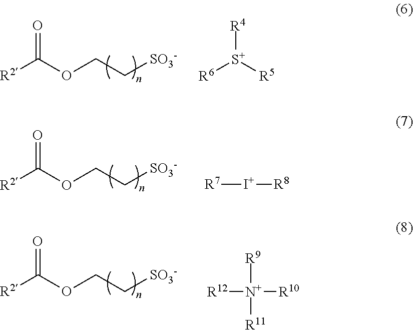

wherein

R²′ represents a straight, branched, or cyclic alkyl group having 1 to 50 carbon atoms which may contain a heteroatom;

n represents the same meaning as before;

each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;

wherein any two or more of R⁴, R⁵, and R⁶ may bond to each other to form a ring together with a sulfur atom in the formula;

each R⁷ and R⁸ independently represent a substituted or unsubstituted aryl group having 6 to 18 carbon atoms; and

each R⁹, R¹⁰, R¹¹, and R¹² independently represent: a substituted or unsubstituted straight, branched, or cyclic alkyl group, alkenyl group, or oxoalkyl group having 1 to 18 carbon atoms, which group may contain a heteroatom; or a substituted or unsubstituted aryl group, aralkyl group, or aryloxoalkyl group having 6 to 18 carbon atoms;

wherein any two or more of R⁹, R¹⁰, R¹¹, and R¹² may bond to each other to form a ring together with a nitrogen atom in the formula.

The alkyl groups, alkenyl groups, oxoalkyl groups, aryl groups, aralkyl groups, and aryloxoalkyl groups exemplified as R⁴ to R⁶, and R⁹ to R¹², are the same as those exemplified for the general formula (4). The aryl groups exemplified as R⁷ and R⁸ are the same as those exemplified for the general formula (5).

Shown below are specific examples of the onium sultanates (B) represented by the general formulae (6), (7), and (8):

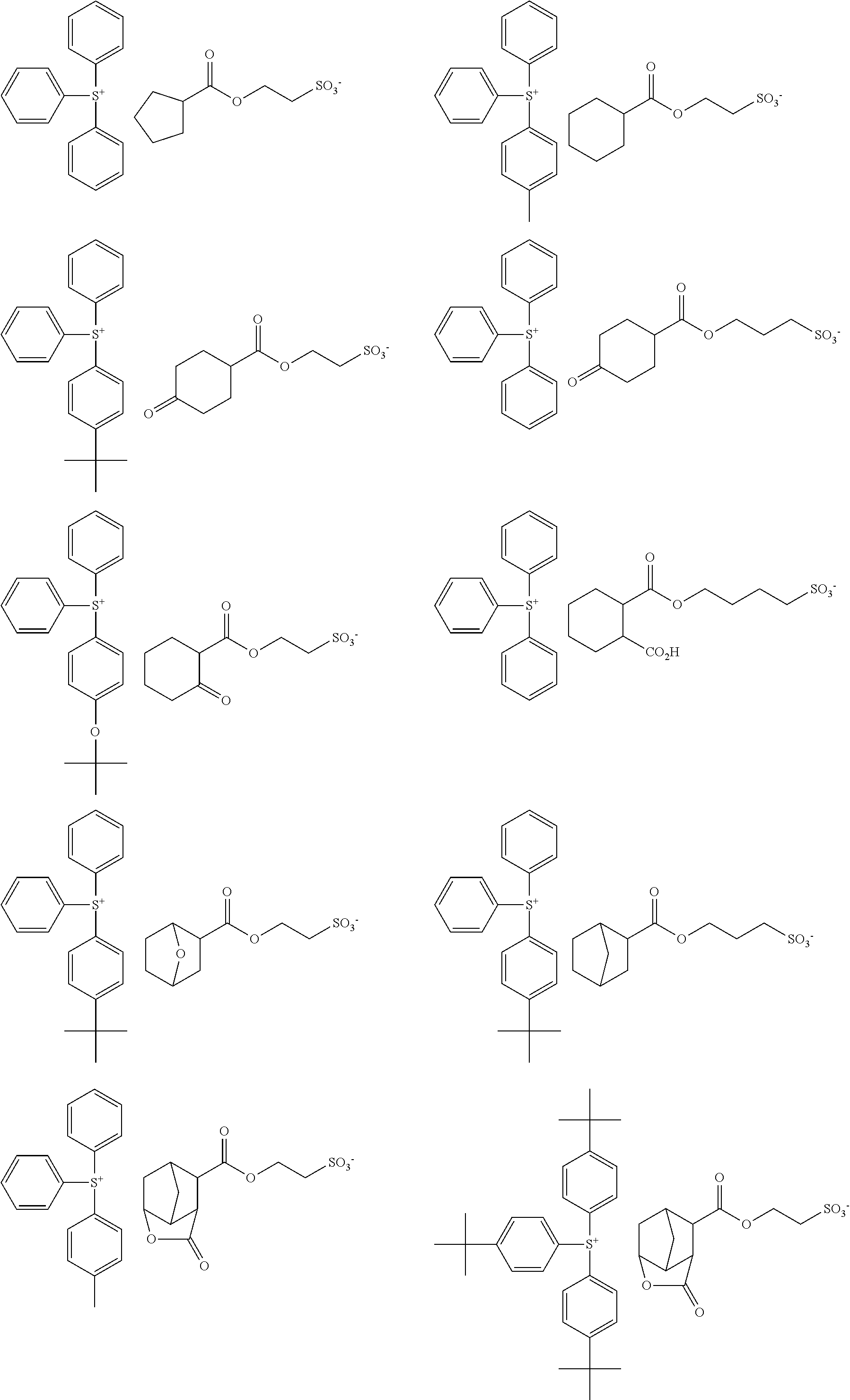

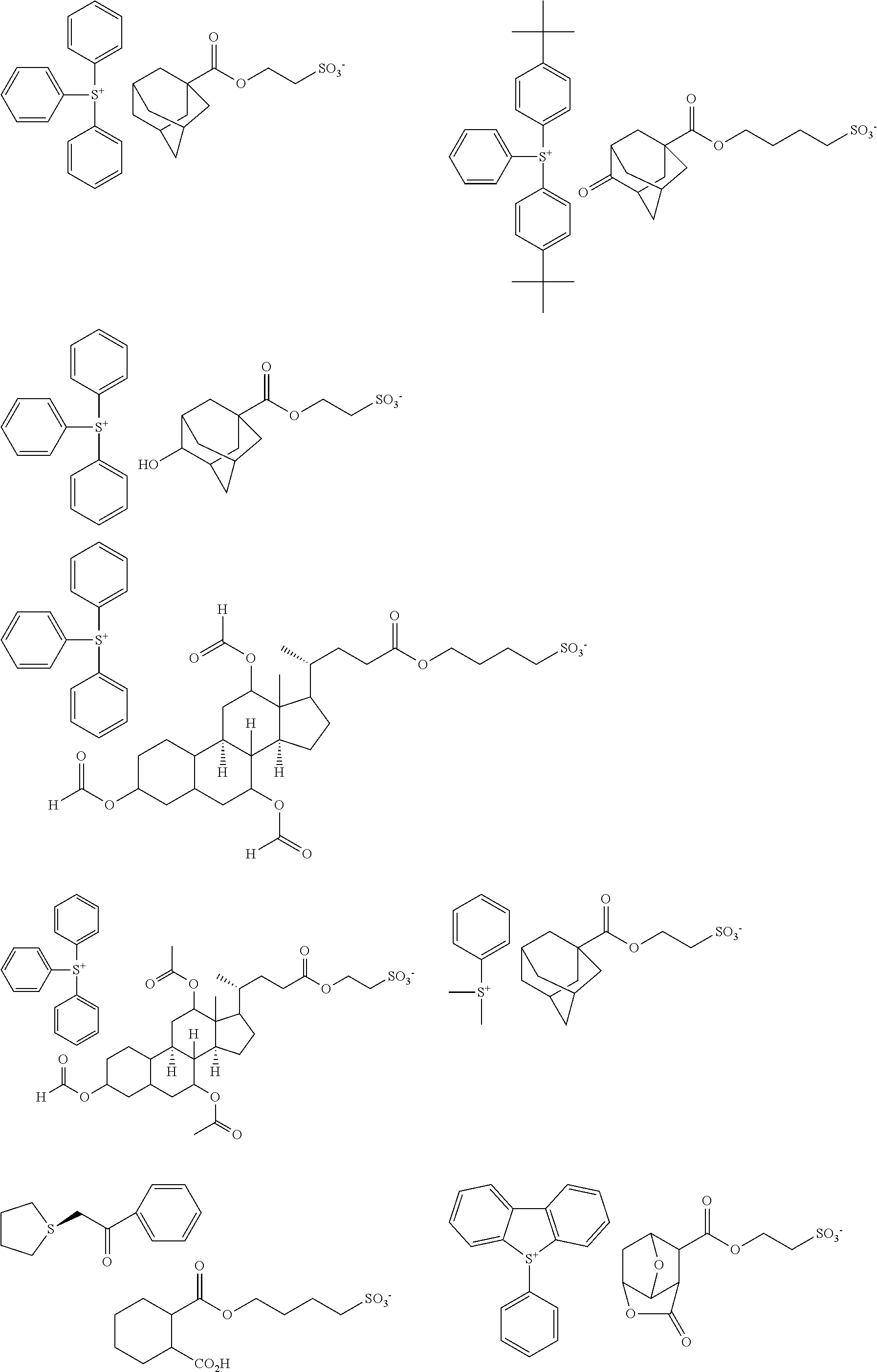

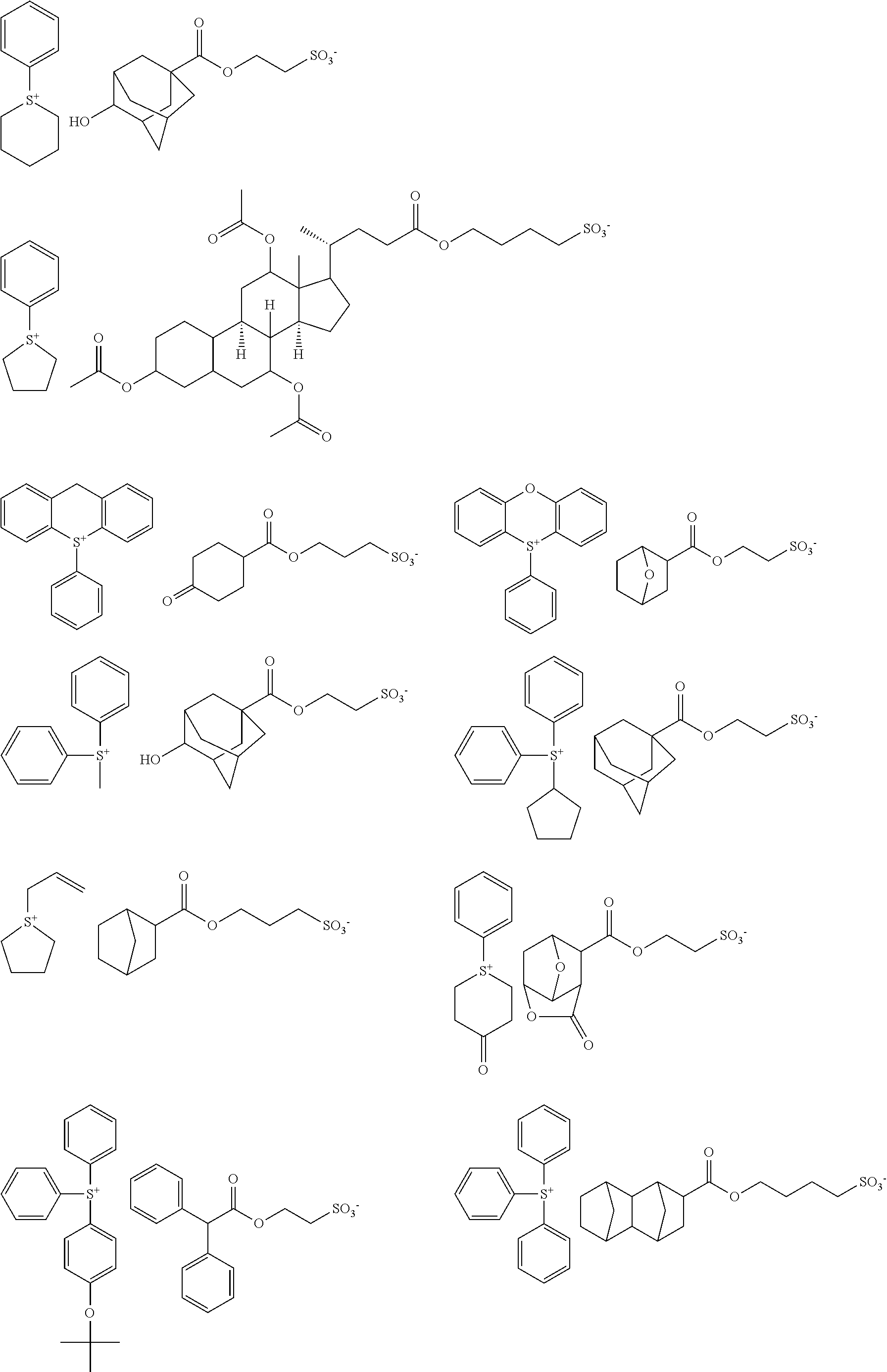

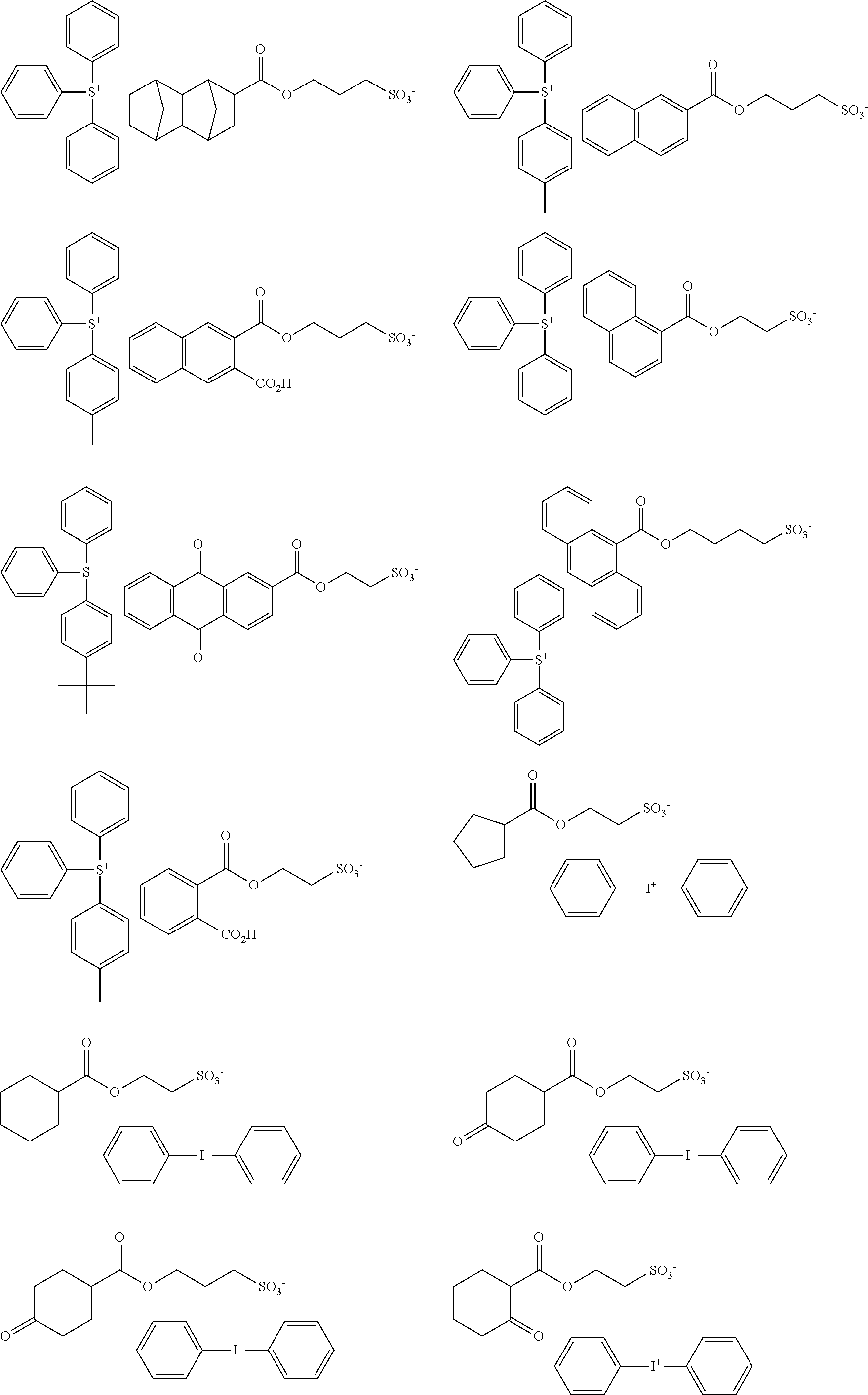

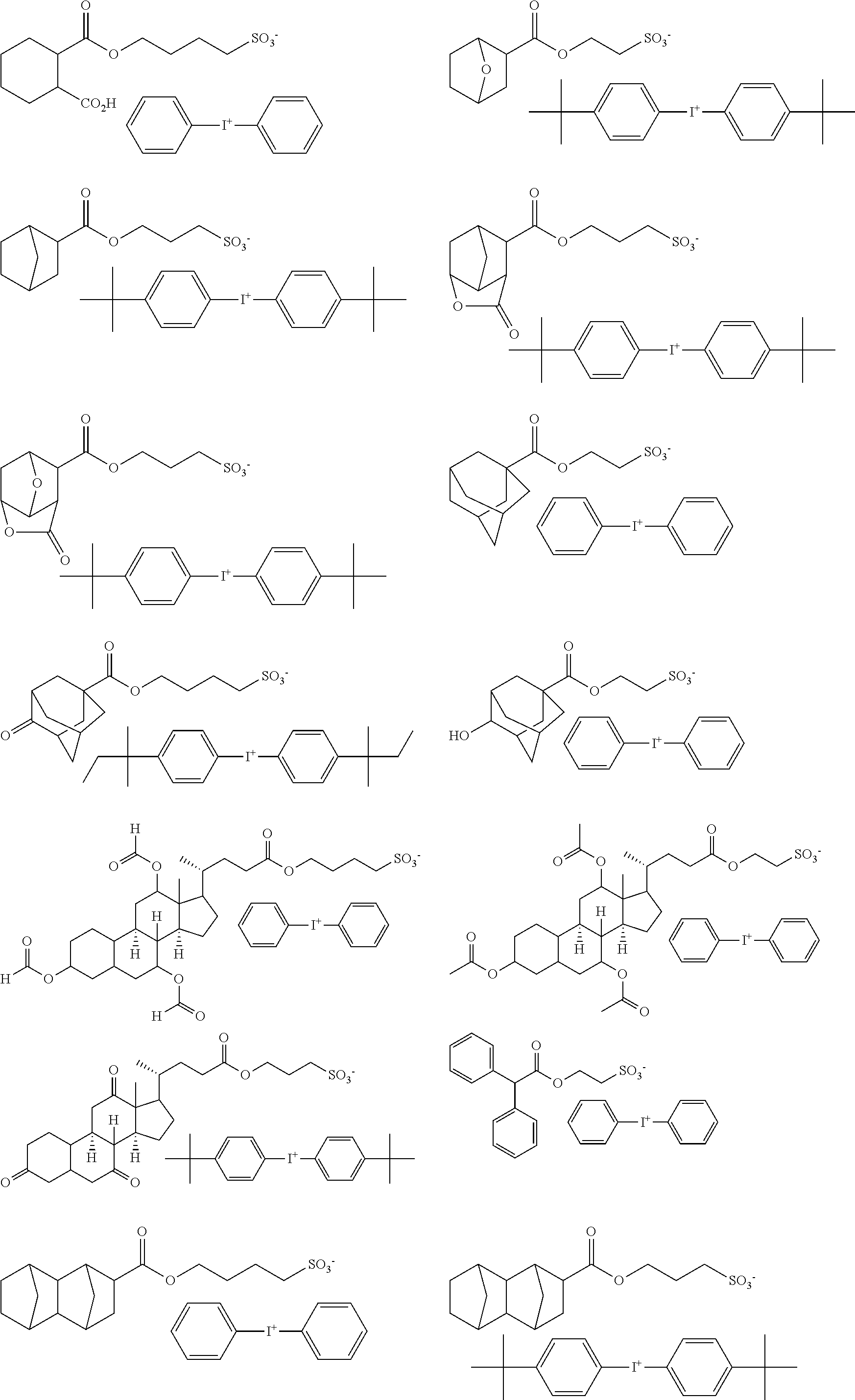

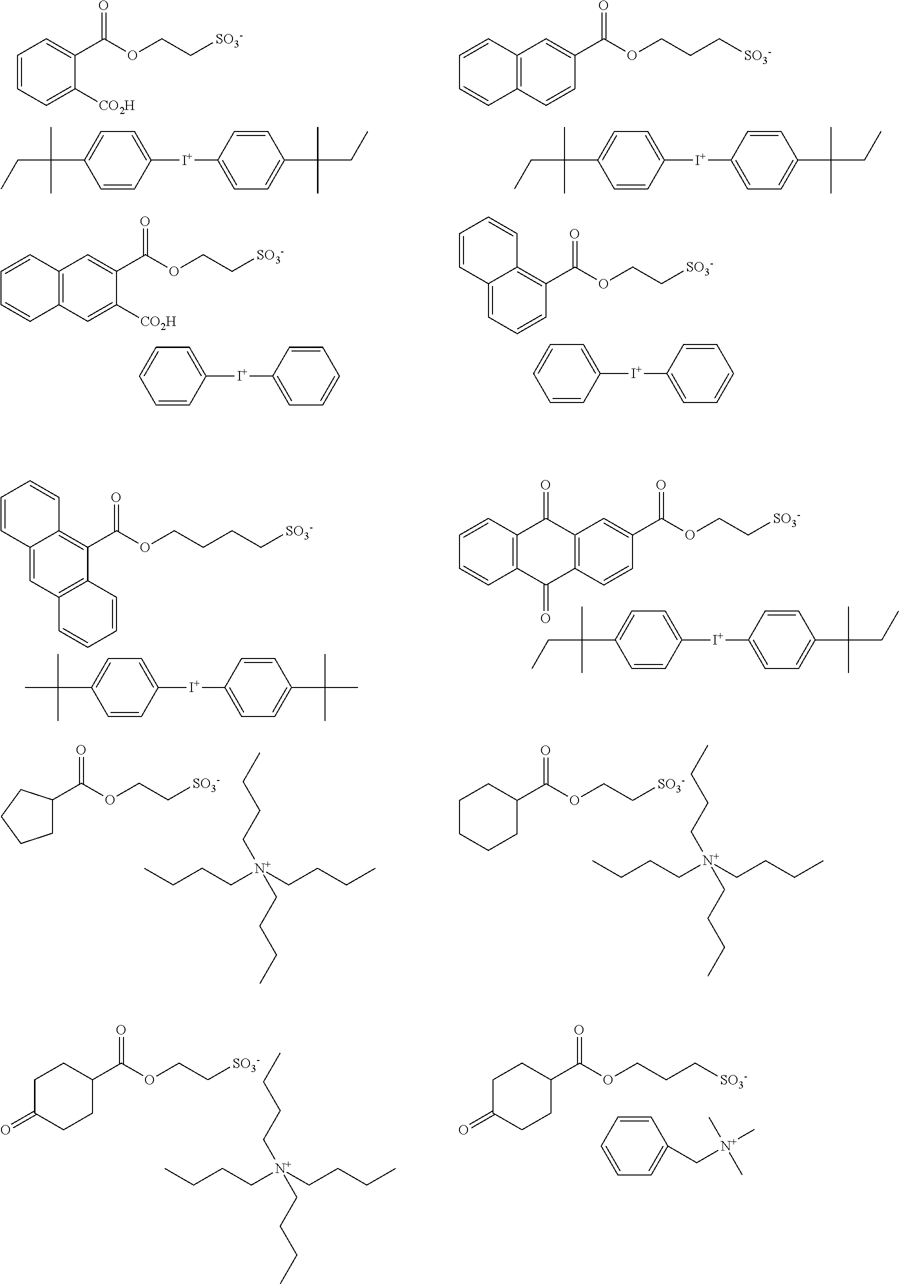

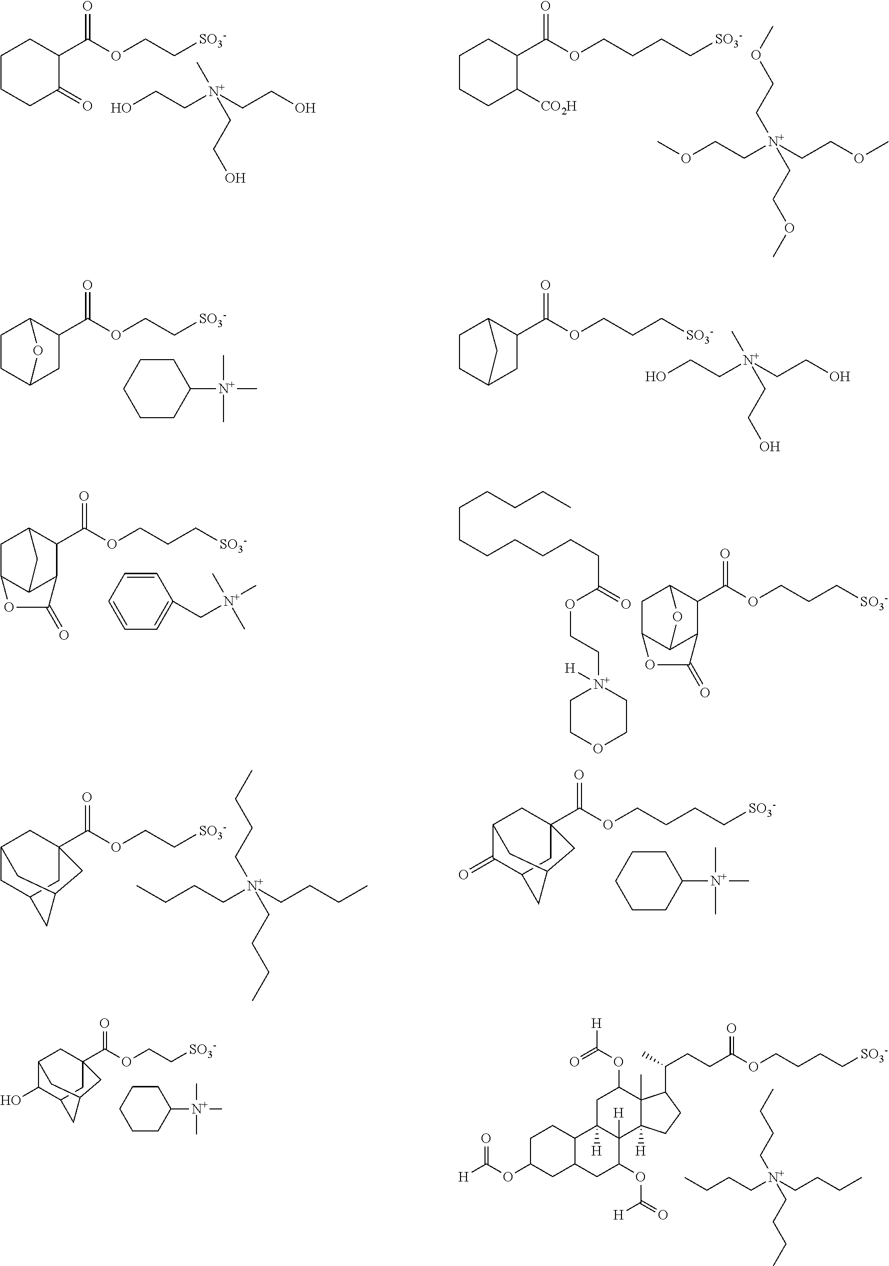

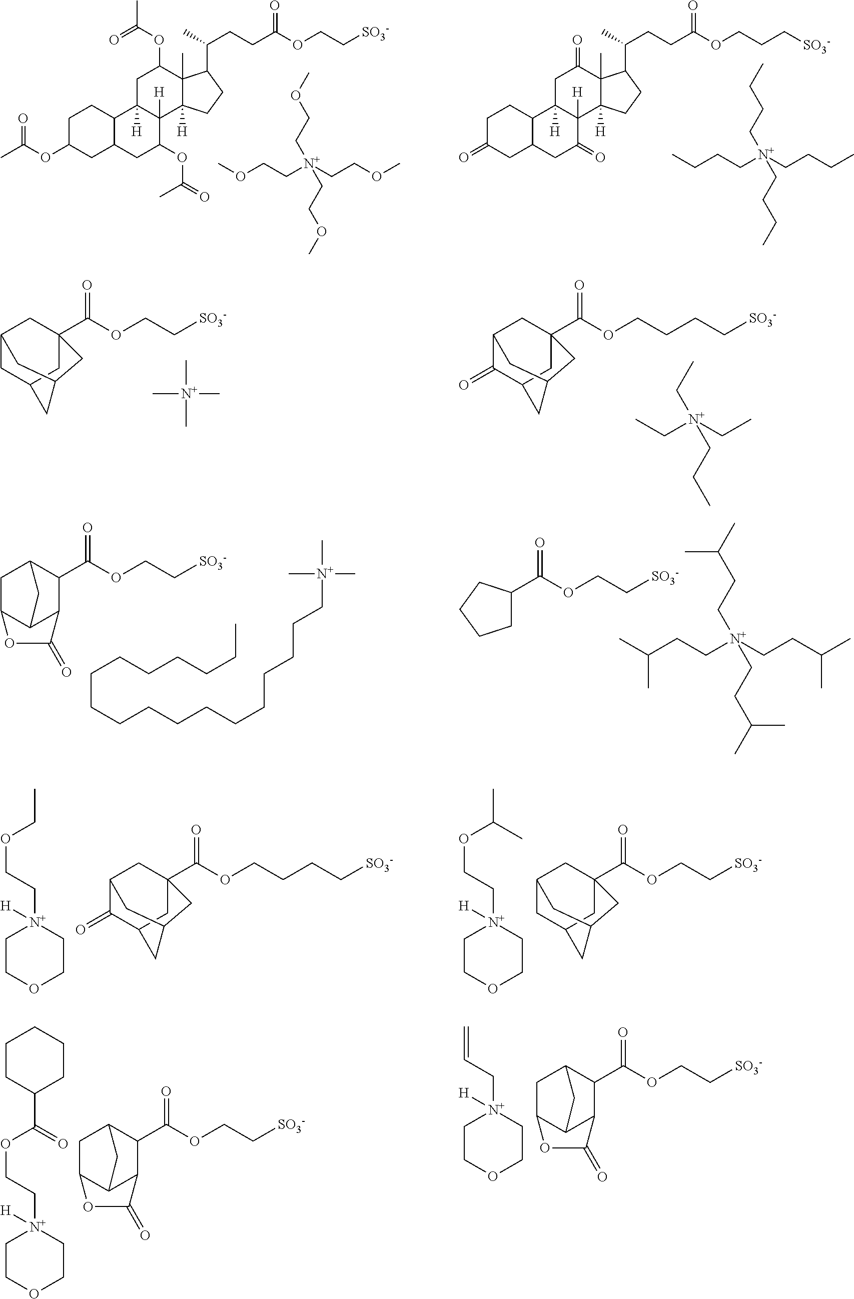

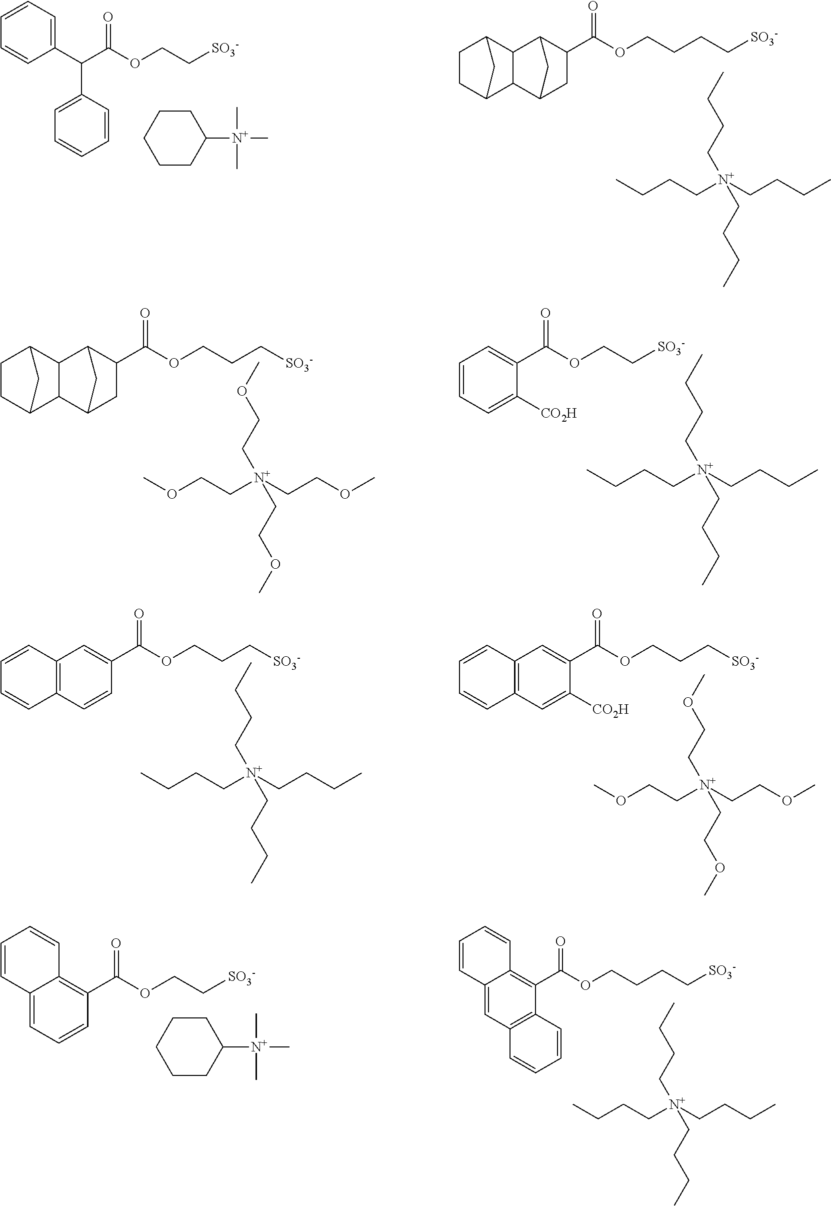

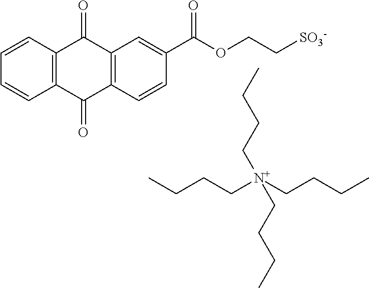

The onium sulfonate (B) is to preferably have a content of 1 to 15 mass parts, particularly 1 to 10 mass parts, relative to 100 mass parts of the polymer (A).

The positive resist composition proposed by the present invention may contain another resin component, in addition to the polymer (A). For example, examples thereof include polymers represented by the formula (R1) and/or formula (R2) and each having a weight-average molecular weight of 1,000 to 100,000, preferably 3,000 to 30,000 determined relative to polystyrene standards by GPC, without limited thereto:

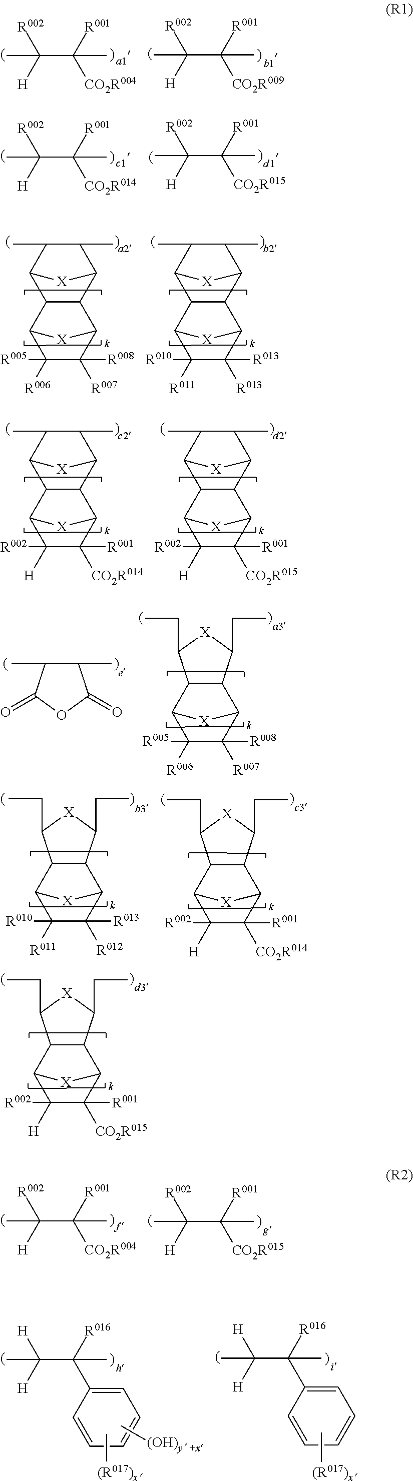

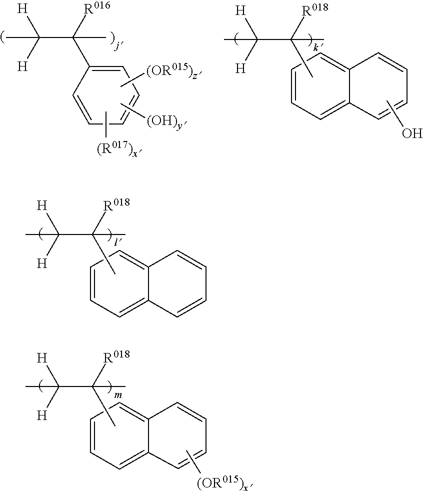

In the above formulae, R⁰⁰¹ represents a hydrogen atom, methyl group, or —CH₂CO₂R⁰⁰³. R⁰⁰² represents a hydrogen atom, methyl group, or —CO₂R⁰⁰³. R⁰⁰³ represents a straight, branched, or cyclic alkyl group having 1 to 15 carbon atoms, and examples thereof specifically include a methyl group, ethyl group, propyl group, isopropyl group, n-butyl group, sec-butyl group, tert-butyl group, tert-amyl group, n-pentyl group, n-hexyl group, cyclopentyl group, cyclohexyl group, ethylcyclopentyl group, butylcyclopentyl group, ethylcyclohexyl group, butylcyclohexyl group, adamantyl group, ethyladamantyl group, butyladamantyl group, and the like.

R⁰⁰⁴ represents a hydrogen atom, or a monovalent hydrocarbon group having 1 to 15 carbon atoms and containing a fluorine-containing substituent, a carboxyl group, or a hydroxyl group, and examples of this group specifically include: a hydrogen atom, carboxyethyl, carboxybutyl, carboxycyclopentyl, carboxycyclohexyl, carboxynorbornyl, carboxyadamantyl, hydroxyethyl, hydroxybutyl, hydroxycyclopentyl, hydroxycyclohexyl, hydroxynorbornyl, hydroxyadamantyl, hydroxyhexafluoro-isopropylcyclohexyl, di(hydroxyhexafluoro-isopropyl)cyclohexyl groups, and the like.

At least one of R⁰⁰⁵ to R⁰⁰⁸ represents a monovalent hydrocarbon group having 1 to 15 carbon atoms and containing a fluorine-containing substituent, a carboxyl group, or a hydroxyl group, and the remainders each independently represent a hydrogen atom, or a straight, branched, or cyclic alkyl group having 1 to 15 carbon atoms. Examples of the monovalent hydrocarbon group having 1 to 15 carbon atoms and containing a fluorine-containing substituent, a carboxyl group, or a hydroxyl group, specifically include carboxy, carboxymethyl, carboxyethyl, carboxybutyl, hydroxymethyl, hydroxyethyl, hydroxybutyl, 2-carboxyethoxycarbonyl, 4-carboxybutoxycarbonyl, 2-hydroxyethoxycarbonyl, 4-hydroxybutoxycarbonyl, carboxycyclopentyloxycarbonyl, carboxycyclohexyloxycarbonyl, carboxynorbornyloxycarbonyl, carboxyadamantyloxycarbonyl, hydroxycyclopentyloxycarbonyl, hydroxycyclohexyloxycarbonyl, hydroxynorbornyloxycarbonyl, hydroxyadamantyloxycarbonyl, hydroxyhexafluoroisopropyl-cyclohexyloxycarbonyl, di(hydroxyhexafluoro-isopropyl)cyclohexyloxycarbonyl groups, and the like. Examples of the straight, branched, or cyclic alkyl group having 1 to 15 carbon atoms specifically include the same groups as those exemplified for R⁰⁰³.

Two of R⁰⁰⁵ to R⁰⁰⁸ (for example, R⁰⁰⁵ and R⁰⁰⁶, R⁰⁰⁶ and R⁰⁰⁷) may bond to each other in a manner to form a ring together with carbon atoms to which these groups are bonded, and in that case, at least one of R⁰⁰⁵ to R⁰⁰⁸ forming the ring represents a divalent hydrocarbon group having 1 to 15 carbon atoms and containing a fluorine-containing substituent, carboxyl group, or hydroxyl group, and the remainders each represent a single bond, or a straight, branched, or cyclic alkylene group having 1 to 15 carbon atoms. Examples of the divalent hydrocarbon group having 1 to 15 carbon atoms and containing a fluorine-containing substituent, carboxyl group, or hydroxyl group, specifically include those each obtained by eliminating one hydrogen atom from each of those examples mentioned above for the monovalent hydrocarbon group containing a fluorine-containing substituent, a carboxyl group, or a hydroxyl group, and the like. Examples of the straight, branched, or cyclic alkylene group having 1 to 15 carbon atoms specifically include those each obtained by eliminating one hydrogen atom from each of those examples mentioned for R⁰⁰³, and the like.

R⁰⁰⁹ represents a monovalent hydrocarbon group having 3 to 15 carbon atoms and having a —CO₂— partial structure, and examples thereof specifically include 2-oxooxolane-3-yl, 4,4-dimethyl-2-oxooxolane-3-yl, 4-methyl-2-oxooxane-4-yl, 2-oxo-1,3-dioxolane-4-ylmethyl, 5-methyl-2-oxooxolane-5-yl groups, and the like.

At least one of R⁰¹⁰ to R⁰¹³ represents a monovalent hydrocarbon group having 2 to 15 carbon atoms and having a —CO₂— partial structure, and the remainders each independently represent a hydrogen atom, or a straight, branched, or cyclic alkyl group having 2 to 15 carbon atoms. Examples of the monovalent hydrocarbon group having 2 to 15 carbon atoms and having a —CO₂— partial structure specifically include 2-oxooxolane-3-yloxycarbonyl, 4,4-dimethyl-2-oxooxolane-3-yloxycarbonyl, 4-methyl-2-oxooxane-4-yloxycarbonyl, 2-oxo-1,3-dioxolane-4-ylmethyloxycarbonyl, 5-methyl-2-oxooxolane-5-yloxycarbonyl groups, and the like. Examples of the straight, branched, or cyclic alkyl group having 1 to 15 carbon atoms specifically include the same groups as those exemplified for R⁰⁰³.

Two of R⁰¹⁰ to R⁰¹³ (for example, R⁰¹⁰ and R⁰¹¹, R⁰¹¹ and R⁰¹²) may bond to each other in a manner to form a ring together with carbon atoms to which these groups are bonded, and in that case, at least one of R⁰¹⁰ to R⁰¹³ forming the ring represents a divalent hydrocarbon group having 1 to 15 carbon atoms and having a —CO₂— partial structure, and the remainders each independently represent a single bond, or a straight, branched, or cyclic alkylene group having 1 to 15 carbon atoms. Examples of the divalent hydrocarbon group having 1 to 15 carbon atoms and having a —CO₂— partial structure, specifically include: 1-oxo-2-oxapropan-1,3-diyl, 1,3-dioxo-2-oxapropan-1,3-diyl, 1-oxo-2-oxabutan-1,4-diyl 1,3-dioxo-2-oxabutan-1,4-diyl groups, and the like; as well as those each obtained by eliminating one hydrogen atom from each of those examples mentioned above for the monovalent hydrocarbon group having a —CO₂— partial structure, and the like. Examples of the straight, branched, or cyclic alkylene group having 1 to 15 carbon atoms specifically include those each obtained by eliminating one hydrogen atom from each of those examples mentioned for R⁰⁰³, and the like.

R⁰¹⁴ represents a polycyclic hydrocarbon group, or an alkyl group containing a polycyclic hydrocarbon group, each having 7 to 15 carbon atoms, and examples thereof specifically include norbornyl, bicyclo[3.3.1]nonyl, tricyclo[5.2.1.0^{2.6}]decyl, adamantyl, ethyladamantyl, butyladamantyl, norbornylmethyl, adamantylmethyl groups, and the like.

R⁰¹⁵ represents an acid labile group. X represents —CH₂, or an oxygen atom. k is 0 or 1.

Usable as the acid labile group of R⁰¹⁵ are various ones, and examples thereof specifically include: those groups represented by the general formulae (L1) to (L4), identically to the acid labile group contained in the polymer (A); a tertiary alkyl group having 4 to 20 carbon atoms, preferably 4 to 15 carbon atoms; a trialkylsilyl group, each of alkyl groups of which has 1 to 6 carbon atoms; an oxoalkyl group having 4 to 20 carbon atoms; and the like.

In the formula (R2), R⁰¹⁶ and R⁰¹⁸ each represent a hydrogen atom or a methyl group. R⁰¹⁷ represents a straight, branched, or cyclic alkyl group having 1 to 8 carbon atoms.

In the formula (R1), a1′, a2′, a3′, b1′, b2′, b3′, c1′, c2′, c3′, d1′, d2′, d3′, and e′ are each a number of 0 or more and less than 1, in a manner to satisfy that a1′+a2′+a3′+b1′+b2′+b3′+c1′+c2′+c3′+d1′+d2′+d3′+e′=1. In the formula (R2), f′, g′, h′, j′, k′, 1′, and m′ are each a number of 0 or more and less than 1, in a manner to satisfy that f′+g′+h′+i′+j′+k′+k′+l′+m′=1. x′, y′, and z′ are each an integer from 0 to 3, in a manner to satisfy that 1≦x′+y′+z′≦5, and 1≦y′+z′≦3.

Further, it is also possible to copolymerize indenes, norbornadienes, acenaphthylenes, and vinyl ethers.

Examples of the repeating unit to be introduced at the composition ratio a1′ in the formula (R1) specifically include the hydroxyl group, carboxyl group, fluoroalkyl group, or fluoroalcohol unit, having been exemplified as those units which the polymer (A) may contain, without limited thereto.

Examples of the repeating unit to be introduced at the composition ratio b1′ in the formula (R1) specifically include the repeating unit having an adhesive group comprising the lactone ring having been exemplified as that unit which the polymer (A) may contain, without limited thereto.

Examples of the repeating unit to be introduced at the composition ratio d1′ in the formula (R1) specifically include the same acid labile units as those which the polymer (A) contains, without limited thereto.

Examples of the polymers constituted of the repeating units at the composition ratios a3′, b3′, c3′, and d3′ in the formula (R1) specifically include those polymers shown below, without limited thereto.

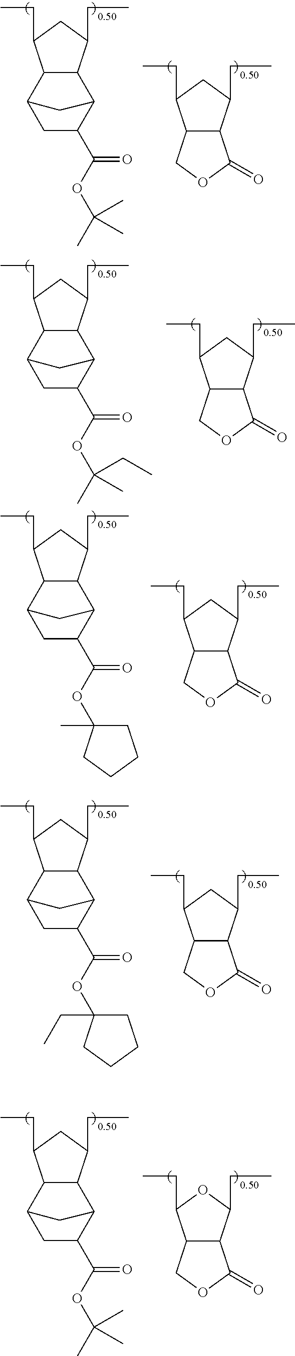

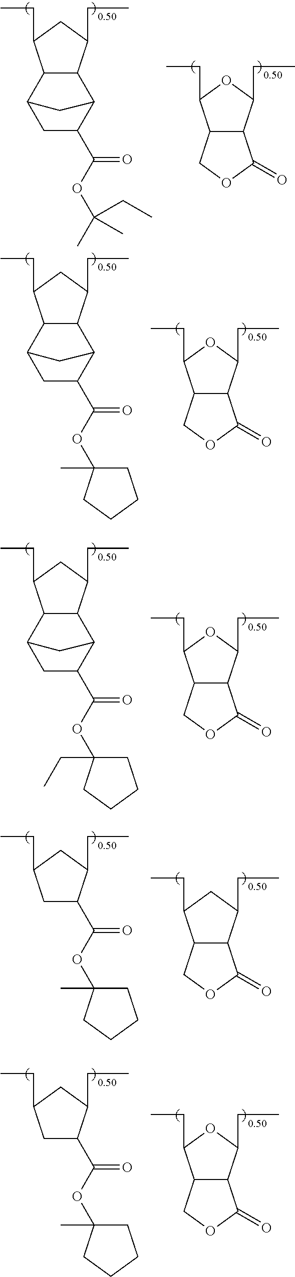

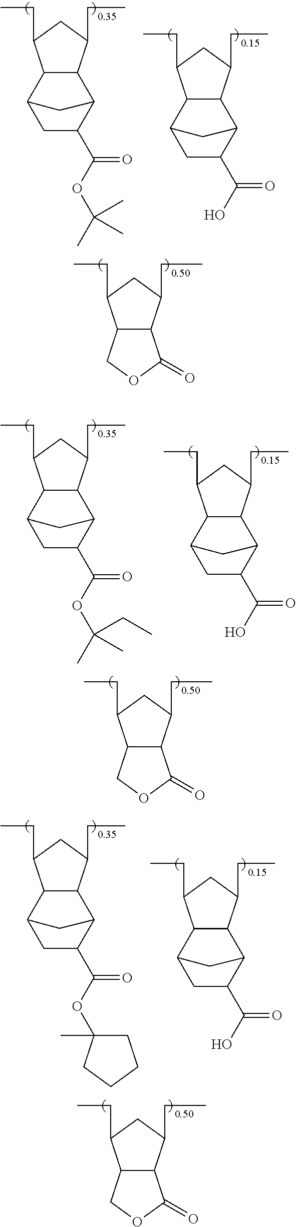

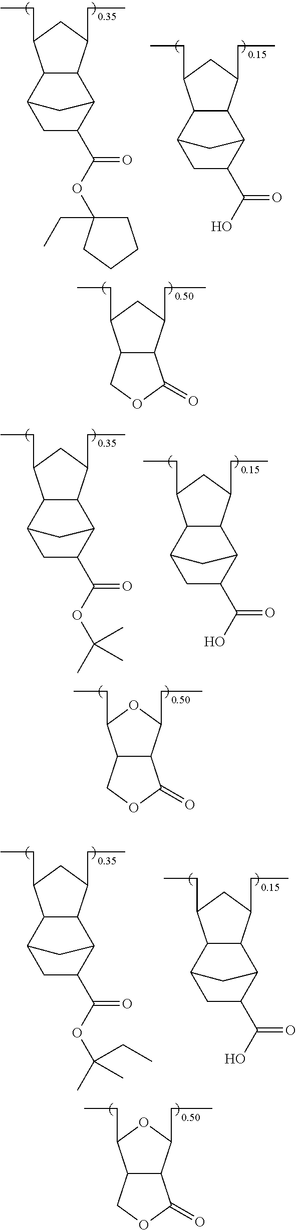

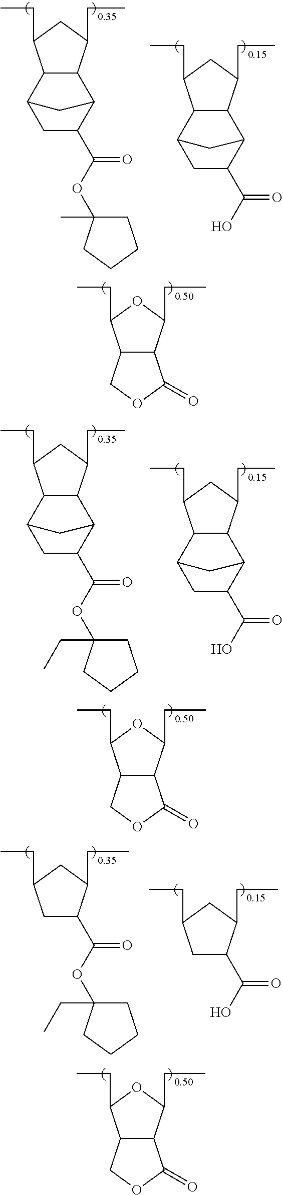

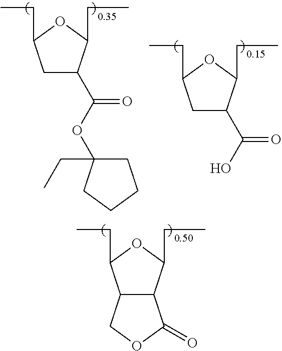

It is possible to add two or more kinds of polymers, other than the polymer (A), into the positive resist composition of the present invention, without limited to one kind, thereby providing a base resin. Adopting multiple kinds of polymers enables to adjust a performance of the resist composition.

The positive resist composition of the present invention comprises at least: (A) a polymer containing a repeating unit (a1) and an acid labile repeating unit (a2), wherein the repeating unit (a1) generates an acid of a specific structure (the structure represented by the above general formula (1)) by irradiation of a high-energy radiation, and which polymer is changed in solubility in alkali, by the acid; and (B) an onium sulfonate represented by the above general formula (2) and having an acid-generating ability; as described above. However, it is possible for the positive resist composition to additionally contain another acid generator configured to generate an acid by irradiation of a high-energy radiation.

Examples of such a preferable photoacid generator include acid generators of types of a sulfonium salt, iodonium salt, N-sulfonyloxydicarboxylmide, and oxime-O-arylsulfonate, respectively, and it is possible to use a compound defined in a formula (F-1) (the following formula (F)) described in Japanese Patent Laid-Open (Kokai) No. 2009-269953, and the like:

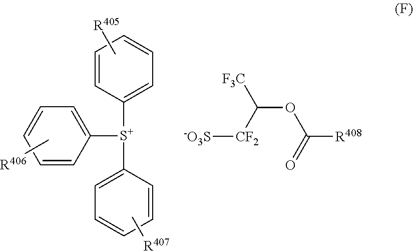

In the formula, R⁴⁰⁵, R⁴⁰⁵, and R⁴⁰⁷ each independently represent a hydrogen atom, or a monovalent straight, branched, or cyclic hydrocarbon group having 1 to 20 carbon atoms, particularly an alkyl group or alkoxy group, which group may contain a heteroatom; and examples of the hydrocarbon group which may contain a heteroatom specifically include: a methyl group, ethyl group, propyl group, isopropyl group, n-butyl group, sec-butyl group, tert-butyl group, tert-amyl group, n-pentyl group, n-hexyl group, cyclopentyl group, cyclohexyl group, ethylcyclopentyl group, butylcyclopentyl group, ethylcyclohexyl group, butylcyclohexyl group, adamantyl group, ethyladamantyl group, and butyladamantyl group; those groups each obtained by inserting, between an arbitrary carbon-carbon bond of one of the above mentioned groups, a heteroatom group such as —O—, —S—, —SO—, —SO₂—, —NH—, —C(═O)—, —C(═O)O—, —C(═O)NH—, or the like; and those groups each obtained by substituting an arbitrary hydrogen atom(s) of one of the above mentioned groups, with a functional group such as —OH, —NH₂, —CHO, —CO₂H, or the like. R⁴⁰⁸ represents a monovalent straight, branched, or cyclic hydrocarbon group having 7 to 30 carbon atoms, which group may contain a heteroatom.

In the positive resist composition of the present invention, the addition amount of a photoacid generator which may be added into the composition in addition to the polymer (A) and the onium sulfonate (B), is 0.1 to 15 mass parts, preferably 0.1 to 10 mass parts, relative to 100 mass parts of a base resin including the polymer (A), or the polymer (A) and another resin component if contained, in the resist composition. When the photoacid generator is contained in an amount of 15 mass parts or less, the photoresist film (also called “resist film”) is sufficiently large in transmittance, thereby decreasing a possibility of occurrence of deterioration of resolution performance. The above photoacid generators may each be used solely, or may be used mixedly in two or more kinds. Further, it is also possible to use a photoacid generator having a low transmittance at an exposure wavelength and to adjust its addition amount, thereby controlling a transmittance of the resist film.

Moreover, the positive resist composition of the present invention may further contain at least one or more of an organic solvent, a basic compound, a dissolution control agent, and a surfactant.

Usable as the organic solvent to be used in the positive resist composition of the present invention, is any organic solvent insofar as the same allows dissolution therein of the polymer (A), the onium sulfonate (B), the other resin component(s), the acid generator, other additive(s), and the like. Examples of such an organic solvent include: ketones such as cyclohexanone, methyl-2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as 7-butyrolactone; and these solvents may be used solely in one kind, or mixedly in two or more kinds, without limited thereto. To be preferably used in the present invention among these organic solvents, are diethylene glycol dimethyl ether, 1-ethoxy-2-propanol, propylene glycol monomethyl ether acetate, and mixed solvents thereof, which solvents are most excellent in solubility therein of the acid generator in the resist components.

The usage amount of the organic solvent is preferably 200 to 4,000 mass parts, particularly 400 to 3,000 mass parts, relative to 100 mass parts of a base resin (a total of the polymer (A), and other resin component(s)) in the resist composition.

Examples of the nitrogen-containing compound as the basic compound include: primary, secondary, and tertiary amine compounds, particularly amine compounds each having a hydroxy group, ether group, ester group, lactone ring, cyano group, or sulfonic acid ester group, as described in paragraphs (0146) to (0164) of Japanese Patent Laid-Open (Kokai) No. 2008-111103; or a compound having a carbamate group described in Japanese Patent No. 3790649.

The usage amount of the nitrogen-containing compound is preferably 0.001 to 50 mass parts relative to 100 mass parts of the base resin in the resist composition.

Additionally, the resist composition may contain one or more of a surfactant and a dissolution control agent.

Usable as the surfactant is a material described in paragraphs (0165) to (0166) of Japanese Patent Laid-Open (Kokai) No. 2008-111103, and usable as the dissolution control agent is a material described in paragraphs (0155) to (0178) of Japanese Patent Laid-Open (Kokai) No 2008-122932.

The blending amount of the surfactant is preferably 0.0001 to 10 mass parts relative to 100 mass parts of the base resin, and the blending amount of the dissolution control agent is preferably 0 to 40 mass parts relative to 100 mass parts of the base resin.

The present invention provides a patterning process using the above described positive resist composition.

It is possible to adopt a known lithography technique so as to form a pattern by adopting the positive resist composition of the present invention, such that the composition is applied to a substrate (Si, SiO₂, SiN, SiON, TiN, WSi, BPSG, SOG, organic antireflective film, or the like) for fabricating integrated circuits, a substrate (Cr, CrO, CrON, MoSi, or the like) for fabricating mask circuits, or a substrate such as silicon wafer, by a technique such as spin coating so as to achieve a film thickness of 0.05 to 2.0 μm, and the film is pre-baked on a hot plate at 60 to 150° C. for 1 to 10 minutes, preferably at 80 to 140° C. for 1 to 5 minutes, thereby obtaining a resist film, for example. Next, the mask for forming the intended pattern is held over the resist film, followed by irradiation therethrough of a high-energy radiation such as ultraviolet rays, deep ultraviolet rays, electron beam, X-rays, excimer laser, γ-rays, synchrotron radiation, or the like, in a manner to achieve an exposure dose of 1 to 200 mJ/cm², preferably 10 to 100 mJ/cm². Alternatively, the pattern is directly written by an electron beam, without through a mask for patterning. In addition to a typical exposure technique, it is also possible to occasionally adopt an immersion method configured to immersingly provide a liquid between a mask and a resist film. In that case, it is possible to form and use a top coat insoluble in water, on the resist film. Next, post-exposure baking (PEB) is conducted on a hot plate at 60 to 150° C. for 1 to 5 minutes, preferably at 80 to 140° C. for 1 to 3 minutes. Further, development is conducted by using a developer comprising an alkaline aqueous solution containing 0.1 to 5 mass %, preferably 2 to 3 mass % of tetramethylammonium hydroxide (TMAH) or the like, for 0.1 to 3 minutes, preferably 0.5 to 2 minutes, in the usual manner such as a dip method, puddle method, spray method, or the like, thereby forming an intended pattern on the substrate. It is noted that the positive resist composition of the present invention is optimum for a fine patterning by deep ultraviolet rays or excimer laser of 180 to 250 nm, X-rays, electron beam, and the like, among high-energy radiations. It is occasionally impossible to obtain an intended pattern, when the applicable conditions are outside the upper limits or lower limits of the above ranges, respectively.

The above-mentioned top coat insoluble in water is used to prevent from leaching from a resist film and to improve a water slidablity of a surface of the film, and is generally classified into two types. One type is an organic solvent stripping type which is required to be stripped, before alkaline development, by an organic solvent in which the resist film is insoluble, and the other type is an alkali-soluble type which is soluble in an alkaline developer in a manner that the top coat is removed simultaneously with removal of a soluble portion of the resist film.

Particularly preferable as the latter type is a material, which material contains, as a base component, a polymer having a 1,1,1,3,3,3-hexafluoro-2-propanol residue that is insoluble in water and soluble in an alkaline developer, and which material is dissolved in a solvent based on an alcohol having 4 or more carbon atoms, a solvent based on an ether having 8 to 12 carbon atoms, or a mixed solvent thereof.

Alternatively, it is also possible to provide a material of the latter type, by dissolving the above-mentioned surfactant, that is insoluble in water and soluble in an alkaline developer, in a solvent based on an alcohol having 4 or more carbon atoms, a solvent based on an ether having 8 to 12 carbon atoms, or a mixed solvent thereof.

Further, as a technique of patterning process, it is possible: to conduct rinsing by pure water after photoresist film formation to thereby extract an acid generator or the like from a surface of the film or to wash away particles therefrom; or to conduct rinsing (post-soaking) for removing water remaining on the film, after exposure.

### EXAMPLES

Although the present invention will be described hereinafter in more detail based on Examples and Comparative Examples, the present invention is not limited to these Examples.

(Composition and Molecular Weight/Dispersity of Polymer)

Shown in Table 1 and Table 2 are composition ratios (mol %), molecular weights, and dispersities of repeating units constituting polymers adopted in this evaluation, respectively. Further, shown in Table 3 to Table 5 are structures of the repeating units, respectively. In Table 3, Monomers 1 to 7 are each a repeating unit (a1), which is indispensable to the polymer (A) contained in the positive resist composition of the present invention and which is sensed to a high-energy radiation to thereby generate an, acid, and in Table 4, ALU-1 to ALU-10 are each an acid labile repeating unit (a2) indispensable to the polymer (A). Thus, Polymer-1 to Polymer-39 correspond to the polymers (A) of the present invention, respectively. Polymer-40 and Polymer-41 are polymers of Comparative Examples, respectively.

TABLE 1

| | Repeating | Repeating | Repeating | Repeating | Repeating | | |
|---|---|---|---|---|---|---|---|
| | unit 1 | unit 2 | unit 3 | unit 4 | unit 5 | | |
| | (composi- | (composi- | (composi- | (composi- | (composi- | | |
| | tion | tion | tion | tion | tion | Molecular | |
| | ratio) | ratio) | ratio) | ratio) | ratio) | weight | Dispersity |
| Polymer- | Monomer 1 | ALU-7 (45) | Unit-1 | Unit-8 | — | 7200 | 1.80 |
| 1 | (10) | | (35) | (10) | | | |
| Polymer- | Monomer 1 | ALU-7 (45) | Unit-1 | Unit-8 | — | 6800 | 1.71 |
| 2 | (8) | | (37) | (10) | | | |
| Polymer- | Monomer 1 | ALU-7 (45) | Unit-1 | Unit-8 | — | 7000 | 1.65 |
| 3 | (5) | | (40) | (10) | | | |
| Polymer- | Monomer 1 | ALU-7 (45) | Unit-1 | Unit-8 | — | 6400 | 1.89 |
| 4 | (2) | | (43) | (10) | | | |
| Polymer- | Monomer 1 | ALU-1 (45) | Unit-4 | Unit-8 | — | 8800 | 1.67 |
| 5 | (5) | | (40) | (10) | | | |
| Polymer- | Monomer 2 | ALU-1 (45) | Unit-4 | Unit-8 | — | 8100 | 1.76 |
| 6 | (5) | | (40) | (10) | | | |
| Polymer- | Monomer 3 | ALU-9 (45) | Unit-5 | Unit-8 | — | 7700 | 1.88 |
| 7 | (8) | | (37) | (10) | | | |
| Polymer- | Monomer 4 | ALU-9 (45) | Unit-5 | Unit-8 | — | 7570 | 1.71 |
| 8 | (8) | | (37) | (10) | | | |
| Polymer- | Monomer 5 | ALU-7 (45) | Unit-4 | Unit-8 | — | 6150 | 1.67 |
| 9 | (5) | | (40) | (10) | | | |
| Polymer- | Monomer 6 | ALU-7 (45) | Unit-4 | Unit-8 | — | 6300 | 1.65 |
| 10 | (5) | | (40) | (10) | | | |
| Polymer- | Monomer 7 | ALU-1 (45) | Unit-1 | Unit-8 | — | 8890 | 1.77 |
| 11 | (5) | | (40) | (10) | | | |
| Polymer- | Monomer 3 | ALU-4 (45) | Unit-5 | Unit-9 | — | 7130 | 1.78 |
| 12 | (8) | | (37) | (10) | | | |
| Polymer- | Monomer 7 | ALU-1 (45) | Unit-1 | Unit-4 | — | B800 | 1.72 |
| 13 | (5) | | (30) | (20) | | | |
| Polymer- | Monomer 7 | ALU-2 (45) | Unit-1 | Unit-4 | — | 7220 | 1.70 |
| 14 | (5) | | (30) | (20) | | | |
| Polymer- | Monomer 7 | ALU-4 (45) | Unit-1 | Unit-4 | — | 6600 | 1.97 |
| 15 | (5) | | (30) | (20) | | | |
| Polymer- | Monomer 7 | ALU-6 (45) | Unit-1 | Unit-4 | — | 6200 | 1.47 |
| 16 | (5) | | (30) | (20) | | | |
| Polymer- | Monomer 7 | ALU-9 (45) | Unit-1 | Unit-4 | — | 8120 | 1.76 |
| 17 | (5) | | (30) | (20) | | | |
| Polymer- | Monomer 1 | ALU -7 (45) | Unit-1 | Unit-5 | — | 6690 | 1.55 |
| 18 | (5) | | (30) | (20) | | | |
| Polymer- | Monomer 1 | ALU-8 (45) | Unit-1 | Unit-5 | — | 7100 | 1.66 |
| 19 | (5) | | (30) | (20) | | | |
| Polymer- | Monomer 1 | ALU-3 (45) | Unit-1 | Unit-5 | — | 7760 | 1.89 |
| 20 | (5) | | (30) | (20) | | | |

TABLE 2

| | Repeating | Repeating | Repeating | Repeating | Repeating | | |
|---|---|---|---|---|---|---|---|
| | unit 1 | unit 2 | unit 3 | unit 4 | unit 5 | | |
| | (composi- | (composi- | (composi- | (composi- | (composi- | | |
| | tion | tion | tion | tion | tion | Molecular | |
| | ratio) | ratio) | ratio) | ratio) | ratio) | weight | Dispersity |
| Polymer- | Monomer 1 | ALU-5 | Unit-1 | Unit-5 | | 6200 | 1.70 |
| 21 | (5) | (45) | (30) | (20) | | | |
| Polymer- | Monomer 1 | ALU-9 | Unit-1 | Unit-4 | | 8350 | 1.69 |
| 22 | (5) | (45) | (30) | (20) | | | |
| Polymer- | Monomer 1 | ALU-1 | ALU-7 | Unit-1 | Unit-5 | 5780 | 1.63 |
| 23 | (5) | (5) | (50) | (10) | (30) | | |
| Polymer- | Monomer 1 | ALU-1 | ALU-7 | Unit-1 | Unit-5 | 5660 | 1.81 |
| 24 | (5) | (5) | (55) | (10) | (25) | | |
| Polymer- | Monomer 1 | ALU-1 | ALU-7 | Unit-1 | Unit-4 | 6130 | 1.77 |
| 25 | (5) | (5) | (50) | (10) | (30) | | |
| Polymer- | Monomer 1 | ALU-1 | ALU-7 | Unit-1 | Unit-4 | 7100 | 1.73 |
| 26 | (5) | (10) | (45) | (10) | (30) | | |
| Polymer- | Monomer 1 | ALU-1 | ALU-9 | Unit-1 | Unit-5 | 8340 | 1.69 |
| 27 | (3) | (5) | (50) | (12) | (30) | | |
| Polymer- | Monomer 1 | ALU-10 | ALU-9 | Unit-1 | Unit-5 | 8120 | 1.61 |
| 28 | (3) | (5) | (50) | (12) | (30) | | |
| Polymer- | Monomer 1 | ALU-7 | Unit-1 | Unit-4 | — | 6170 | 1.61 |
| 29 | (5) | (55) | (10) | (30) | | | |
| Polymer- | Monomer 1 | ALU-7 | Unit-1 | Unit-5 | — | 6340 | 1.88 |
| 30 | (5) | (55) | (10) | (30) | | | |
| Polymer- | Monomer 1 | ALU-7 | Unit-7 | Unit-4 | — | 6500 | 1.98 |
| 31 | (5) | (55) | (10) | (30) | | | |
| Polymer- | Monomer 1 | ALU-7 | Unit-2 | Unit-4 | — | 6200 | 1.79 |
| 32 | (5) | (55) | (10) | (30) | | | |
| Polymer- | Monomer 1 | ALU-7 | Unit-3 | Unit-4 | — | 6800 | 1.64 |
| 33 | (5) | (45) | (20) | (30) | | | |
| Polymer- | Monomer 1 | ALU-7 | Unit-2 | Unit-4 | — | 6500 | 1.54 |
| 34 | (5) | (45) | (20) | (30) | | | |
| Polymer- | Monomer 1 | ALU-7 | Unit-6 | Unit-4 | — | 6330 | 1.60 |
| 35 | (5) | (45) | (20) | (30) | | | |
| Polymer- | Monomer 7 | ALU-1 | Unit-1 | Unit-8 | Unit-10 | 7990 | 1.80 |
| 36 | (2) | (45) | (43) | (5) | (5) | | |
| Polymer- | Monomer 7 | ALU-1 | Unit-1 | Unit-8 | Unit-13 | 8100 | 1.89 |
| 37 | (2) | (45) | (43) | (5) | (5) | | |
| Polymer- | Monomer 7 | ALU-1 | Unit-1 | — | Unit-12 | 8220 | 2.10 |
| 38 | (2) | (45) | (43) | | (10) | | |
| Polymer- | Monomer 7 | ALU-1 | Unit-1 | — | Unit-11 | 8460 | 1.88 |
| 39 | (2) | (45) | (43) | | (10) | | |
| Polymer- | — | ALU-1 | Unit-4 | Unit-8 | — | 9100 | 1.72 |
| 40 | | (45) | (45) | (10) | | | |
| Polymer- | — | ALU-9 | Unit-5 | Unit-8 | — | 8600 | 1.62 |
| 41 | | (45) | (45) | (10) | | | |

TABLE 3

| | |
|---|---|
| 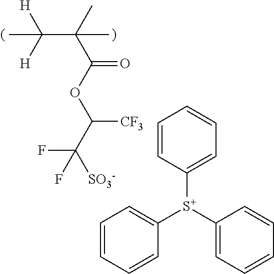 | Monomer 1 |
| 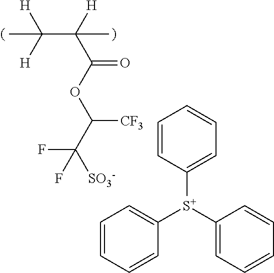 | Monomer 2 |
| 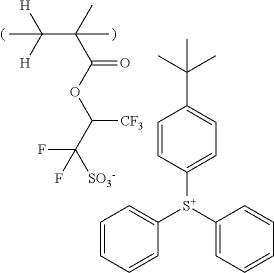 | Monomer 3 |
| 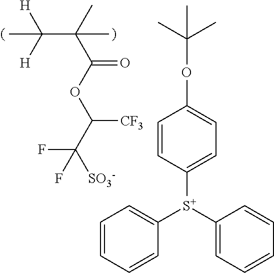 | Monomer 4 |
| 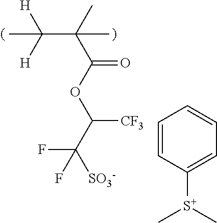 | Monomer 5 |
| 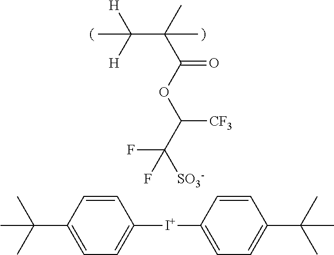 | Monomer 6 |
| 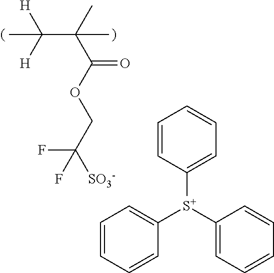 | Monomer 7 |

TABLE 4

| | |
|---|---|
| 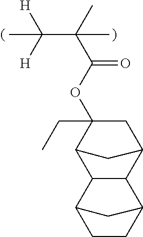 | ALU-1 |
| 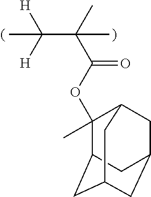 | ALU-2 |
| 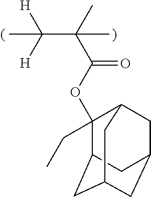 | ALU-3 |
| 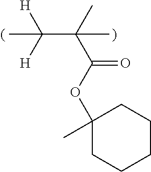 | ALU-4 |
| 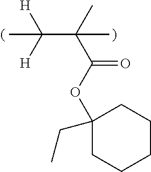 | ALU-5 |
| 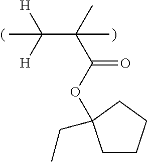 | ALU-6 |
| 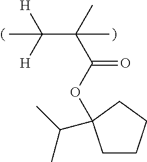 | ALU-7 |
| 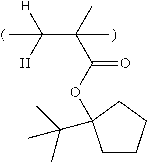 | ALU-8 |
| 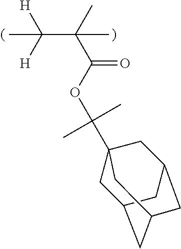 | ALU-9 |
| 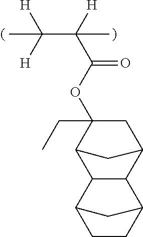 | ALU-10 |

TABLE 5

| | |
|---|---|
| 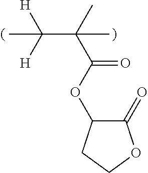 | Unit-1 |
| 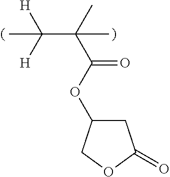 | Unit-2 |
| 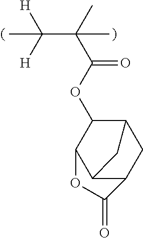 | Unit-3 |
| 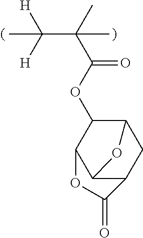 | Unit-4 |
| 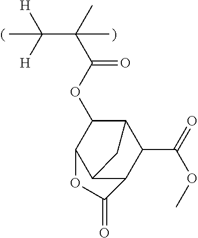 | Unit-5 |
| 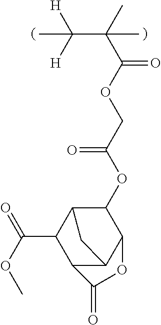 | Unit-6 |
| 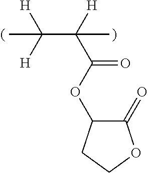 | Unit-7 |
| 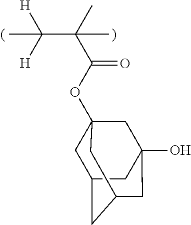 | Unit-8 |
| 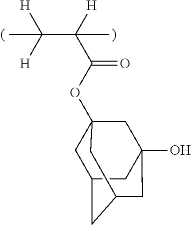 | Unit-9 |
| 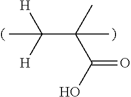 | Unit-10 |
| 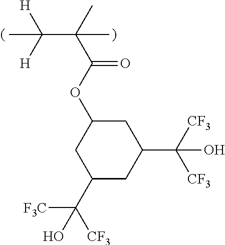 | Unit-11 |
| 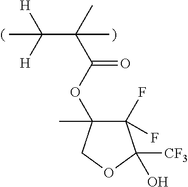 | Unit-12 |
| 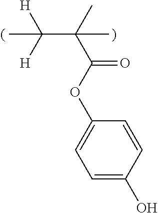 | Unit-13 |

(Preparation of Resist Composition)

Next, various photoacid generators, and various quenchers were dissolved in solvents, in addition to the above polymers, respectively, followed by filtration by a filter (pore diameter of 0.2 μm) made of Teflon (Registered Trade-Mark) after the dissolution, thereby preparing resist compositions of the present invention shown in Table 6 to Table 8, respectively. Further prepared were resist compositions shown in the following Table 9, as comparative specimens, respectively. Shown in Table 10 are structures of onium salts in Table 6 to Table 9, respectively, and shown in Table 11 are structures of nitrogen-containing organic compounds used as the quenchers, respectively. Among the onium salts of Table 10, Salt 1 to Salt 13 each correspond to an onium sulfonate (B) as a component indispensable to a resist composition of the present invention.

TABLE 6

| | | | onium | nitrogen- | |
|---|---|---|---|---|---|
| | | onium | salt 2 | containing | |
| resist | polymer | salt 1 | (parts | compound | |
| compo- | (parts by | (parts by | by | (parts by | Solvent |
| sition | mass) | mass) | mass) | mass) | (parts by mass) |
| PR-1 | Polymer-1 | salt 1 | — | — | PGMEA(2700) |
| | (80) | (3.3) | | | GBL(300) |
| PR-2 | Polymer-2 | salt 1 | — | — | PGMEA(2700) |
| | (80) | (4.4) | | | GBL(300) |
| PR-3 | Polymer-3 | salt 1 | — | — | PGMEA(2700) |
| | (80) | (5.5) | | | GBL(300) |
| PR-4 | Polymer-3 | salt 2 | — | — | PGMEA(2700) |
| | (80) | (5.8) | | | GBL(300) |
| PR-5 | Polymer-4 | salt 1 | salt 2 | — | PGMEA(2700) |
| | (80) | (3.3) | (3.5) | | GBL(300) |
| PR-6 | Polymer-4 | salt 2 | salt 3 | — | PGMEA(2700) |
| | (80) | (3.5) | (3.2) | | GBL(300) |
| PR-7 | Polymer-4 | salt 3 | salt 5 | — | PGMEA(2700) |
| | (80) | (3.2) | (4.6) | | GBL(300) |
| PR-8 | Polymer-5 | salt 1 | — | — | PGMEA(2700) |
| | (80) | (5.5) | | | GBL(300) |
| PR-9 | Polymer-6 | salt 3 | — | — | PGMEA(2700) |
| | (80) | (5.3) | | | GBL(300) |
| PR-10 | Polymer-7 | salt 4 | — | — | PGMEA(2700) |
| | (80) | (5.3) | | | GBL(300) |
| PR-11 | Polymer-8 | salt 1 | — | — | PGMEA(2700) |
| | (80) | (5.5) | | | GBL(300) |
| PR-12 | Polymer-9 | salt 2 | — | A-2 | PGMEA(2700) |
| | (80) | (5.8) | | (0.7) | GBL(300) |
| PR-13 | Polymer-10 | salt 2 | — | A-2 | PGMEA(2700) |
| | (80) | (5.8) | | (0.7) | GBL(300) |
| PR-14 | Polymer-11 | salt 3 | — | — | PGMEA(2700) |
| | (80) | (7.5) | | | GBL(300) |
| PR-15 | Polymer-12 | salt 3 | — | — | PGMEA(2700) |
| | (80) | (7.5) | | | GBL(300) |
| PR-16 | Polymer-13 | salt 4 | — | A-2 | PGMEA(2700) |
| | (80) | (6.2) | | (0.7) | GBL(300) |
| PR-17 | Polymer-14 | salt 4 | — | A-3 | PGMEA(2700) |
| | (80) | (6.2) | | (1.0) | GBL(300) |
| PR-18 | Polymer-15 | salt 4 | — | A-4 | PGMEA(2700) |
| | (80) | (6.2) | | (0.8) | GBL(300) |
| PR-19 | Polymer-16 | salt 4 | — | A-4 | PGMEA(2700) |
| | (80) | (6.2) | | (0.8) | GBL(300) |
| PR-20 | Polymer-17 | salt 4 | — | — | PGMEA(2700) |
| | (80) | (6.2) | | | GBL(300) |

TABLE 7

| | | | onium | nitrogen- | |
|---|---|---|---|---|---|
| | | onium | salt 2 | containing | |
| resist | polymer | salt 1 | (parts | compound | Solvent |
| compo- | (parts by | (parts by | by | (parts by | (parts by |
| sition | mass) | mass) | mass) | mass) | mass) |
| PR-21 | Polymer-18 | salt 3 | — | — | PGMEA(2700) |
| | (80) | (5.3) | | | GBL(300) |
| PR-22 | Polymer-18 | salt 6 | — | — | PGMEA(2700) |
| | (80) | (4.4) | | | GBL(300) |
| PR-23 | Polymer-18 | salt 9 | — | — | PGMEA(2700) |
| | (80) | (3.7) | | | GBL(300) |
| PR-24 | Polymer-18 | salt 3 | salt 19 | — | PGMEA(2700) |
| | (80) | (3.2) | (5.1) | | GBL(300) |
| PR-25 | Polymer-18 | salt 3 | salt 5 | — | PGMEA(2700) |
| | (80) | (3.2) | (4.6) | | GBL(300) |
| PR-26 | Polymer-18 | salt 3 | salt 6 | — | PGMEA(2700) |
| | (80) | (3.2) | (3.3) | | GBL(300) |
| PR-27 | Polymer-19 | salt 12 | salt 10 | — | PGMEA(2700) |
| | (80) | (3.3) | (3.0) | | GBL(300) |
| PR-28 | Polymer-20 | salt 13 | salt 10 | — | PGMEA(2700) |
| | (80) | (3.8) | (3.0) | | GBL(300) |
| PR-29 | Polymer-21 | salt 12 | salt 10 | — | PGMEA(2700) |
| | (80) | (3.3) | (3.0) | | GBL(300) |
| PR-30 | Polymer-22 | salt 13 | salt 10 | — | PGMEA(2700) |
| | (80) | (3.8) | (3.0) | | GBL(300) |
| PR-31 | Polymer-23 | salt 3 | — | — | PGMEA(2700) |
| | (80) | (5.3) | | | GBL(300) |
| PR-32 | Polymer-24 | salt 3 | — | — | PGMEA(2700) |
| | (80) | (5.3) | | | GBL(300) |
| PR-33 | Polymer-25 | salt 3 | — | — | PGMEA(2700) |
| | (80) | (5.3) | | | GBL(300) |
| PR-34 | Polymer-26 | salt 3 | — | — | PGMEA(2700) |
| | (80) | (5.3) | | | GBL(300) |
| PR-35 | Polymer-27 | salt 3 | — | — | PGMEA(2700) |
| | (80) | (5.3) | | | GBL(300) |
| PR-36 | Polymer-28 | salt 3 | — | — | PGMEA(2700) |
| | (80) | (5.3) | | | GBL(300) |
| PR-37 | Polymer-29 | salt 3 | — | — | PGMEA(2700) |
| | (80) | (5.3) | | | GBL(300) |
| PR-38 | Polymer-29 | salt 3 | — | — | PGMEA(2700) |
| | (80) | (7.5) | | | GBL(300) |
| PR-39 | Polymer-30 | salt 3 | — | — | PGMEA(2700) |
| | (80) | (5.3) | | | GBL(300) |
| PR-40 | Polymer-30 | salt 7 | — | — | PGMEA(2700) |
| | (80) | (5.0) | | | GBL(300) |

TABLE 8

| | | | onium | nitrogen- | |
|---|---|---|---|---|---|
| | | onium | salt 2 | containing | |
| resist | polymer | salt 1 | (parts | compound | Solvent |
| compo- | (parts by | (parts by | by | (parts by | (parts by |
| sition | mass) | mass) | mass) | mass) | mass) |
| PR-41 | Polymer-31 | salt 6 | — | — | PGMEA(2700) |
| | (80) | (4.4) | | | GBL(300) |
| PR-42 | Polymer-32 | salt 7 | — | — | PGMEA(2700) |
| | (80) | (5.0) | | | GBL(300) |
| PR-43 | Polymer-33 | salt 8 | — | — | PGMEA(2700) |
| | (80) | (3.2) | | | GBL(300) |
| PR-44 | Polymer-34 | salt 9 | — | — | PGMEA(2700) |
| | (80) | (3.7) | | | GBL(300) |
| PR-45 | Polymer-35 | salt 6 | — | — | PGMEA(2700) |
| | (80) | (4.4) | | | GBL(300) |
| PR-46 | Polymer-36 | salt 10 | — | A-2 | PGMEA(2700) |
| | (80) | (5.0) | | (0.7) | GBL(300) |
| PR-47 | Polymer-37 | salt 10 | — | A-2 | PGMEA(2700) |
| | (80) | (5.0) | | (0.7) | GBL(300) |
| PR-48 | Polymer-38 | salt 11 | — | A-3 | PGMEA(2700) |
| | (80) | (5.1) | | (1.0) | GBL(300) |
| PR-49 | Polymer-39 | salt 11 | — | A-3 | PGMEA(2700) |
| | (80) | (5.1) | | (1.0) | GBL(300) |
| PR-50 | Polymer-23 | salt 6 | — | — | PGMEA(2700) |
| | (80) | (4.4) | | | GBL(300) |
| PR-51 | Polymer-23 | salt 7 | — | — | PGMEA(2700) |
| | (80) | (5.0) | | | GBL(300) |
| PR-52 | Polymer-23 | salt 8 | — | — | PGMEA(2700) |
| | (80) | (3.2) | | | GBL(300) |
| PR-53 | Polymer-30 | salt 9 | — | — | PGMEA(2700) |
| | (80) | (3.7) | | | GBL(300) |
| PR-54 | Polymer-30 | salt 11 | — | — | PGMEA(2700) |
| | (80) | (5.1) | | | GBL(300) |
| PR-55 | Polymer-3 | salt 2 | — | — | PGMEA(2700) |
| | (80) | (6.9) | | | GBL(300) |
| PR-56 | Polymer-3 | salt 3 | — | — | PGMEA(2700) |
| | (80) | (5.3) | | | GBL(300) |
| PR-57 | Polymer-8 | salt 4 | — | — | PGMEA(2700) |
| | (80) | (6.2) | | | GBL(300) |
| PR-58 | Polymer-3 | salt 6 | — | — | PGMEA(2700) |
| | (80) | (4.4) | | | GBL(300) |
| PR-59 | Polymer-3 | salt 6 | Salt-19 | — | PGMEA(2700) |
| | (80) | (4.4) | (10.1) | — | GBL(300) |

TABLE 9

| | | | onium | nitrogen- | |
|---|---|---|---|---|---|
| | | onium | salt 2 | containing | |
| resist | polymer | salt 1 | (parts | compound | Solvent |
| compo- | (parts by | (parts by | by | (parts by | (parts by |
| sition | mass) | mass) | mass) | mass) | mass) |
| PR-60 | Polymer-3 | Salt-14 | — | — | PGMEA(2700) |
| | (80) | (6.2) | | | GBL(300) |
| PR-61 | Polymer-3 | Salt-15 | — | — | PGMEA(2700) |
| | (80) | (4.4) | | | GBL(300) |
| PR-62 | Polymer-3 | Salt-16 | — | — | PGMEA(2700) |
| | (80) | (4.8) | | | GBL(300) |
| PR-63 | Polymer-3 | Salt-17 | — | — | PGMEA(2700) |
| | (80) | (4.3) | | | GBL(300) |
| PR-64 | Polymer-3 | Salt-18 | — | — | PGMEA(2700) |
| | (80) | (4.9) | | | GBL(300) |
| PR-65 | Polymer-3 | — | — | A-1 | PGMEA(2700) |
| | (80) | | | (2.4) | GBL(300) |
| PR-66 | Polymer-40 | Salt-19 | Salt-1 | — | PGMEA(2700) |
| | (80) | (10.1) | (5.5) | | GBL(300) |
| PR-67 | Polymer-40 | Salt-19 | Salt-2 | — | PGMEA(2700) |
| | (80) | (10.1) | (5.8) | | GBL(300) |
| PR-68 | Polymer-40 | Salt-19 | Salt-3 | — | PGMEA(2700) |
| | (80) | (10.1) | (5.3) | | GBL(300) |
| PR-69 | Polymer-41 | Salt-19 | Salt-4 | — | PGMEA(2700) |
| | (80) | (10.1) | (6.2) | | GBL(300) |
| PR-70 | Polymer-40 | Salt-19 | — | A-1 | PGMEA(2700) |
| | (80) | (10.1) | | (2.4) | GBL(300) |
| PR-71 | Polymer-8 | — | — | A-1 | PGMEA(2700) |
| | (80) | | | (2.4) | GBL(300) |

TABLE 10

| | |
|---|---|
| 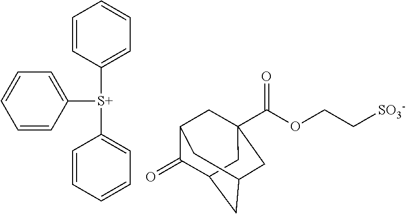 | Salt 1 |
| 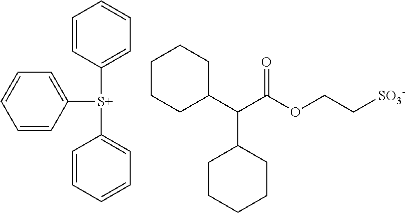 | Salt 2 |
| 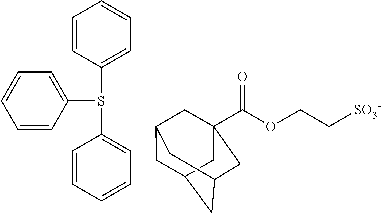 | Salt 3 |
| 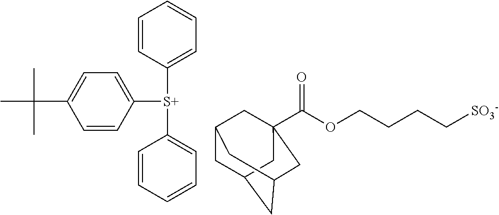 | Salt 4 |
| 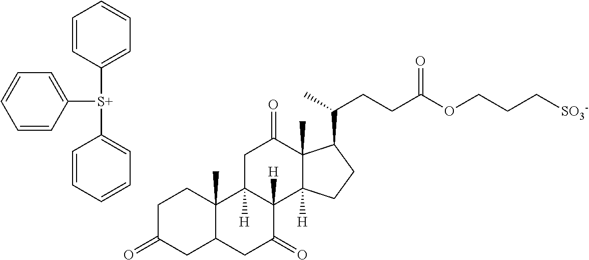 | Salt 5 |
| 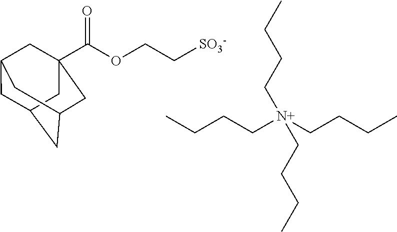 | Salt 6 |
| 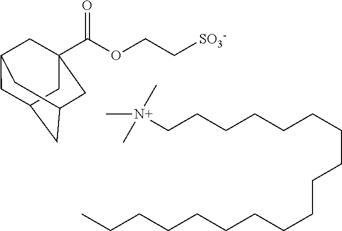 | Salt 7 |
| 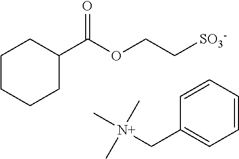 | Salt 8 |
| 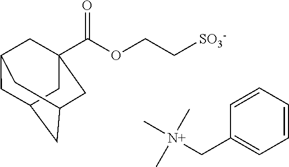 | Salt 9 |
| 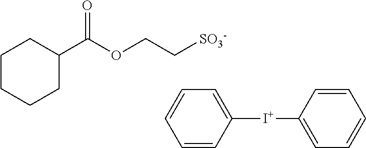 | Salt 10 |
| 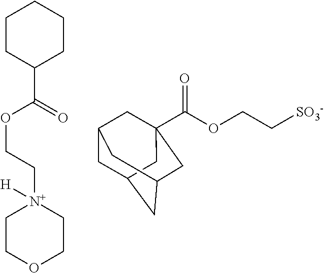 | Salt 11 |
| 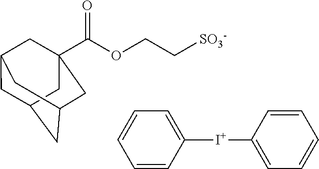 | Salt 12 |
| 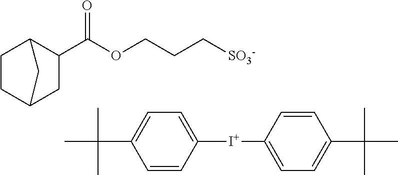 | Salt 13 |
| 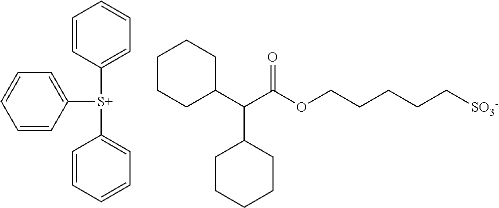 | Salt 14 |
| 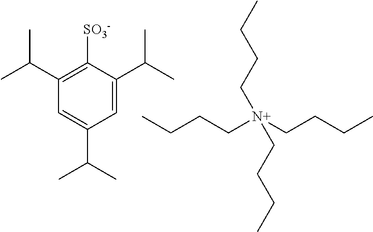 | Salt 15 |
| 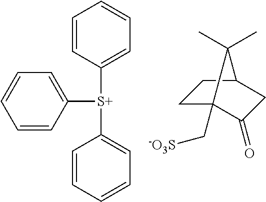 | Salt 16 |
| 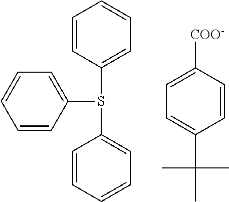 | Salt 17 |
| 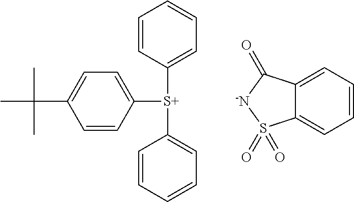 | Salt 18 |
| 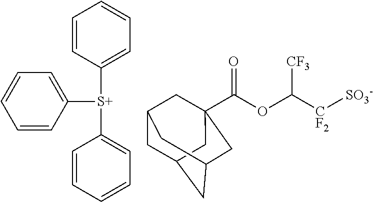 | Salt 19 |

TABLE 11

| | |
|---|---|
| 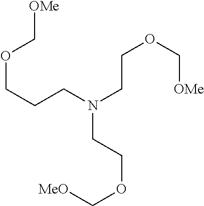 | A1 |
| 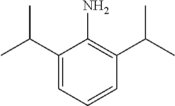 | A2 |
| 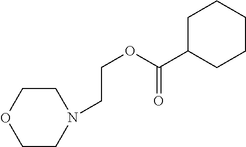 | A3 |
| 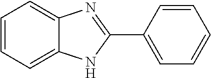 | A4 |

The solvents shown in Table 6 to Table 9 are as follows:

PGMEA: propylene glycol monomethyl ether acetate

GBL: γ-butyrolactone

Further, added into each of all the resist compositions shown in Table 6 to Table 9 were an alkali-soluble type surfactant SF-1 (5.0 mass parts) and a surfactant A (0.1 mass part). Structures of the alkali-soluble type surfactant SF-1 and the surfactant A are shown below:

Alkali-soluble type surfactant SF-1 (compound described in Japanese Patent Laid-Open (Kokai) No. 2008-122932):

poly(methacrylic acid=3,3,3-trifluoro-2-hydroxy-1,1-dimethyl-2-trifluoromethylpropyl.methacrylic acid=1,1,1-trifluoro-2-hydroxy-6-methyl-2-trifluoromethylhepta-4-yl) (following formula)

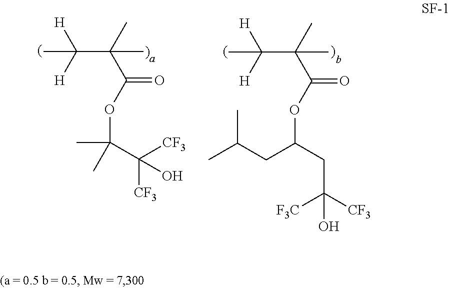

Surfactant A: 3-methyl-3-(2,2,2-trifluoroethoxymethyl oxetane.tetrahydrofuran.2,2-dimethyl-1,3-propanediol copolymer (produced by Omnova Solutions Inc.) (following formula)

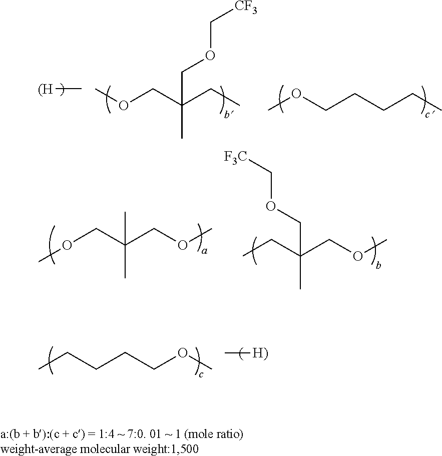

### Evaluation Method 1

### Examples 1 to 26, and Comparative Examples 1 to 7

Each resist solution was applies by spin coating to an substrate having an antireflective film (thickness of 100 nm) formed by applying an antireflective film solution (ARC-29A, produced by Nissan Chemical Industries, Ltd.) to a silicon substrate and by baking it at 200° C. for 60 seconds; and the thus applied resist solution was baked at 100° C. for 60 seconds by a hot plate, thereby forming a resist film of 80 nm thickness. This resist film was subjected to immersion exposure by adopting an ArF excimer laser scanner (NSR-S610C manufactured by Nikon Corp., NA-1.30., σ=0.93, ⅔ annular illumination, 6% halftone phase-shift mask), and then subjected to baking (PEB) at an arbitrary temperature for 60 seconds, followed by development by an aqueous solution of 2.38 mass % of tetramethylammonium hydroxide for 60 seconds, thereby forming a hole pattern.

The evaluation of the resist was conducted for a pattern of 90 nm hole/180 nm pitch, such that an exposure dose, where the holes were finished at an average diameter of 75 nm, was determined to be an optimum exposure dose (Eop, mJ/cm²), by means of an electron microscope.

At the optimum exposure dose, the focus was shifted upwardly and downwardly, in a manner to obtain a range of focus where the hole pattern was kept resolved at a dimension within the target dimension 75 nm±10% (i.e., 67.5 nm to 82.5 nm), and this range was determined to be a depth of focus (DOF, in nm).

Exposure was conducted at the optimum exposure dose by using masks of such patterns that only hole diameters were varied (85 to 95 nm, at steps of 1 nm) with fixed pitches (180 nm) as dimensions on wafers, respectively, and the dimensions were measured after transference of the mask patterns onto the wafers, respectively. With respect to a hole diameter value, dimensions in the transferred patterns were plotted relative to designed dimensions in the masks, respectively, in a manner to calculate a gradient of the plots by linear approximation, and to regard the gradient as a mask error factor (MEF). Smaller MEF values are more excellent, since such values lead to restricted affection of errors in transferred and finished mask patterns.

Obtained were variances (measured at 20 points) of diameter dimension of hole patterns each formed at the optimum exposure dose and intended to have a diameter of 75 nm, and a value of 3σ thereof was regarded as a circularity. Smaller values are more excellent.

Shown in Table 12 are evaluation results of the resist compositions (Examples 1 to 26) of the present invention shown in above Tables. Further, shown in Table 13 are evaluation results of comparative resist compositions (Comparative Examples 1 to 7).

TABLE 12

| | resist | PEB | Eop | | | Circularity | |
|---|---|---|---|---|---|---|---|
| No. | composition | (° C.) | (mJ/cm²) | circularity Profile | DOF (nm) | (nm) | MEF |
| Example-1 | PR-1 | 100 | 28 | Slightly rounding | 80 | 2.69 | 3.00 |
| | | | | profile | | | |
| Example-2 | PR-2 | 100 | 29 | Slightly rounding | 85 | 2.71 | 2.82 |
| | | | | profile | | | |
| Example-3 | PR-3 | 100 | 31 | Rectangular profile | 100 | 2.83 | 2.65 |
| Example-4 | PR-4 | 100 | 34 | Rectangular profile | 95 | 2.60 | 2.58 |
| Example-5 | PR-5 | 100 | 40 | Rectangular profile | 90 | 2.71 | 2.88 |
| Example-6 | PR-6 | 100 | 31 | Rectangular profile | 95 | 2.78 | 2.75 |
| Example-7 | PR-7 | 100 | 37 | Rectangular profile | 100 | 2.59 | 3.01 |
| Example-8 | PR-8 | 85 | 38 | Rectangular profile | 90 | 2.80 | 2.81 |
| Example-9 | PR-9 | 85 | 27 | Rectangular profile | 95 | 2.96 | 2.70 |
| Example-10 | PR-10 | 105 | 36 | Rectangular profile | 95 | 3.00 | 2.95 |
| Example-11 | PR-11 | 105 | 47 | Rectangular profile | 90 | 2.92 | 2.87 |
| Example-12 | PR-12 | 100 | 49 | Rectangular profile | 85 | 2.80 | 2.67 |
| Example-13 | PR-13 | 100 | 60 | Rectangular profile | 85 | 2.71 | 2.60 |
| Example-14 | PR-14 | 85 | 50 | Rectangular profile | 85 | 2.98 | 2.73 |
| Example-15 | PR-15 | 90 | 34 | Rectangular profile | 90 | 2.84 | 2.90 |
| Example-16 | PR-16 | 85 | 45 | Rectangular profile | 90 | 3.00 | 2.97 |
| Example-17 | PR-17 | 90 | 50 | Rectangular profile | 95 | 3.04 | 2.80 |
| Example-18 | 2R-18 | 95 | 46 | Rectangular profile | 95 | 2.88 | 2.86 |
| Example-19 | PR-19 | 95 | 54 | Rectangular profile | 85 | 2.65 | 2.71 |
| Example-20 | PR-20 | 95 | 44 | Rectangular profile | 85 | 2.87 | 2.79 |
| Example-21 | PR-21 | 95 | 38 | Rectangular profile | 105 | 2.51 | 2.44 |
| Example-22 | PR-22 | 95 | 39 | Rectangular profile | 100 | 2.73 | 2.50 |
| Example-23 | PR-23 | 95 | 38 | Rectangular profile | 100 | 2.63 | 2.49 |
| Example-24 | PR-24 | 95 | 30 | Slightly rounding | 95 | 2.78 | 2.66 |
| | | | | profile | | | |
| Example-25 | PR-25 | 95 | 30 | Rectangular profile | 95 | 2.78 | 2.66 |
| Example-26 | PR-26 | 95 | 30 | Rectangular profile | 95 | 2.78 | 2.66 |

TABLE 13

| | resist | | Eop | | | Circu- | |
|---|---|---|---|---|---|---|---|
| | compo- | PEB | (mJ/ | | DOF | larity | |
| No. | sition | (° C.) | cm²) | Profile | (nm) | (nm) | MEF |
| Comparative | PR-60 | 90 | 34 | Rounding | 65 | 3.28 | 3.40 |
| Example-1 | | | | profile | | | |
| Comparative | PR-61 | 90 | 31 | Rounding | 65 | 3.05 | 3.55 |
| Example-2 | | | | profile | | | |
| Comparative | PR-62 | 90 | 36 | Tapered | 60 | 3.46 | 3.47 |
| Example-3 | | | | profile | | | |
| Comparative | PR-63 | 90 | 33 | Tapered | 60 | 3.35 | 3.33 |
| Example-4 | | | | profile | | | |
| Comparative | PR 69 | 90 | 32 | Rounding | 50 | 3.20 | 3.31 |
| Example-5 | | | | profile | | | |
| Comparative | PR-65 | 90 | 28 | Rounding | 30 | 3.88 | 3.48 |
| Example-6 | | | | profile | | | |
| Comparative | FR-66 | 90 | 43 | Tapered | 25 | 3.67 | 3.78 |
| Example-7 | | | | profile | | | |

From the results shown in Table 12 and Table 13, it is proven that Examples 1 to 26 of the present invention each exhibit an excellent performance in a contact hole pattern, with respect to profile, circularity, MEF, and particularly DOF.

### Evaluation Method 2

### Examples 27 to 59, and Comparative Examples 8 to 14

Each resist solution was applied by spin coating to a substrate having an antireflective film (thickness of 100 nm) formed by applying an antireflective film solution (ARC-29A, produced by Nissan Chemical Industries, Ltd.) to a silicon substrate and by baking it at 200° C. for 60 seconds; and the thus applied resist solution was baked at 100° C. for 60 seconds by a hot plate, thereby forming a resist film of 80 nm thickness. This resist film was subjected to immersion exposure by adopting an ArF excimer laser scanner (NSR-S610C manufactured by Nikon Corp., NA=1.30., σ=0.85, ¾ annular illumination, 6% halftone phase-shift mask), and then subjected to baking (PEB) at an arbitrary temperature for 60 seconds, followed by development by an aqueous solution of 2.38 mass % of tetramethylammonium hydroxide for 60 seconds, thereby forming a trench pattern.

The evaluation of the resist was conducted for a pattern of 70 nm trench/170 nm pitch, such that an exposure dose, where the trenches were finished at widths of 70 nm, was determined to be an optimum exposure dose (Eop, mJ/cm²), by means of an electron microscope.

Further, concerning roughness of a trench edge portion at the optimum exposure dose, variances (measured at 30 points, for calculation of 3σ value) of dimension widths were obtained, numericalized, and compared (LWR, in nm).

At the optimum exposure dose, the focus was shifted upwardly and downwardly, in a manner to obtain a range of focus where the trench pattern was kept resolved at a dimension within the target dimension 70 nm±10% (i.e., 63 nm to 77 nm), and this range was determined to be a depth of focus (DOF, in nm). Larger values thereof are regarded to exhibit more excellent performances having wider margins against deviations of focuses.

Shown in Table 14 are evaluation results of the resist compositions (Examples 27 to 59) of the present invention shown in the above Tables. Further, shown in Table 15 are evaluation results of comparative resist compositions (Comparative Examples 8 to 14).

TABLE 14

| | resist | | Eop | | | |
|---|---|---|---|---|---|---|
| | compo- | PEB | (mJ/ | | LWR | DOF |
| No. | sition | (° C.) | Cm²) | Profile | (nm) | (nm) |
| Example-27 | PR-27 | 85 | 39 | Rectangular profile | 5.0 | 85 |
| Example-28 | PR-28 | 105 | 37 | Rectangular profile | 5.2 | 85 |
| Example-29 | PR-29 | 90 | 33 | Rectangular profile | 5.1 | 80 |
| Example-30 | PR-30 | 100 | 31 | Rectangular profile | 4.9 | 80 |
| Example-31 | PR-31 | 85 | 36 | Rectangular profile | 3.9 | 95 |
| Example-32 | PR-32 | 85 | 34 | Rectangular profile | 3.5 | 100 |
| Example-33 | PR-33 | 85 | 35 | Rectangular profile | 4.2 | 90 |
| Example-34 | PR-34 | 85 | 30 | Rectangular profile | 4.0 | 90 |
| Example-35 | PR-35 | 95 | 38 | Rectangular profile | 5.5 | 75 |
| Example-36 | PR-36 | 95 | 40 | Rectangular profile | 4.5 | 75 |
| Example-37 | PR-37 | 90 | 28 | Rectangular profile | 4.9 | 85 |
| Example-38 | PR-38 | 90 | 28 | Rectangular profile | 5.8 | 90 |
| Example-39 | PR-39 | 90 | 26 | Rectangular profile | 3.0 | 100 |
| Example-40 | PR-40 | 90 | 25 | Rectangular profile | 3.6 | 100 |
| Example-41 | PR-41 | 80 | 28 | Rectangular profile | 4.3 | 85 |
| Example-42 | PR-42 | 90 | 27 | Rectangular profile | 4.2 | 85 |
| Example-43 | PR-43 | 95 | 26 | Rectangular profile | 4.1 | 85 |
| Example-44 | PR-44 | 90 | 29 | Rectangular profile | 4.5 | 85 |
| Example-45 | PR-45 | 90 | 25 | Rectangular profile | 3.9 | 90 |
| Example-46 | PR-46 | 90 | 44 | Rectangular profile | 5.5 | 85 |
| Example-47 | PR-47 | 90 | 38 | Rectangular profile | 5.6 | 85 |
| Example-48 | PR-48 | 90 | 41 | Rectangular profile | 4.8 | 85 |
| Example-49 | PR-49 | 90 | 43 | Rectangular profile | 4.4 | 80 |
| Example-50 | PR-50 | 85 | 35 | Rectangular profile | 3.4 | 90 |
| Example-51 | PR-51 | 85 | 33 | Rectangular profile | 3.8 | 90 |
| Example-52 | PR-52 | 85 | 38 | Rectangular profile | 4.1 | 95 |
| Example-53 | PR-53 | 90 | 28 | Rectangular profile | 4.5 | 100 |
| Example-54 | PR-54 | 90 | 25 | Rectangular profile | 4.0 | 95 |
| Example-55 | PR-55 | 100 | 34 | Rectangular profile | 4.8 | 85 |
| Example-56 | PR-56 | 100 | 33 | Rectangular profile | 4.5 | 90 |
| Example-57 | PR-57 | 105 | 40 | Rectangular profile | 4.9 | 85 |
| Example-58 | PR-58 | 100 | 31 | Rectangular profile | 5.3 | 80 |
| Example-59 | PR-59 | 100 | 36 | Rectangular profile | 4.8 | 85 |

TABLE 15

| | resist | PEE | Eop | | LWR | DOF |
|---|---|---|---|---|---|---|
| No. | composition | (° C.) | (mJ/cm²) | Profile | (nm) | (nm) |
| Comparative | PR-65 | 90 | 31 | Slightly | 8.8 | 30 |
| Example-8 | | | | T-top | | |
| Comparative | PR-66 | 90 | 46 | Slightly | 7.3 | 40 |
| Example-9 | | | | T-top | | |
| Comparative | PR-67 | 100 | 45 | Slightly | 6.9 | 35 |
| Example-10 | | | | T-top | | |
| Comparative | PR-68 | 100 | 34 | Slightly | 6.7 | 35 |
| Example-11 | | | | T-top | | |
| Comparative | PR-69 | 110 | 32 | Slightly | 6.9 | 35 |
| Example-12 | | | | T-top | | |
| Comparative | PR-70 | 100 | 44 | T-top | 11.8 | 15 |
| Example-13 | | | | | | |
| Comparative | PR-71 | 110 | 33 | Slightly | 8.2 | 30 |
| Example-14 | | | | T-top | | |

From the results shown in Table 14 and Table 15, it is proven that Examples 27 to 59 of the present invention each exhibit an excellent performance in a trench pattern, with respect to profile, LWR, and DOF.

### Evaluation Method 3

### Examples 60 to 63, and Comparative Examples 15 to 18

Each resist solution was applied by spin coating to a substrate having an antireflective film (thickness of 100 nm) formed by applying an antireflective film solution (ARC-29A, produced by Nissan Chemical Industries, Ltd.) to a silicon substrate and by baking it at 200° C. for 60 seconds; and the thus applied resist solution was baked at 100° C. for 60 seconds by a hot plate, thereby forming a resist film of 80 nm thickness. This resist film was subjected to dry exposure by adopting an ArF excimer laser scanner (NSR-S307E manufactured by Nikon Corp., NA=0.85., σ=0.93, ⅘ annular illumination, 6% halftone phase-shift mask), and then subjected to baking (PEB) at an arbitrary temperature for 60 seconds, followed by development by an aqueous solution of 2.38 mass % of tetramethylammonium hydroxide for 60 seconds.

The evaluation of the resist was conducted for a bright pattern of 75 nm line/150 nm pitch, such that an exposure dose, where the lines were finished at 75 nm, was determined to be an optimum exposure dose (Eop, mJ/cm²), by means of an electron microscope. Further measured was a dimension difference (“dark portion dimension”−“bright portion dimension”, in nm) which was caused upon observation of a dark pattern of 75 nm line/150 nm pitch at that exposure dose, for comparison. Smaller values of dimension difference exhibit more excellent performances with smaller chemical flares.

Shown in Table 16 are evaluation results of the resist compositions (Examples 60 to 63) of the present invention shown in the above Table. Further, shown in Table 17 are evaluation results of comparative resist compositions (Comparative Examples 15 to 18).

TABLE 16

| | | PEB | Eop | difference |
|---|---|---|---|---|
| No. | resist composition | (° C.) | (mJ/cm²) | in dimension(nm) |
| Example-60 | PR-56 | 100 | 36 | 4.5 |
| Example-61 | PR-57 | 110 | 39 | 3.9 |
| Example-62 | PR-58 | 100 | 45 | 3.4 |
| Example-63 | PR-59 | 100 | 45 | 8.8 |

TABLE 17

| | | | | Difference |
|---|---|---|---|---|
| | | PEB | Eop | in dimension |
| No. | resist composition | (° C.) | (mJ/cm²) | (nm) |
| Comparative | PR-68 | 100 | 40 | 15.5 |
| Example-15 | | | | |
| Comparative | PR-69 | 110 | 43 | 13.9 |
| Example-16 | | | | |
| Comparative | PR-70 | 100 | 52 | 22.8 |
| Example-17 | | | | |
| Comparative | PR-71 | 110 | 38 | 17.4 |
| Example-18 | | | | |

From the results shown in Table 16 and Table 17, it was confirmed that the positive resist compositions of the present invention containing both of the specific polymers (A) and the specific sulfonic acid onium salts (B), exhibit excellent performances with extremely lower affections of chemical flare. It is apparent that improvement of performance is not recognized by only one of the specific polymer (A) and the specific sulfonic acid onium salt (B).

It must be noted here that the present invention is not limited to the embodiments as described above. The foregoing embodiments are mere examples; any form having substantially the same composition as the technical concept described in claims of the present invention and showing similar effects is included in the technical scope of the present invention.

What is claimed is:

1. A positive resist composition comprising at least:
(A) a polymer containing a repeating unit (a1) and an acid labile repeating unit (a2), wherein the repeating unit (a1) generates an acid of a structure represented by the following general formula (1) as a result that the repeating unit (a1) is sensed to a high-energy radiation,
the polymer being changed in solubility in alkali by the acid; and
(B) an onium sulfonate represented by the following general formula (2), 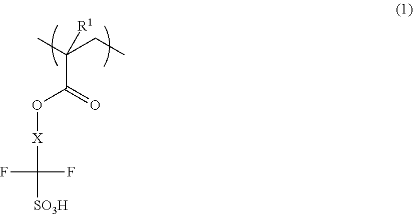
wherein
R¹ represents a hydrogen atom or a methyl group; and
X represents a straight, branched, or cyclic alkylene group having 1 to 10 carbon atoms which may contain an ether group or ester group, and one or more hydrogen atoms of the alkylene group may each be substituted by a fluorine atom, 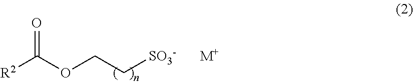
wherein
R² represents a monovalent hydrocarbon group which may contain a heteroatom;
n represents an integer of 1 to 3; and
M⁺ represents a counter cation having a substituent, and represents a sulfonium cation, iodonium cation, or ammonium cation.

2. The positive resist composition according to claim 1, wherein the acid generated as the result that the repeating unit (a1) in the polymer (A) is sensed to the high-energy radiation, is an acid of a structure represented by the following general formula (3), 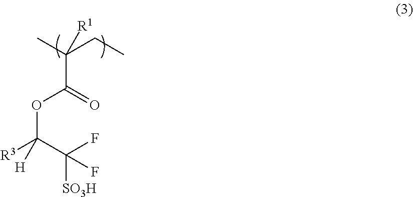
wherein
R¹ represents the same meaning as before; and
R³ represents a hydrogen atom or a trifluoromethyl group.

3. The positive resist composition according to claim 1, wherein the repeating unit (a1) in the polymer (A) is a repeating unit represented by the following general formula (4), 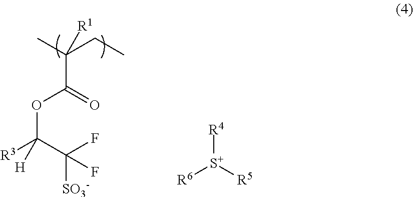
wherein
R¹ represents the same meaning as before;
R³ represents a hydrogen atom or a trifluoromethyl group; and
each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;
wherein any two or more of R⁴, R⁵, and R⁶ may bond to each other to form a ring together with a sulfur atom in the formula.

4. The positive resist composition according to claim 2, wherein the repeating unit (a1) in the polymer (A) is a repeating unit represented by the following general formula (4), 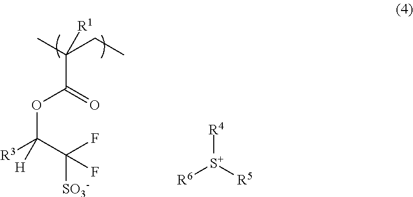
wherein
R¹ represents the same meaning as before;
R³ represents a hydrogen atom or a trifluoromethyl group; and
each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;
wherein any two or more of R⁴, R⁵, and R⁶ may bond to each other to form a ring together with a sulfur atom in the formula.

5. The positive resist composition according to claim 1, wherein the repeating unit (a1) in the polymer (A) is a repeating unit represented by the following general formula (5), 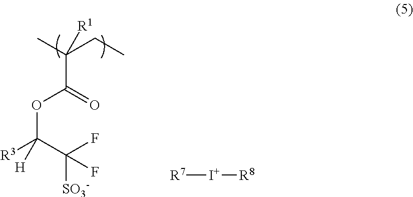
wherein
R¹ represents the same meaning as before;
R³ represents a hydrogen atom or a trifluoromethyl group; and
each R⁷ and R⁸ independently represent a substituted or unsubstituted aryl group having 6 to 18 carbon atoms.

6. The positive resist composition according to claim 2, wherein the repeating unit (a1) in the polymer (A) is a repeating unit represented by the following general formula (5), 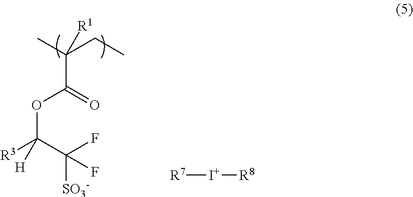
wherein
R¹ represents the same meaning as before;
R³ represents a hydrogen atom or a trifluoromethyl group; and
each R⁷ and R⁸ independently represent a substituted or unsubstituted aryl group having 6 to 18 carbon atoms.

7. The positive resist composition according to claim 1, wherein the onium sulfonate (B) is a sulfonium sulfonate represented by the following general formula (6), 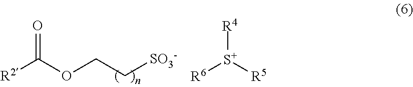
wherein
R²′ represents a straight, branched, or cyclic alkyl group having 1 to 50 carbon atoms which may contain a heteroatom;
n represents the same meaning as before; and
each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;
wherein any two or more of R⁴, R⁵, and R⁶ may bond to each other to form a ring together with a sulfur atom in the formula.

8. The positive resist composition according to claim 3, wherein the onium sulfonate (B) is a sulfonium sulfonate represented by the following general formula (6), 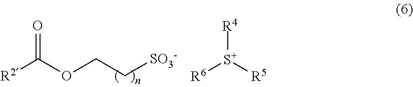
wherein
R²′ represents a straight, branched, or cyclic alkyl group having 1 to 50 carbon atoms which may contain a heteroatom;
n represents the same meaning as before; and
each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;
wherein any two or more of R⁴, R⁵, and R⁶ may bond to each other to form a ring together with a sulfur atom in the formula.

9. The positive resist composition according to claim 5, wherein the onium sulfonate (B) is a sulfonium sulfonate represented by the following general formula (6), 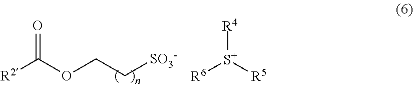
wherein
R²′ represents a straight, branched, or cyclic alkyl group having 1 to 50 carbon atoms which may contain a heteroatom;
n represents the same meaning as before; and
each R⁴, R⁵, and R⁶ independently represent: a substituted or unsubstituted straight, branched, or cyclic alkyl group, alkenyl group, or oxoalkyl group having 1 to 10 carbon atoms; or a substituted or unsubstituted aryl group, aralkyl group, or aryloxoalkyl group having 6 to 18 carbon atoms;
wherein any two or more of R⁴, R⁵, and R⁶ may bond to each other to form a ring together with a sulfur atom in the formula.

10. The positive resist composition according to claim 1, wherein the onium sulfonate (B) is a iodonium sulfonate represented by the following general formula (7), 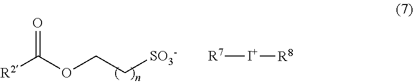
wherein
R²′ represents a straight, branched, or cyclic alkyl group having 1 to 50 carbon atoms which may contain a heteroatom;
n represents the same meaning as before; and
each R⁷ and R⁸ independently represent a substituted or unsubstituted aryl group having 6 to 18 carbon atoms.

11. The positive resist composition according to claim 3, wherein the onium sulfonate (B) is a iodonium sulfonate represented by the following general formula (7), 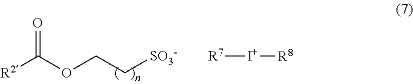
wherein
R²′ represents a straight, branched, or cyclic alkyl group having 1 to 50 carbon atoms which may contain a heteroatom;
n represents the same meaning as before; and
each R⁷ and R⁸ independently represent a substituted or unsubstituted aryl group having 6 to 18 carbon atoms.

12. The positive resist composition according to claim 5, wherein the onium sulfonate (B) is a iodonium sulfonate represented by the following general formula (7), 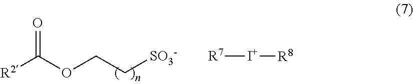
wherein
R²′ represents a straight, branched, or cyclic alkyl group having 1 to 50 carbon atoms which may contain a heteroatom;
n represents the same meaning as before; and
each R⁷ and R⁸ independently represent a substituted or unsubstituted aryl group having 6 to 18 carbon atoms.

13. The positive resist composition according to claim 1, wherein the onium sulfonate (B) is a ammonium sulfonate represented by the following general formula (8), 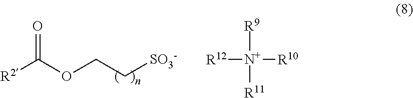
wherein
R²′ represents a straight, branched, or cyclic alkyl group having 1 to 50 carbon atoms which may contain a heteroatom;
n represents the same meaning as before; and
each R⁹, R¹⁰, R¹¹, and R¹² independently represent: a substituted or unsubstituted straight, branched, or cyclic alkyl group, alkenyl group, or oxoalkyl group having 1 to 18 carbon atoms, which group may contain a heteroatom; or a substituted or unsubstituted aryl group, aralkyl group, or aryloxoalkyl group having 6 to 18 carbon atoms;
wherein any two or more of R⁹, R¹⁰, R¹¹, and R¹² may bond to each other to form a ring together with a nitrogen atom in the formula.

14. The positive resist composition according to claim 3, wherein the onium sulfonate (B) is a ammonium sulfonate represented by the following general formula (8) 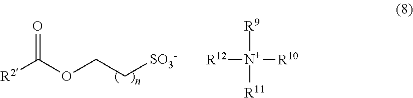
wherein
R²′ represents a straight, branched, or cyclic alkyl group having 1 to 50 carbon atoms which may contain a heteroatom;
n represents the same meaning as before; and
each R⁹, R¹⁰, R¹¹, and R¹² independently represent: a substituted or unsubstituted straight, branched, or cyclic alkyl group, alkenyl group, or oxoalkyl group having 1 to 18 carbon atoms, which group may contain a heteroatom; or a substituted or unsubstituted aryl group, aralkyl group, or aryloxoalkyl group having 6 to 18 carbon atoms;
wherein any two or more of R⁹, R¹⁰, R¹¹, and R¹² may bond to each other to form a ring together with a nitrogen atom in the formula.

15. The positive resist composition according to claim 5, wherein the onium sulfonate (B) is a ammonium sulfonate represented by the following general formula (8), 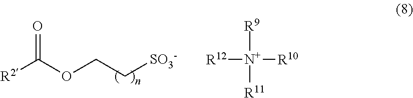
wherein
R²′ represents a straight, branched, or cyclic alkyl group having 1 to 50 carbon atoms which may contain a heteroatom;
n represents the same meaning as before; and
each R⁹, R¹⁰, R¹¹, and R¹² independently represent: a substituted or unsubstituted straight, branched, or cyclic alkyl group, alkenyl group, or oxoalkyl group having 1 to 18 carbon atoms, which group may contain a heteroatom; or a substituted or unsubstituted aryl group, aralkyl group, or aryloxoalkyl group having 6 to 18 carbon atoms;
wherein any two or more of R⁹, R¹⁰, R¹¹, and R¹² may bond to each other to form a ring together with a nitrogen atom in the formula.

16. The positive resist composition according to claim 1, wherein the polymer (A) further includes a repeating unit (a3) of a structure containing a lactone ring.

17. The positive resist composition according to claim 15, wherein the polymer (A) further includes a repeating unit (a3) of a structure containing a lactone ring.

18. The positive resist composition according to claim 1, wherein the repeating unit (a1) in the polymer (A) has a content ratio of 1 to 10% in molar ratio; and
wherein the onium sulfonate (B) has a content of 1 to 15 mass parts, relative to 100 mass parts of a content of the polymer (A).

19. The positive resist composition according to claim 17, wherein the repeating unit (a1) in the polymer (A) has a content ratio of 1 to 10% in molar ratio; and
wherein the onium sulfonate (B) has a content of 1 to 15 mass parts, relative to 100 mass parts of a content of the polymer (A).

20. The positive resist composition according to claim 1, further containing at least one or more of an organic solvent, a basic compound, a dissolution control agent, and a surfactant.

21. The positive resist composition according to claim 19, further containing at least one or more of an organic solvent, a basic compound, a dissolution control agent, and a surfactant.

22. A patterning process comprising the steps of:
applying the resist composition according to claim 1, to a substrate, and heat-treating the resist composition, to obtain a resist film;
exposing the resist film to a high-energy radiation; and
developing the resist film by a developer.

23. A patterning process comprising the steps of:
applying the resist composition according to claim 21, to a substrate, and heat-treating the resist composition, to obtain a resist film;
exposing the resist film to a high-energy radiation; and
developing the resist film by a developer.

24. The patterning process according to claim 22, wherein the high-energy radiation is within a wavelength range of 180 to 250 nm.

25. The patterning process according to claim 23, wherein the high-energy radiation is within a wavelength range of 180 to 250 nm.

26. The patterning process according to claim 22, wherein the step of exposing the resist film to the high-energy radiation is conducted by immersion exposure configured to expose the resist film through a liquid.

27. The patterning process according to claim 25, wherein the step of exposing the resist film to the high-energy radiation is conducted by immersion exposure configured to expose the resist film through a liquid.

28. The patterning process according to claim 26, wherein the resist film is provided with a top coat thereon, in the immersion exposure.

29. The patterning process according to claim 27, wherein the resist film is provided with a top coat thereon, in the immersion exposure.

30. The patterning process according to claim 26, wherein water is used as the liquid.

31. The patterning process according to claim 29, wherein water is used as the liquid.
